(19) United States
(12) Patent Application Publication
(10) Pub. No.: US 2025/0176353 A1
(43) Pub. Date: May 29, 2025

(54) ORGANIC ELECTRONIC ELEMENT WITH IMPROVED LATERAL RESISTANCE CHANGE RATIO AND AN ELECTRONIC DEVICE THEREOF

(71) Applicant: DUK SAN NEOLUX CO., LTD., Cheonan-si (KR)

(72) Inventors: Ui Sik KWON, Cheonan-si (KR); Hye Jeong KIM, Cheonan-si (KR); Hyung Dong LEE, Cheonan-si (KR)

(73) Assignee: DUK SAN NEOLUX CO., LTD., Cheonan-si (KR)

(21) Appl. No.: 18/946,418

(22) Filed: Nov. 13, 2024

(30) Foreign Application Priority Data
Nov. 23, 2023 (KR) 10-2023-0164627

(51) Int. Cl. H10K 50/12; H10K 50/15; H10K 85/60; H10K 101/40; H10K 102/00

(52) U.S. Cl. CPC H10K 50/12; H10K 50/15; H10K 85/633; H10K 85/636; H10K 85/615; H10K 85/624; H10K 85/626; H10K 85/6574; H10K 85/6576; H10K 2101/40; H10K 2102/351

(57) ABSTRACT

The present invention provides an organic electronic element comprising a first electrode; a second electrode; and an organic material layer formed between the first electrode and the second electrode; wherein the organic material layer comprises a hole transport layer, an emitting layer, and an electron transport layer, and forms an emitting auxiliary layer between the hole transport layer and the emitting layer, and can lower the driving voltage of an organic electronic element and improve the luminescence efficiency and lifespan by controlling the lateral resistance change ratio in according to the hole transport layer and the emitting auxiliary layer.

### BACKGROUND

### Technical Field

The present invention relates to an organic electronic element with improved lateral resistance change ratio and an electronic device thereof.

### Background Art

In general, organic light emitting phenomenon refers to a phenomenon that converts electric energy into light energy by using an organic material. An organic electronic element using an organic light emitting phenomenon usually has a structure including an anode, a cathode, and an organic material layer interposed therebetween. Here, the organic material layer is often composed of a multi-layered structure composed of different materials in order to increase the efficiency and stability of the organic electronic element, for example, may include a hole injection layer, a hole transport layer, an emitting layer, an electron transport layer, an electron injection layer etc.

In general, electrons are transferred from the electron transport layer to the emitting layer, and holes are transferred from the hole transport layer to the emitting layer to generate excitons by recombination.

However, the material used for the hole transport layer has a low HOMO value and therefore has mostly low T1 value, therefore the exciton generated in the emitting layer is transferred to the hole transport layer, resulting in charge unbalance in the emitting layer, and light is emitted at the interface of the hole transport layer. To solve the problem of luminescence in such hole transport layers, organic electronic elements that form multiple hole transport layers or form a emitting auxiliary layer between the hole transport layer and the emitting layer are being proposed.

By using an emitting auxiliary layer, problems such as light emission in the hole transport layer and charge imbalance within the emitting layer can be solved. However, in order to achieve the goal of high brightness, hole injection and transport between the hole transport layer and the emitting auxiliary layer or between the emitting auxiliary layer and the emitting layer must be controlled, and in particular, the interaction between the hole transport layer and the emitting auxiliary layer plays an important role.

### Prior art literature

### Patent Document

(patent document 1) Korean document 10-1647160

### DETAILED DESCRIPTION OF THE INVENTION

### Summary

The purpose of the present invention is to provide an organic electronic element comprising a compound that can lower the driving voltage of the element and improve the luminous efficiency, color purity, stability, and lifespan of the element, and electronic device thereof

### Technical Solution

In one aspect, the organic electronic element according to the present invention provides an organic electronic element comprising a first electrode; a second electrode; and an organic material layer formed between the first electrode and the second electrode, wherein the organic material layer comprises a hole transport layer, an emitting layer and an electron transport layer, and forms an emitting auxiliary layer between the hole transport layer and the emitting layer, wherein the hole transport layer and the emitting auxiliary layer satisfy the following equation 1.

$$\vert \frac{Δ {Rs}_{p}}{Δ {d}_{p}} \vert \leq 1.1 \qquad [ Equation 1 ]$$

In another aspect, the present invention provides an electronic device comprising the organic electronic element.

### Effects of the Invention

The present invention can achieve high luminous efficiency, low driving voltage and high heat resistance of an element by controlling the lateral resistance change ratio to limit parasitic current, and can significantly improve the color purity and lifespan of the element.

### BRIEF DESCRIPTION OF THE DRAWINGS

FIG. 1 illustrates an example of an organic electronic element according to the present invention.

FIG. 2 is a schematic diagram for the experimental setup as a device for measuring lateral resistance.

FIG. 3 is a graph showing the efficiency and lateral resistance change ratio according to one embodiment of the present invention.

### DETAILED DESCRIPTION

Hereinafter, some embodiments of the present invention will be described in detail. Further, in the following description of the present invention, a detailed description of known functions and configurations incorporated herein will be omitted when it may make the subject matter of the present invention rather unclear.

In addition, terms, such as first, second, A, B, (a), (b) or the like may be used herein when describing components of the present invention. Each of these terminologies is not used to define an essence, order or sequence of a corresponding component but used merely to distinguish the corresponding component from other component(s). It should be noted that if a component is described as being “connected”, “coupled”, or “connected” to another component, the component may be directly connected or connected to the other component, but another component may be “connected”, “coupled” or “connected” between each component.

As used in the specification and the accompanying claims, unless otherwise stated, the following is the meaning of the term as follows.

Unless otherwise stated, the term “halo” or “halogen”, as used herein, includes fluorine(F), bromine(Br), chlorine(CI), or iodine(I).

Unless otherwise stated, the term “alkyl” or “alkyl group”, as used herein, has a single bond of 1 to 60 carbon atoms, and means saturated aliphatic functional radicals including a linear alkyl group, a branched chain alkyl group, a cycloalkyl group (alicyclic), an cycloalkyl group substituted with a alkyl or an alkyl group substituted with a cycloalkyl.

Unless otherwise stated, the term “alkenyl” or “alkynyl”, as used herein, has double or triple bonds of 2 to 60 carbon atoms, but is not limited thereto, and includes a linear or a branched chain group.

Unless otherwise stated, the term “cycloalkyl”, as used herein, means alkyl forming a ring having 3 to 60 carbon atoms, but is not limited thereto.

Unless otherwise stated, the term “alkoxyl group”, “alkoxy group” or “alkyloxy group”, as used herein, means an oxygen radical attached to an alkyl group, but is not limited thereto, and has 1 to 60 carbon atoms.

Unless otherwise stated, the term “aryloxyl group” or “aryloxy group”, as used herein, means an oxygen radical attached to an aryl group, but is not limited thereto, and has 6 to 60 carbon atoms.

Unless otherwise stated, the term “aryl group” or “arylene group”, as used herein, has 6 to 60 carbon atoms, but is not limited thereto. In the present invention, an aryl group or arylene group means a single ring or multi-ring aromatic group, and comprises an aromatic ring formed by the participation of adjacent substituents in a bond or reaction. For example, “aryl group” may include a phenyl group, a biphenyl group, a fluorene group, or a spirofluorene group.

The prefix “aryl” or “ar” means a radical substituted with an aryl group. For example, an arylalkyl may be an alkyl substituted with an aryl, and an arylalkenyl may be an alkenyl substituted with aryl, and a radical substituted with an aryl has a number of carbon atoms as defined herein.

Also, when prefixes are named subsequently, it means that substituents are listed in the order described first. For example, an arylalkoxy means an alkoxy substituted with an aryl, an alkoxylcarbonyl means a carbonyl substituted with an alkoxyl, and an arylcarbonylalkenyl also means an alkenyl substituted with an arylcarbonyl, wherein the arylcarbonyl may be a carbonyl substituted with an aryl.

Unless otherwise stated, the term “heterocyclic group”, as used herein, contains one or more heteroatoms, but is not limited thereto, has 2 to 60 carbon atoms, includes any one of monocyclic and polycyclic rings, and may include heteroaliphatic ring and/or heteroaromatic ring. Also, the heterocyclic group may also be formed in conjunction with an adjacent group.

Unless otherwise stated, the term “heteroatom”, as used herein, represents at least one of N, O, S, P, or Si.

Also, the term “heterocyclic group” may include a ring including SO₂ instead of carbon consisting of cycle. For example, “heterocyclic group” includes compound below.

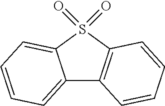 [SMILES: O=S1(=O)c2ccccc2-c2ccccc21]

Unless otherwise stated, the term “fluorenyl group” or “fluorenylene group”, as used herein, means a monovalent or divalent functional group, in which R, R′ and R″ are all hydrogen in the following structures, and the term “substituted fluorenyl group” or “substituted fluorenylene group” means that at least one of the substituents R, R′, R″ is a substituent other than hydrogen, and include those in which R and R′ are bonded to each other to form a spiro compound together with the carbon to which they are bonded.

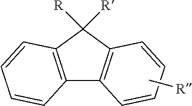

The term “spiro compound”, as used herein, has a ‘spiro union’, and the spiro union means a connection in which 2 rings share only one atom. The atoms shared between the 2 rings are called ‘spiro atoms’, and these compounds are called ‘monospiro-’, ‘di-spiro-’ and ‘tri-spiro-’, respectively, depending on the number of atoms contained in a compound.

Unless otherwise stated, the term “aliphatic”, as used herein, means an aliphatic hydrocarbon having 1 to 60 carbon atoms, and the term “aliphatic ring”, as used herein, means an aliphatic hydrocarbon ring having 3 to 60 carbon atoms.

Unless otherwise stated, the term “ring”, as used herein, means an aliphatic ring having 3 to 60 carbon atoms, or an aromatic ring having 6 to 60 carbon atoms, or a hetero ring having 2 to 60 carbon atoms, or a fused ring formed by the combination of them, and includes a saturated or unsaturated ring.

Other hetero compounds or hetero radicals other than the above-mentioned hetero compounds include one or more heteroatoms, but are not limited thereto.

Unless otherwise stated, the term “substituted or unsubstituted”, as used herein, means that substitution is substituted by at least one substituent selected from the group consisting of deuterium, halogen, an amino group, a nitrile group, a nitro group, a C₁-C₂₀ alkyl group, a C₁-C₂₀ alkoxyl group, a C₁-C₂₀ alkylamine group, a C₁-C₂₀ alkylthiophen group, a C₆-C₂₀ arylthiophen group, a C₂-C₂₀ alkenyl group, a C₂-C₂₀ alkynyl group, a C₃-C₂₀ cycloalkyl group, a C₆-C₂₀ aryl group, a C₆-C₂₀ aryl group substituted by deuterium, a C₈-C₂₀ arylalkenyl group, a silane group, a boron group, a germanium group, and a C₂-C₂₀ heterocyclic group, but is not limited thereto.

Unless otherwise expressly stated, the Formula used in the present invention, as used herein, is applied in the same manner as the substituent definition according to the definition of the exponent of the following Formula.

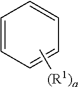

wherein, when a is an integer of 0, the substituent R¹ is absent, when a is an integer of 1, the sole substituent R¹ is linked to any one of the carbon constituting the benzene ring, when a is an integer of 2 or 3, each substituent R¹s may be the same and different, when a is an integer of 4 to 6, and is linked to the carbon of the benzene ring in a similar manner, whereas the indication of hydrogen bound to the carbon forming the benzene ring is omitted.

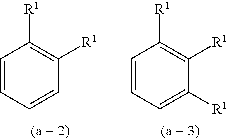

The term “composition” as used in the present invention is intended to be broadly interpreted to include not only compounds but also solutions, dispersions, liquid and solid mixtures (mixtures, admixtures).

The composition of the present invention may contain the compound of the present invention alone, or may contain 2 or more different compounds in combination, or may contain the compound in combination with 2 or more other compounds. In other words, the composition may contain a compound corresponding to Formula 1 alone, may contain a mixture of 2 or more compounds of Formula 1, or may contain a mixture of a compound of Formula 1 and a compound not corresponding to the present invention. Wherein, the compound not corresponding to the present invention may be a single compound or may be 2 or more compounds. At this time, when the compound is contained in a combination of 2 or more other compounds, the other compounds may be already known compounds of each organic material layer, or compounds to be developed in the future. At this time, the compound contained in the organic material layer may be composed only of homogeneous compounds, but may also be a mixture of 2 or more heterogeneous compounds represented by Formula 1.

Hereinafter, an organic electronic element according to one aspect of the present invention will be described.

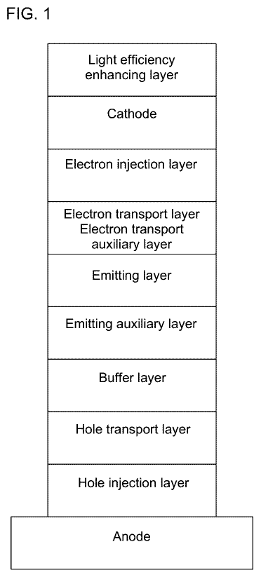

Referring to FIG. 1, the organic electronic element according to one aspect of the present invention comprises a first electrode formed on a substrate (not shown), a second electrode, an organic material layer formed between the first electrode and the second electrode.

Wherein, the first electrode may be an anode (a positive electrode), and the second electrode may be a cathode (a negative electrode), and in the case of an inverted organic electronic element, the first electrode may be a cathode, and the second electrode may be an anode.

The organic material layer may comprise a hole transport layer, an emitting layer, an electron transport layer, and an emitting auxiliary layer is formed between the hole transport layer and the emitting layer.

The interaction between the hole transport layer and the emitting auxiliary layer can be determined by lateral resistance change ratio. When the lateral resistance change ratio is large, hole injection between the hole transport layer and the emitting auxiliary layer is smooth, so the amount of holes in the emitting layer increases, causing an imbalance between holes and electrons in the emitting layer. This causes non-luminous annihilating holes to be generated, which reduces the luminous efficiency of the element. Therefore, when the energy level or intrinsic properties of the material (mobility, interface properties, etc.) between the hole transport layer and the emitting auxiliary layer are optimally combined, the properties of the organic electronic element can be improved.

At this time, the hole transport layer and the emitting auxiliary layer satisfy the following equation 1.

$$\vert \frac{Δ {Rs}_{p}}{Δ {d}_{p}} \vert \leq 1.1 \qquad [ Equation 1 ]$$

{In the equation 1,
1) ΔRsₚ is the difference in lateral resistance according to the thickness of the emitting auxiliary layer,
2) Δdₚ is the difference in thickness of the emitting auxiliary layer.

More specifically, by changing the emitting auxiliary layer in an element having a hole transport layer made of the same compound, the lateral resistance change ratio is controlled, ΔRsₚ means the difference in the lateral resistance value measured by changing the thickness of the emitting auxiliary layer, Δdₚ represents the difference in thickness of the emitting auxiliary layer.

For example, the difference in the lateral resistance values when the thickness of the emitting auxiliary layer is 56 nm and 20 nm, respectively, is ΔRsₚ, and Δdₚ is 36 nm, which is the difference in thickness of the emitting auxiliary layer.

In the equation 1, the lateral resistance change ratio according to the thickness of the emitting auxiliary layer is expressed as the absolute value of the ΔRsₚ/Δdₚ ratio.

The lateral resistance change ratio of the emitting auxiliary layer can have an absolute value of 1.1 or less. It is preferable to have a value less than or equal to 1.0 in absolute value, and more preferably a value less than or equal to 0.9 in absolute value.

The lateral resistance change ratio is determined by the degree of hole injection and hole mobility between the hole transport layer and the emitting auxiliary layer, and the closer the value is to 0, the less holes are injected from the hole transport layer to the emitting auxiliary layer.

FIG. 3 is a graph showing the efficiency and lateral resistance change ratio. Referring to FIG. 3, it can be seen that the closer the lateral resistance change ratio is to 1.1, the more the efficiency decreases, and when the lateral resistance change ratio has a value between 1.1 and 1.4, the efficiency decreases rapidly. This can also be confirmed in Table 6.

The organic material layer may further comprise a hole injection layer between the first electrode and the hole transport layer, and an electron injection layer between the second electrode and the electron transport layer.

Additionally, a buffer layer may be further formed between the hole transport layer and the emitting auxiliary layer.

Although not shown in FIG. 1, an electron transport auxiliary layer may be additionally formed between the emitting layer and the electron transport layer.

Also, the organic electronic element according to one embodiment of the present invention may further include a protective layer or a light efficiency enhancing layer. This light efficiency enhancing layer can be formed on a surface of both sides of the first electrode, the surface not in contact with the organic material layer or on a surface of both sides of the second electrode, the surface not in contact with the organic material layer.

According to one embodiment of the present specification, the hole transport layer or the emitting auxiliary layer can be represented by Formula 1 or Formula 2.

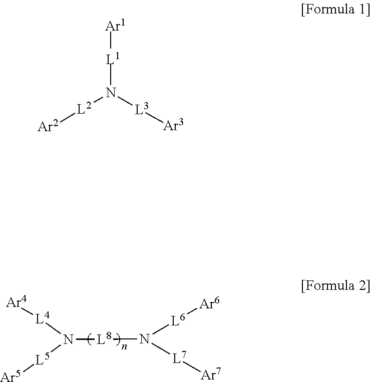

Wherein:
L¹, L², L³, L⁴, L⁵, L⁶ and L⁷ are each selected from the group consisting of single bond; a C₆-C₆₀ arylene group; a fluorenylene group; a C₂-C₆₀ heterocyclic group including at least one heteroatom of O, N, S, Si or P; and a fused ring group of a C₃-C₆₀ aliphatic ring and a C₆-C₆₀ aromatic ring;
L⁸ is selected from the group consisting of single bond; a C₆-C₆₀ arylene group; a fluorenylene group; a C₂-C₆₀ heterocyclic group including at least one heteroatom of O, N, S, Si or P; and a fused ring group of a C₃-C₆₀ aliphatic ring and a C₆-C₆₀ aromatic ring;
When L¹, L², L³, L⁴, L⁵, L⁶, L⁷ and L⁸ are an arylene group, preferably an C₆-C₆₀ arylene group, more preferably an C₆-C₂₅ arylene group, for example, it may be phenylene, biphenylene, naphthylene, terphenylene, anthracenylene, phenanthrenylene and the like.

When L¹, L², L³, L⁴, L⁵, L⁶, L⁷ and L⁸ are a heterocyclic group, preferably a C₂-C₆₀ heterocyclic group, more preferably a C₂-C₂₄ heterocyclic group, for example, it may be pyrazine, thiophene, pyridine, pyrimidoindole, 5-phenyl-5H-pyrimido[5,4-b]indole, quinazoline, benzoquinazoline, carbazole, dibenzoquinazoline, dibenzofuran, dibenzothiophene, benzothienopyrimidine, benzofuropyrimidine, phenothiazine, phenylphenothiazine, naphthobenzofuran, naphthobenzothiophene etc.

When L¹, L², L³, L⁴, L⁵, L⁶, L⁷ and L⁸ are a fused ring group, preferably a fused ring group of a C₃-C₃₀ aliphatic ring and an C₆-C₆₀ aromatic ring, more preferably a fused ring group of an C₃-C₂₄ aliphatic ring and an C₆-C₂₄ aromatic ring.

Ar¹, Ar², Ar³, Ar⁴, Ar⁵, Ar⁶ and Ar⁷ are each selected from the group consisting of a C₆-C₆₀ aryl group; a fluorenyl group; a C₂-C₆₀ heterocyclic group including at least one heteroatom of O, N, S, Si or P; and a fused ring group of a C₃-C₆₀ aliphatic ring and a C₆-C₆₀ aromatic ring; a C₃-C₆₀ aliphatic ring; C₁-C₅₀ alkyl group; C₂-C₂₀ alkenyl group; C₂-C₂₀ alkynyl group; a C₁-C₃₀ alkoxyl group; a C₆-C₆₀ aryloxy group; and -L′-N(R′)(R″); or, the Ar⁴ and Ar⁵ or Ar⁶ and Ar⁷ can be bonded to each other to form a ring,

When Ar¹, Ar², Ar³, Ar⁴, Ar⁵, Ar⁶ and Ar⁷ are an aryl group, preferably an C₆-C₃₀ aryl group, more preferably an C₆-C₂₅ aryl group, for example, it may be phenyl, biphenyl, terphenyl, naphthalene, phenanthrene and the like.

When Ar¹, Ar², Ar³, Ar⁴, Ar⁵, Ar⁶ and Ar⁷ are a heterocyclic group, preferably a C₂-C₃₀ heterocyclic group, more preferably a C₂-C₂₄ heterocyclic group, for example, it may be pyrazine, thiophene, pyridine, pyrimidoindole, 5-phenyl-5H-pyrimido[5,4-b]indole, quinazoline, benzoquinazoline, carbazole, dibenzoquinazoline, dibenzofuran, dibenzothiophene, benzothienopyrimidine, benzofuropyrimidine, phenothiazine, phenylphenothiazine, naphthobenzofuran, naphthobenzothiophene etc.

When Ar¹, Ar², Ar³, Ar⁴, Ar⁵, Ar⁶ and Ar⁷ are a fused ring group, preferably a fused ring group of a C₃-C₃₀ aliphatic ring and an C₆-C₆₀ aromatic ring, more preferably a fused ring group of an C₃-C₂₄ aliphatic ring and an C₆-C₂₄ aromatic ring.

When Ar¹, Ar², Ar³, Ar⁴, Ar⁵, Ar⁶ and Ar⁷ are an aliphatic ring group, preferably a C₃-C₃₀ aliphatic ring group, more preferably a C₃-C₂₄ aliphatic ring group.

When Ar¹, Ar², Ar³, Ar⁴, Ar⁵, Ar⁶ and Ar⁷ are an alkyl group, preferably a C₁-C₃₀ alkyl group, more preferably a C₁-C₂₄ alkyl group.

When Ar¹, Ar², Ar³, Ar⁴, Ar⁵, Ar⁶ and Ar⁷ are an alkoxyl group, preferably a C₁-C₂₄ alkoxyl group.

When Ar¹, Ar², Ar³, Ar⁴, Ar⁵, Ar⁶ and Ar⁷ are an aryloxy group, preferably a C₆-C₂₄ aryloxy group.
wherein L′ is selected from the group consisting of single bond; a C₆-C₆₀ arylene group; a fluorenylene group; a C₃-C₆₀ aliphatic ring; and a C₂-C₆₀ heterocyclic group including at least one heteroatom of O, N, S, Si or P;
When L′ is an arylene group, it is preferably an C₆-C₆₀ arylene group, more preferably an C₆-C₂₅ arylene group, for example, phenylene, biphenylene, naphthylene, terphenylene, anthracenylene, phenanthrenylene and the like.

When L′ is an aliphatic ring group, preferably a C₃-C₃₀ aliphatic ring group, more preferably a C₃-C₂₄ aliphatic ring group.

When L′ is a heterocyclic group, preferably a C₂-C₃₀ heterocyclic group, more preferably a C₂-C₂₄ heterocyclic group, for example, it may be pyrazine, thiophene, pyridine, pyrimidoindole, 5-phenyl-5H-pyrimido[5,4-b]indole, quinazoline, benzoquinazoline, carbazole, dibenzoquinazoline, dibenzofuran, dibenzothiophene, benzothienopyrimidine, benzofuropyrimidine, phenothiazine, phenylphenothiazine, naphthobenzofuran, naphthobenzothiophene etc.

R′ and R″ are each independently selected from the group consisting of a C₆-C₆₀ aryl group; a fluorenyl group; a C₃-C₆₀ aliphatic ring group; and a C₂-C₆₀ heterocyclic group including at least one hetero atom of O, N, S, Si or P;

When R′ and R″ are an aryl group, preferably an C₆-C₆₀ aryl group, more preferably an C₆-C₂₅ aryl group, for example, it may be phenyl, biphenyl, terphenyl, naphthalene, phenanthrene and the like.

When R′ and R″ are an aliphatic ring group, preferably a C₃-C₃₀ aliphatic ring group, more preferably a C₃-C₂₄ aliphatic ring group.

When R′ and R″ are a heterocyclic group, preferably a C₂-C₃₀ heterocyclic group, more preferably a C₂-C₂₄ heterocyclic group, for example, it may be pyrazine, thiophene, pyridine, pyrimidoindole, 5-phenyl-5H-pyrimido[5,4-b]indole, quinazoline, benzoquinazoline, carbazole, dibenzoquinazoline, dibenzofuran, dibenzothiophene, benzothienopyrimidine, benzofuropyrimidine, phenothiazine, phenylphenothiazine, naphthobenzofuran, naphthobenzothiophene etc.

n is an integer from 1 to 3,
wherein the aryl group, arylene group, heterocyclic group, fluorenyl group, fluorenylene group, fused ring group, aliphatic ring group, alkyl group, alkenyl group, alkynyl group, alkoxy group and aryloxy group may be substituted with one or more substituents selected from the group consisting of deuterium; halogen; C₁-C₂₀ alkyl group; or a silane group substituted or unsubstituted with an C₆-C₂₀ aryl group; siloxane group; boron group; germanium group; cyano group; nitro group; C₁-C₂₀ alkylthio group; C₁-C₂₀ alkoxyl group; C₁-C₂₀ alkyl group; C₂-C₂₀ alkenyl group; C₂-C₂₀ alkynyl group; C₆-C₂₀ aryl group; C₆-C₂₀ aryl group substituted with deuterium; a fluorenyl group; C₂-C₂₀ heterocyclic group; C₃-C₂₀ cycloalkyl group; C₇-C₂₀ arylalkyl group; C₈-C₂₀ arylalkenyl group; and -L′-N(R′)(R″); additionally, the hydrogens of these substituents may be further substituted with one or more deuteriums, also the substituents may be bonded to each other to form a saturated or unsaturated ring, wherein the term ‘ring’ means a C₃-C₆₀ aliphatic ring or a C₆-C₆₀ aromatic ring or a C₂-C₆₀ heterocyclic group or a fused ring formed by the combination thereof.

At least one of the Ar¹, Ar², Ar³, Ar⁴, Ar⁵, Ar⁶ and Ar⁷ is represented by any one of the following Formulas Ar-a to Ar-d:

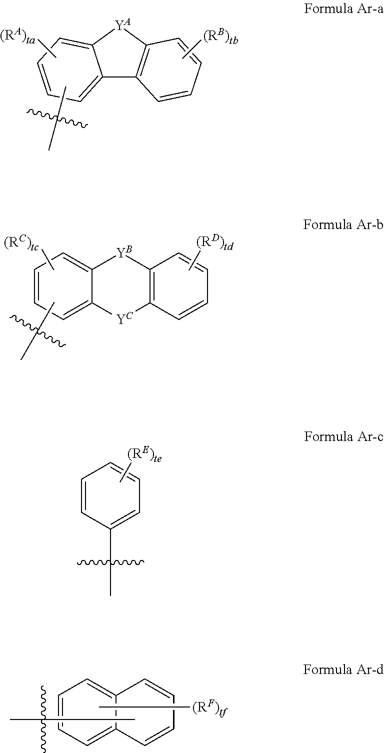

Wherein:
Y^{A}, Y^{B} and Y^{C} are each independently O, S, NR^{1A}, Si(R^{1B})(R^{1C}) or C(R^{1B})(R^{1C}),
R^{A}, R^{B}, R^{C}, R^{D}, R^{E}, R^{F}, R^{1A}, R^{1B} and R^{1C} are each independently the same or different, and each independently selected from the group consisting of hydrogen; deuterium; halogen; cyano group; a C₆-C₂₀ aryl group; C₆-C₂₀ aryl group substituted with deuterium; a fluorenyl group; a C₂-C₂₀ heterocyclic group including at least one hetero atom of O, N, S, Si or P; a C₁-C₂₀ alkyl group; a C₂-C₂₀ alkenyl group; a C₂-C₂₀ alkynyl group; a C₁-C₂₀ alkoxyl group; and a C₆-C₂₀ aryloxy group; and -L′-N(R′)(R″); and or an adjacent plurality of R^{A} or plurality of R^{B} or plurality of R^{C} or plurality of R^{D} or plurality of R^{E} or plurality of R^{F} may be bonded to each other to form a ring, or R^{1B} and R^{1C} can be bonded to each other to form a spiro,
ta and tc are each independently integers from 0 to 3, tb and td are each independently integers from 0 to 4, te is an integer from 0 to 5, tf is an integer from 0 to 7,
L′, R′ and R″ are as defined above,

[symbol] indicates the position to be bonded.

Formula Ar-a can be represented by any one of the following Formulas Ar-a-1 to Ar-a-4.

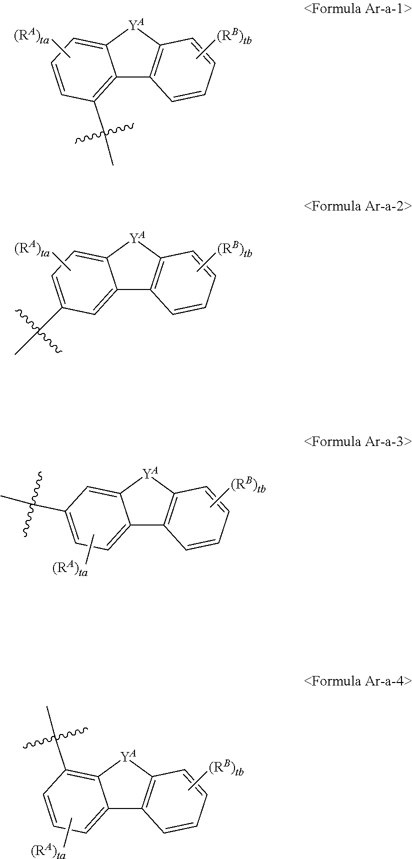

Wherein, R^{A}, R^{B}, Y^{A}, ta, tb and [symbol] are the same as defined in Formula Ar-a.

Formula Ar-b can be represented by the following Formula Ar-b-1 or Formula Ar-b-2.

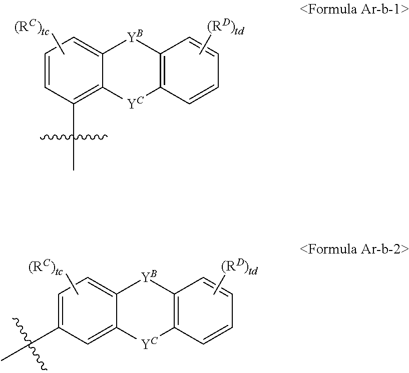

Wherein, R^{C}, R^{D}, Y^{B}, Y^{C}, tc, td and [symbol] are the same as defined in Formula Ar-b.

Formula Ar-d can be represented by the following Formula Ar-d-1 or Formula Ar-d-2.

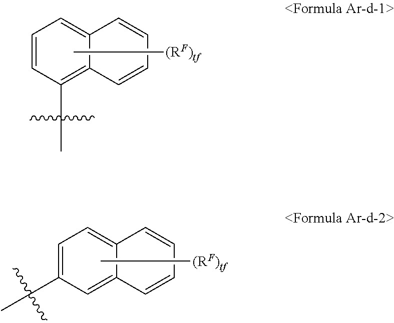

Wherein, R^{F}, tf and [symbol] are the same as defined in Formula Ar-d.

L¹, L², L³, L⁴, L⁵, L⁶ and L⁷ can be represented by a single bond or any one of Formulas b-1 to b-13, and L⁸ can be represented by any one of Formulas b-1 to b-13.

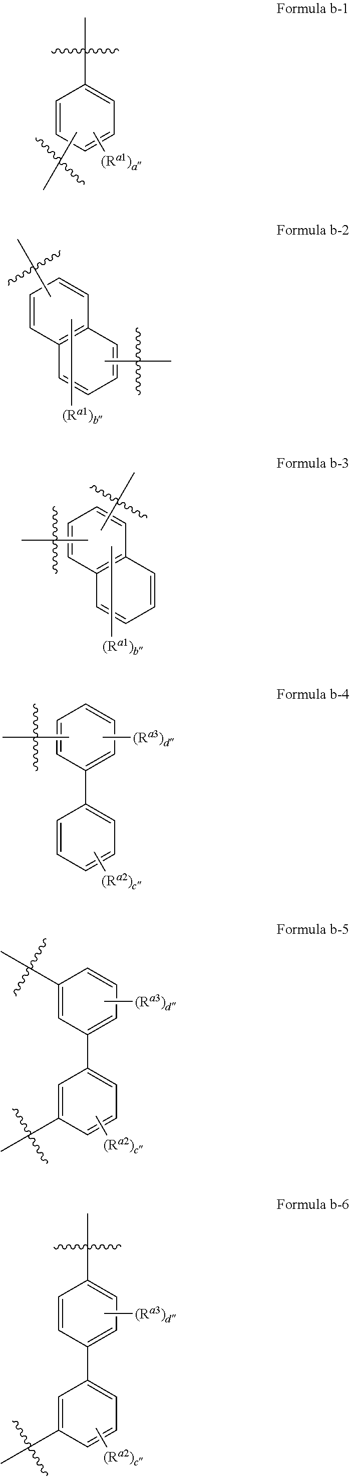

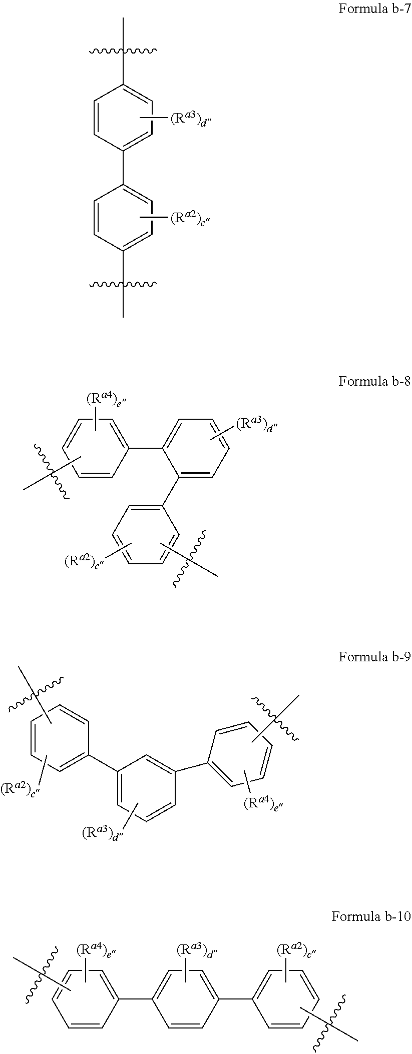

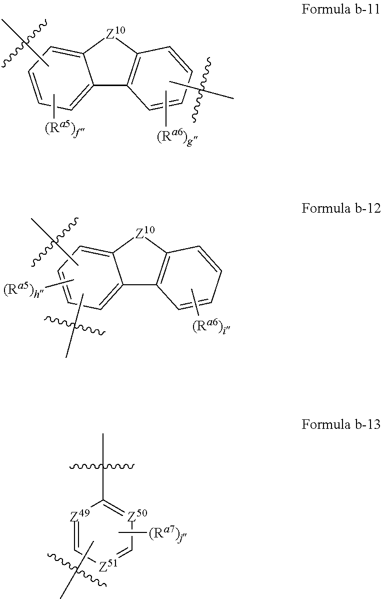

Wherein,
Z¹⁰ is O, S, NR^{1D} or C(R^{1E})(R^{1F}),
a″, c″, d″, e″ and i″ are independently integers from 0 to 4, b″ is an integer from 0 to 6, f″ and g″ are independently integers from 0 to 3, h″ is an integer from 0 to 2, j″ is an integer of 0 or 1,
R^{a1}, R^{a2}, R^{a3}, R^{a4}, R^{a5}, R^{a6}, R^{a7}, R^{1D}, R^{1E} and R^{1F} are each independently the same or different, and each independently selected from the group consisting of hydrogen; deuterium; an C₆-C₂₀ aryl group substituted or unsubstituted with deuterium; a fluorenyl group; a C₂-C₂₀ heterocyclic group including at least one hetero atom of O, N, S, Si or P; a C₁-C₅₀ alkyl group; a C₂-C₂₀ alkenyl group; a C₂-C₂₀ alkynyl group; a C₁-C₃₀ alkoxyl group; and a C₆-C₆₀ aryloxy group; or, adjacent groups can be bonded to each other to form a ring,
Z⁴⁹, Z⁵⁰ and Z⁵¹ are each independently CR^{1G} or N,
provided that at least one of Z⁴⁹, Z⁵⁰ and Z⁵¹ is N,
R^{1G} are each independently selected from the group consisting of hydrogen; deuterium; an C₆-C₂₀ aryl group; a fluorenyl group; a C₂-C₂₀ heterocyclic group including at least one hetero atom of O, N, S, Si or P; a C₁-C₂₀ alkyl group; a C₂-C₂₀ alkenyl group; a C₂-C₂₀ alkynyl group; a C₁-C₃₀ alkoxyl group; and a C₆-C₆₀ aryloxy group;
[symbol] indicates the position to be bonded.

Specifically, the compound represented by Formula 1 may be any one of the following compounds P1-1 to P1-97, but is not limited thereto.

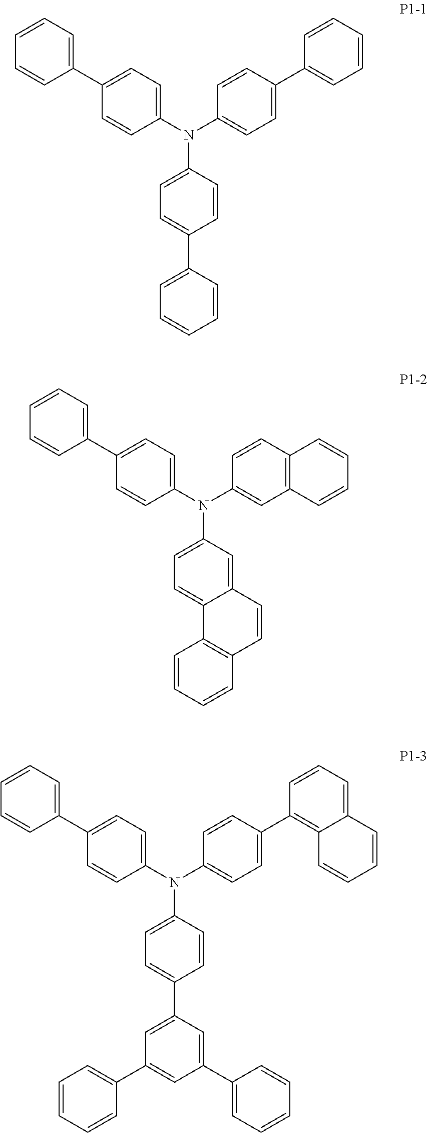 [SMILES: c1ccc(-c2ccc(N(c3ccc(-c4ccccc4)cc3)c3ccc(-c4ccccc4)cc3)cc2)cc1 ; c1ccc(-c2ccc(N(c3ccc4ccccc4c3)c3ccc4c(ccc5ccccc54)c3)cc2)cc1 ; c1ccc(-c2ccc(N(c3ccc(-c4cc(-c5ccccc5)cc(-c5ccccc5)c4)cc3)c3ccc(-c4cccc5ccccc45)cc3)cc2)cc1]

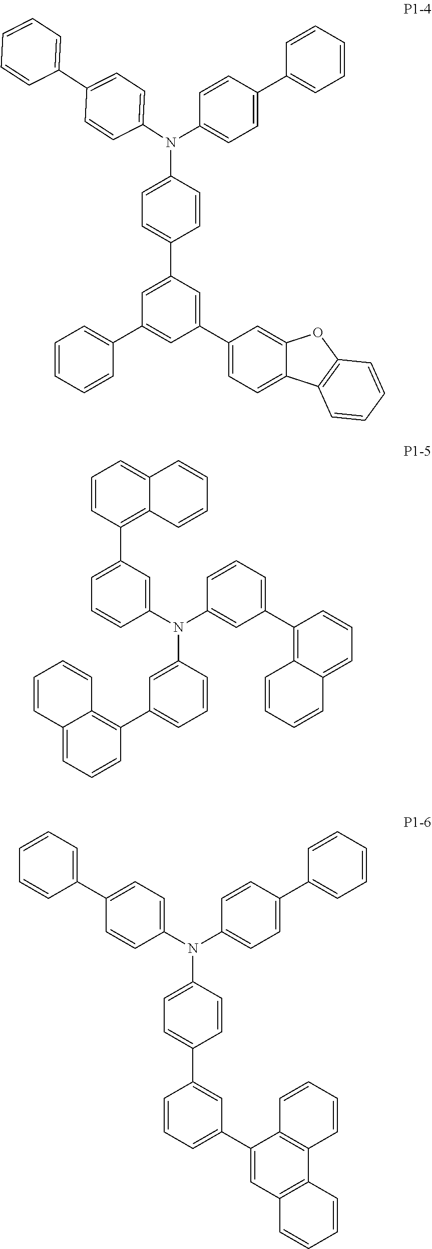 [SMILES: c1ccc(-c2ccc(N(c3ccc(-c4ccccc4)cc3)c3ccc(-c4cc(-c5ccccc5)cc(-c5ccc6c(c5)oc5ccccc56)c4)cc3)cc2)cc1 ; c1cc(-c2cccc3ccccc23)cc(N(c2cccc(-c3cccc4ccccc34)c2)c2cccc(-c3cccc4ccccc34)c2)c1 ; c1ccc(-c2ccc(N(c3ccc(-c4ccccc4)cc3)c3ccc(-c4cccc(-c5cc6ccccc6c6ccccc56)c4)cc3)cc2)cc1]

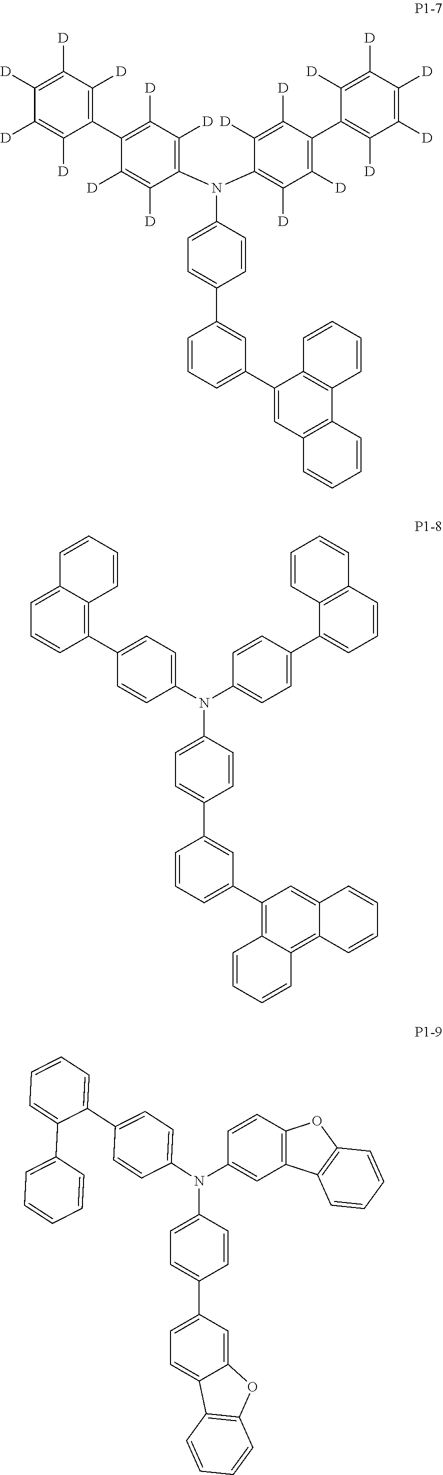 [SMILES: [2H]c1c([2H])c([2H])c(-c2c([2H])c([2H])c(N(c3ccc(-c4cccc(-c5cc6ccccc6c6ccccc56)c4)cc3)c3c([2H])c([2H])c(-c4c([2H])c([2H])c([2H])c([2H])c4[2H])c([2H])c3[2H])c([2H])c2[2H])c([2H])c1[2H] ; c1cc(-c2ccc(N(c3ccc(-c4cccc5ccccc45)cc3)c3ccc(-c4cccc5ccccc45)cc3)cc2)cc(-c2cc3ccccc3c3ccccc23)c1 ; c1ccc(-c2ccccc2-c2ccc(N(c3ccc(-c4ccc5c(c4)oc4ccccc45)cc3)c3ccc4oc5ccccc5c4c3)cc2)cc1]

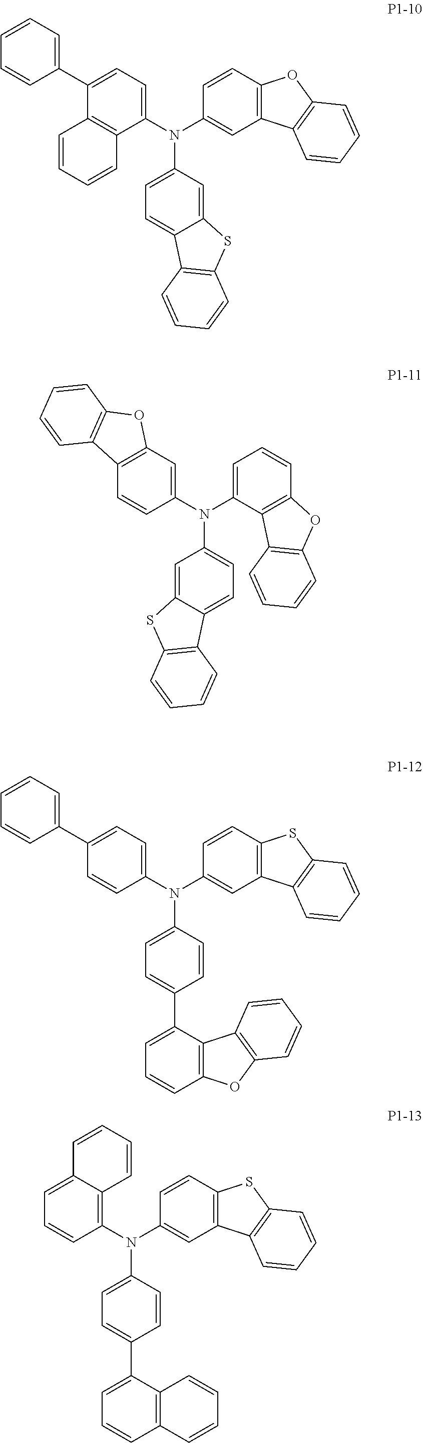 [SMILES: c1ccc(-c2ccc(N(c3ccc4c(c3)sc3ccccc34)c3ccc4oc5ccccc5c4c3)c3ccccc23)cc1 ; c1ccc2c(c1)oc1cc(N(c3ccc4c(c3)sc3ccccc34)c3cccc4oc5ccccc5c34)ccc12 ; c1ccc(-c2ccc(N(c3ccc(-c4cccc5oc6ccccc6c45)cc3)c3ccc4sc5ccccc5c4c3)cc2)cc1 ; c1ccc2c(-c3ccc(N(c4ccc5sc6ccccc6c5c4)c4cccc5ccccc45)cc3)cccc2c1]

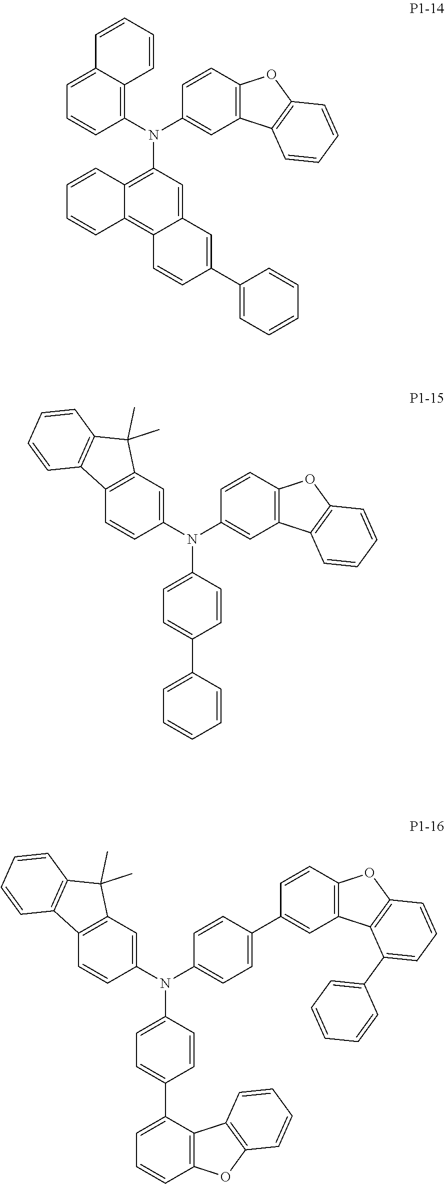 [SMILES: c1ccc(-c2ccc3c(c2)cc(N(c2ccc4oc5ccccc5c4c2)c2cccc4ccccc24)c2ccccc23)cc1 ; CC1(C)c2ccccc2-c2ccc(N(c3ccc(-c4ccccc4)cc3)c3ccc4oc5ccccc5c4c3)cc21 ; CC1(C)c2ccccc2-c2ccc(N(c3ccc(-c4ccc5oc6cccc(-c7ccccc7)c6c5c4)cc3)c3ccc(-c4cccc5oc6ccccc6c45)cc3)cc21]

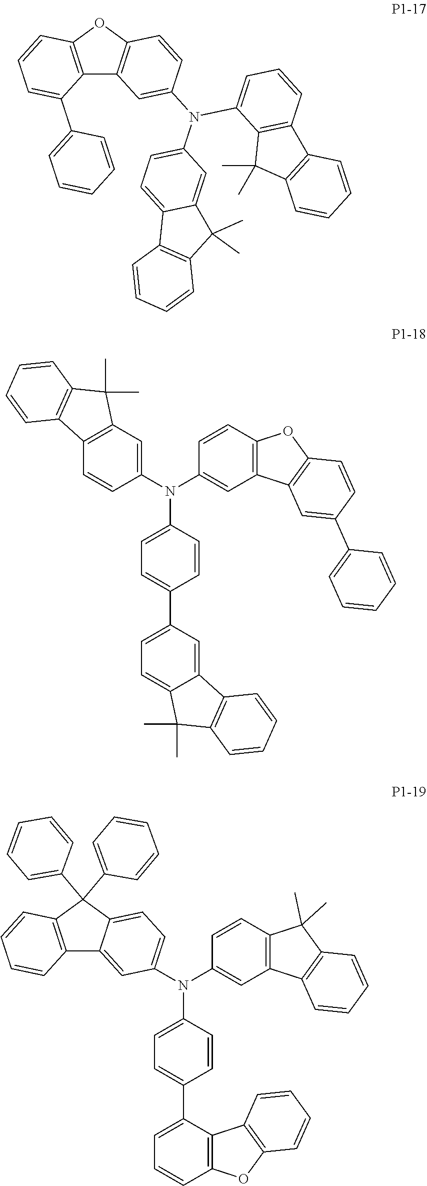 [SMILES: CC1(C)c2ccccc2-c2ccc(N(c3ccc4oc5cccc(-c6ccccc6)c5c4c3)c3cccc4c3C(C)(C)c3ccccc3-4)cc21 ; CC1(C)c2ccccc2-c2cc(-c3ccc(N(c4ccc5c(c4)C(C)(C)c4ccccc4-5)c4ccc5oc6ccc(-c7ccccc7)cc6c5c4)cc3)ccc21 ; CC1(C)c2ccccc2-c2cc(N(c3ccc(-c4cccc5oc6ccccc6c45)cc3)c3ccc4c(c3)-c3ccccc3C4(c3ccccc3)c3ccccc3)ccc21]

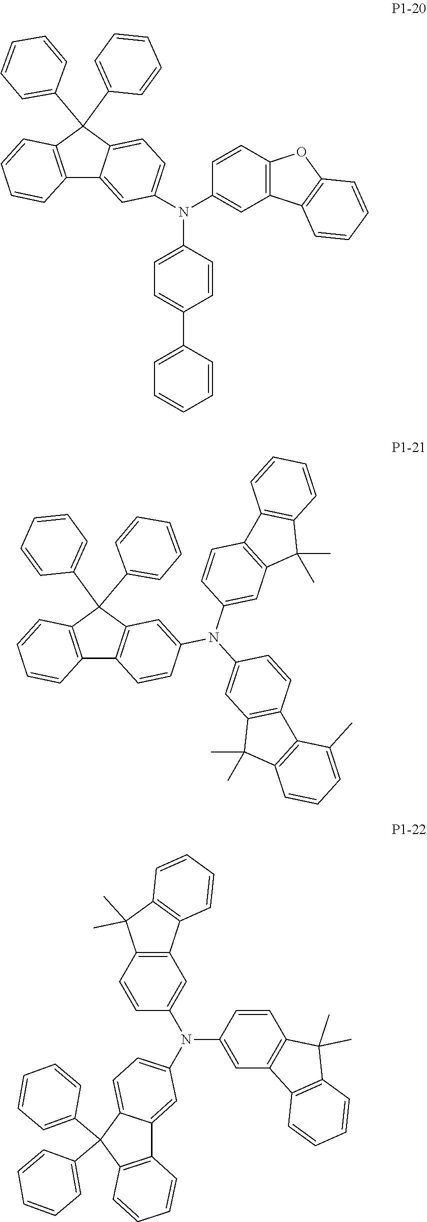 [SMILES: c1ccc(-c2ccc(N(c3ccc4c(c3)-c3ccccc3C4(c3ccccc3)c3ccccc3)c3ccc4oc5ccccc5c4c3)cc2)cc1 ; Cc1cccc2c1-c1ccc(N(c3ccc4c(c3)C(C)(C)c3ccccc3-4)c3ccc4c(c3)C(c3ccccc3)(c3ccccc3)c3ccccc3-4)cc1C2(C)C ; CC1(C)c2ccccc2-c2cc(N(c3ccc4c(c3)-c3ccccc3C4(C)C)c3ccc4c(c3)-c3ccccc3C4(c3ccccc3)c3ccccc3)ccc21]

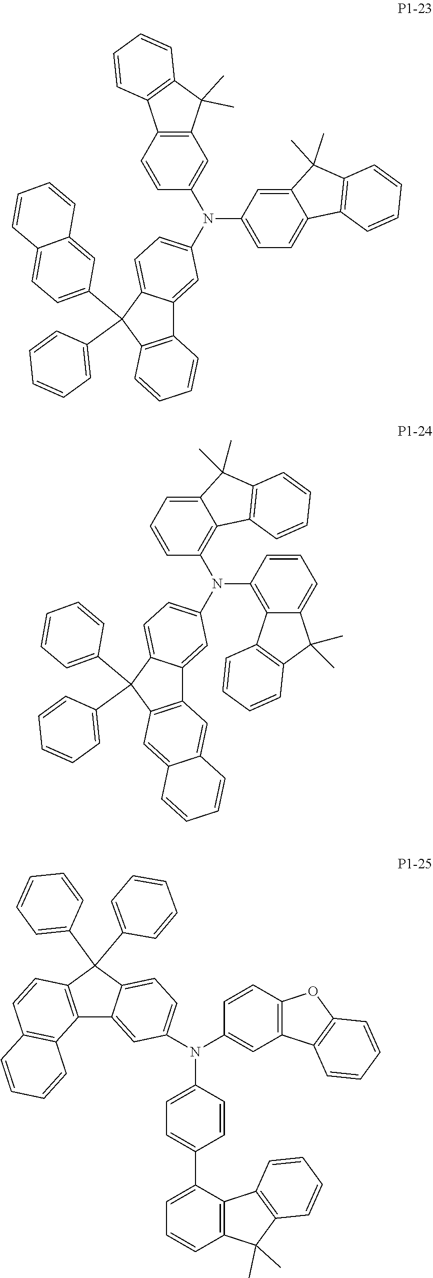 [SMILES: CC1(C)c2ccccc2-c2ccc(N(c3ccc4c(c3)-c3ccccc3C4(c3ccccc3)c3ccc4ccccc4c3)c3ccc4c(c3)C(C)(C)c3ccccc3-4)cc21 ; CC1(C)c2ccccc2-c2c(N(c3ccc4c(c3)-c3cc5ccccc5cc3C4(c3ccccc3)c3ccccc3)c3cccc4c3-c3ccccc3C4(C)C)cccc21 ; CC1(C)c2ccccc2-c2c(-c3ccc(N(c4ccc5c(c4)-c4c(ccc6ccccc46)C5(c4ccccc4)c4ccccc4)c4ccc5oc6ccccc6c5c4)cc3)cccc21]

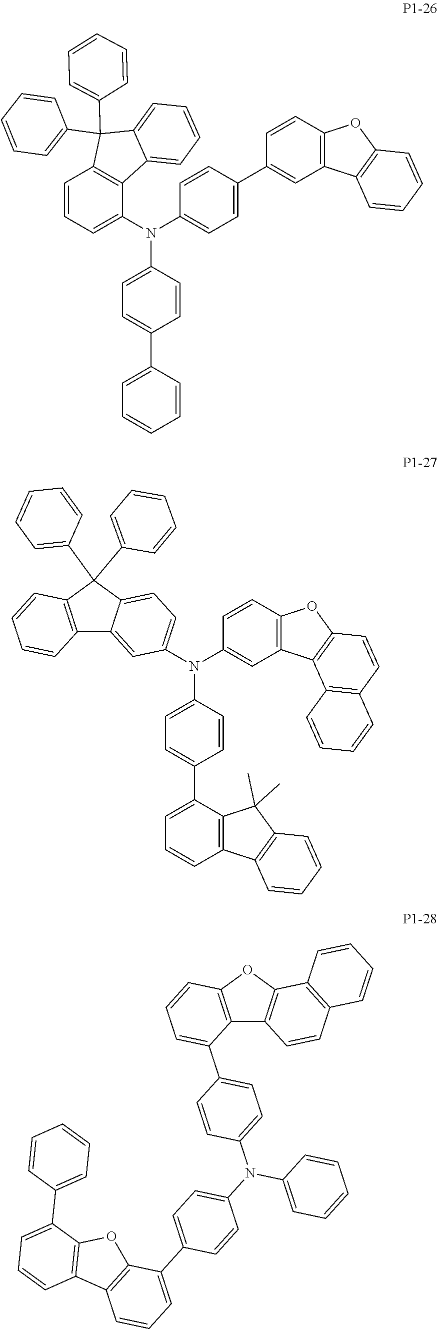 [SMILES: c1ccc(-c2ccc(N(c3ccc(-c4ccc5oc6ccccc6c5c4)cc3)c3cccc4c3-c3ccccc3C4(c3ccccc3)c3ccccc3)cc2)cc1 ; CC1(C)c2ccccc2-c2cccc(-c3ccc(N(c4ccc5c(c4)-c4ccccc4C5(c4ccccc4)c4ccccc4)c4ccc5oc6ccc7ccccc7c6c5c4)cc3)c21 ; c1ccc(-c2cccc3c2oc2c(-c4ccc(N(c5ccccc5)c5ccc(-c6cccc7oc8c9ccccc9ccc8c67)cc5)cc4)cccc23)cc1]

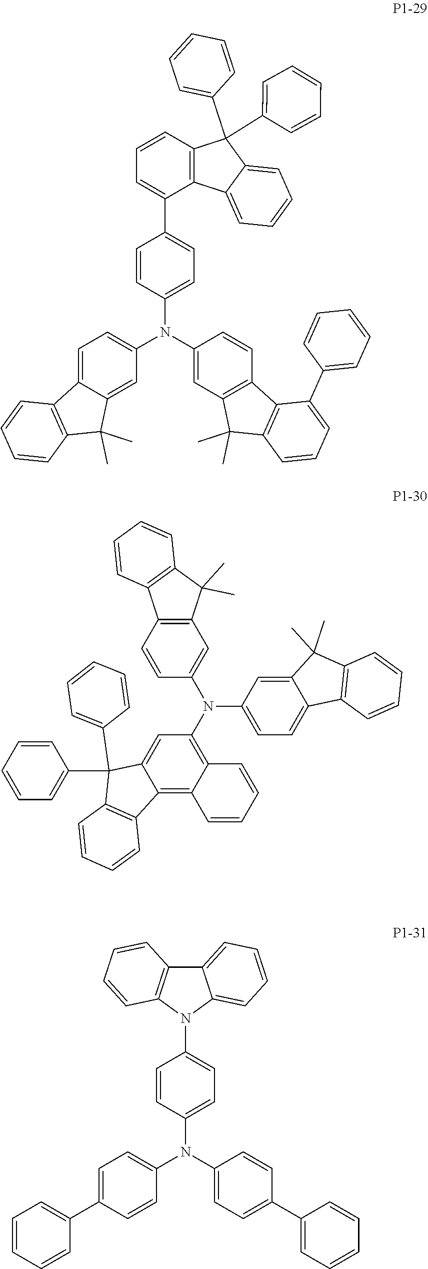 [SMILES: CC1(C)c2ccccc2-c2ccc(N(c3ccc(-c4cccc5c4-c4ccccc4C5(c4ccccc4)c4ccccc4)cc3)c3ccc4c(c3)C(C)(C)c3cccc(-c5ccccc5)c3-4)cc21 ; CC1(C)c2ccccc2-c2ccc(N(c3ccc4c(c3)C(C)(C)c3ccccc3-4)c3cc4c(c5ccccc35)-c3ccccc3C4(c3ccccc3)c3ccccc3)cc21 ; c1ccc(-c2ccc(N(c3ccc(-c4ccccc4)cc3)c3ccc(-n4c5ccccc5c5ccccc54)cc3)cc2)cc1]

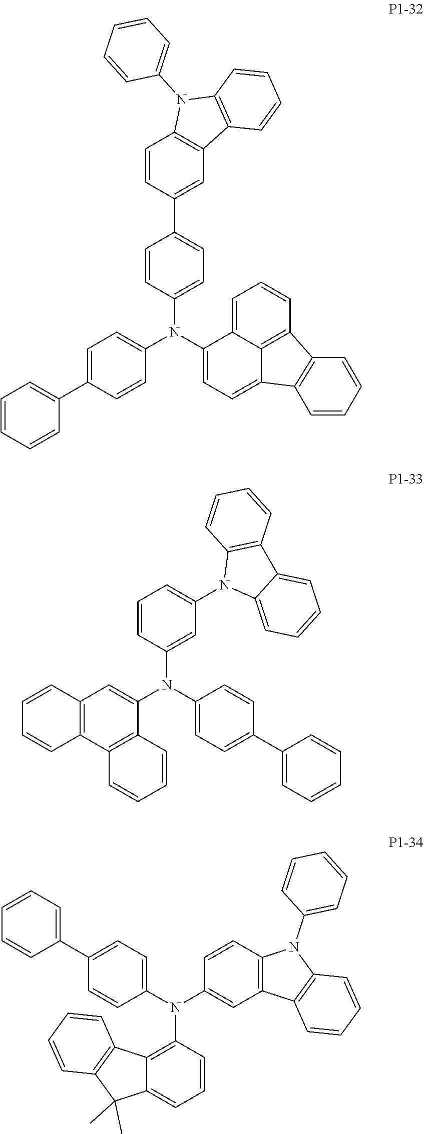 [SMILES: c1ccc(-c2ccc(N(c3ccc(-c4ccc5c(c4)c4ccccc4n5-c4ccccc4)cc3)c3ccc4c5c(cccc35)-c3ccccc3-4)cc2)cc1 ; c1ccc(-c2ccc(N(c3cccc(-n4c5ccccc5c5ccccc54)c3)c3cc4ccccc4c4ccccc34)cc2)cc1 ; CC1(C)c2ccccc2-c2c(N(c3ccc(-c4ccccc4)cc3)c3ccc4c(c3)c3ccccc3n4-c3ccccc3)cccc21]

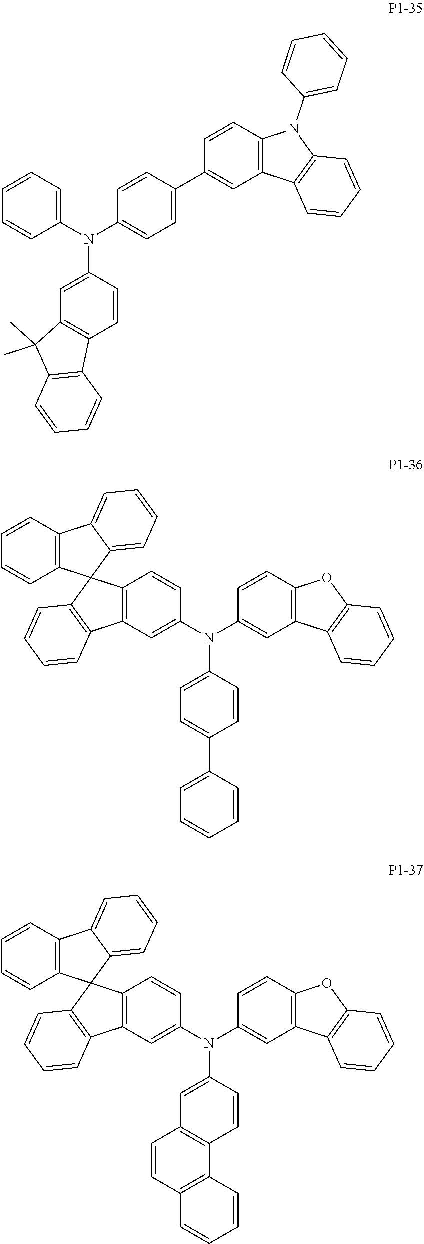 [SMILES: CC1(C)c2ccccc2-c2ccc(N(c3ccccc3)c3ccc(-c4ccc5c(c4)c4ccccc4n5-c4ccccc4)cc3)cc21 ; c1ccc(-c2ccc(N(c3ccc4c(c3)-c3ccccc3C43c4ccccc4-c4ccccc43)c3ccc4oc5ccccc5c4c3)cc2)cc1 ; c1ccc2c(c1)-c1ccccc1C21c2ccccc2-c2cc(N(c3ccc4c(ccc5ccccc54)c3)c3ccc4oc5ccccc5c4c3)ccc21]

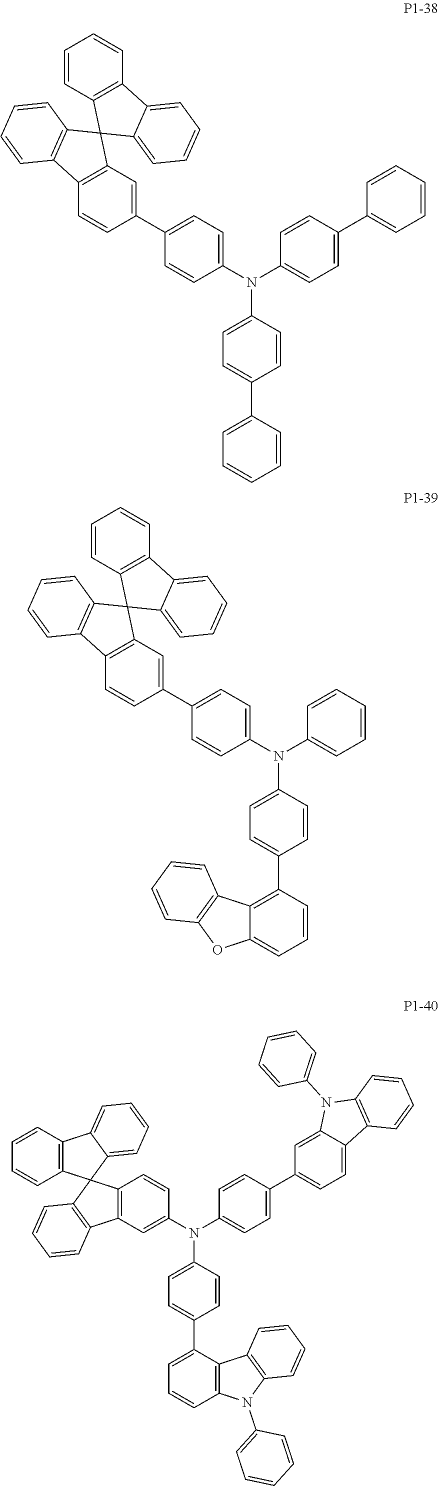 [SMILES: c1ccc(-c2ccc(N(c3ccc(-c4ccccc4)cc3)c3ccc(-c4ccc5c(c4)C4(c6ccccc6-c6ccccc64)c4ccccc4-5)cc3)cc2)cc1 ; c1ccc(N(c2ccc(-c3ccc4c(c3)C3(c5ccccc5-c5ccccc53)c3ccccc3-4)cc2)c2ccc(-c3cccc4oc5ccccc5c34)cc2)cc1 ; c1ccc(-n2c3ccccc3c3ccc(-c4ccc(N(c5ccc(-c6cccc7c6c6ccccc6n7-c6ccccc6)cc5)c5ccc6c(c5)-c5ccccc5C65c6ccccc6-c6ccccc65)cc4)cc32)cc1]

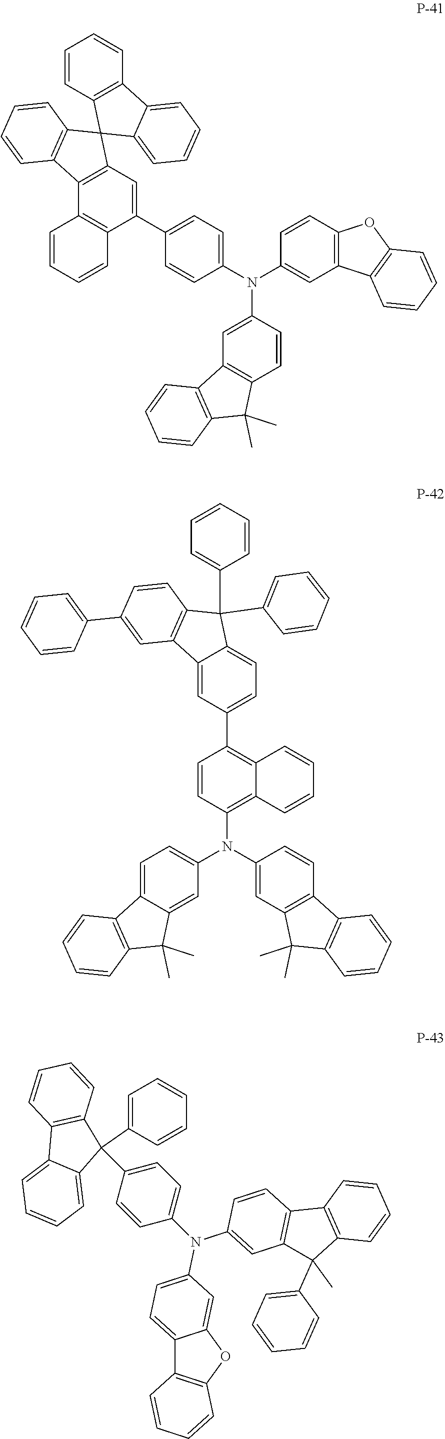 [SMILES: CC1(C)c2ccccc2-c2cc(N(c3ccc(-c4cc5c(c6ccccc46)-c4ccccc4C54c5ccccc5-c5ccccc54)cc3)c3ccc4oc5ccccc5c4c3)ccc21 ; CC1(C)c2ccccc2-c2ccc(N(c3ccc4c(c3)C(C)(C)c3ccccc3-4)c3ccc(-c4ccc5c(c4)-c4cc(-c6ccccc6)ccc4C5(c4ccccc4)c4ccccc4)c4ccccc34)cc21 ; CC1(c2ccccc2)c2ccccc2-c2ccc(N(c3ccc(C4(c5ccccc5)c5ccccc5-c5ccccc54)cc3)c3ccc4c(c3)oc3ccccc34)cc21]

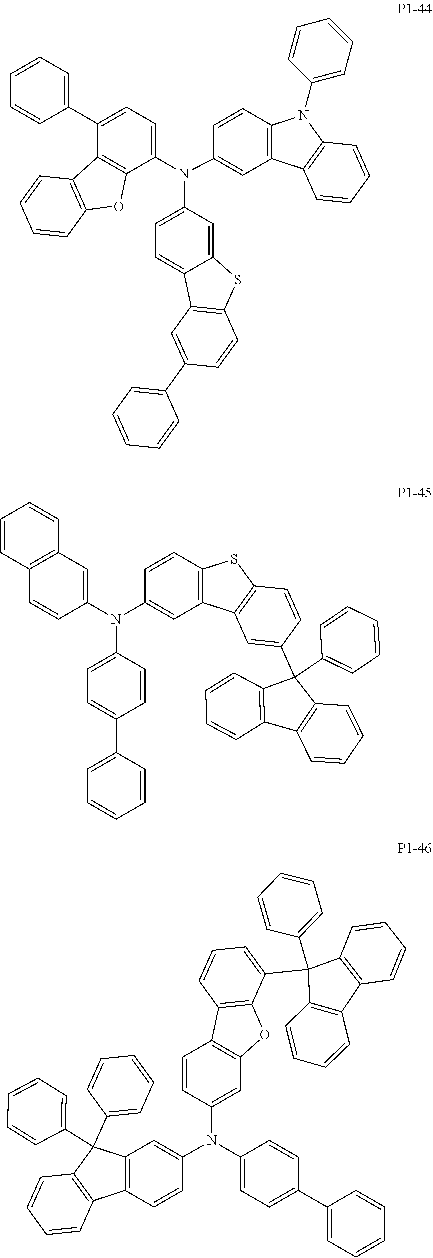 [SMILES: c1ccc(-c2ccc3sc4cc(N(c5ccc6c(c5)c5ccccc5n6-c5ccccc5)c5ccc(-c6ccccc6)c6c5oc5ccccc56)ccc4c3c2)cc1 ; c1ccc(-c2ccc(N(c3ccc4ccccc4c3)c3ccc4sc5ccc(C6(c7ccccc7)c7ccccc7-c7ccccc76)cc5c4c3)cc2)cc1 ; c1ccc(-c2ccc(N(c3ccc4c(c3)C(c3ccccc3)(c3ccccc3)c3ccccc3-4)c3ccc4c(c3)oc3c(C5(c6ccccc6)c6ccccc6-c6ccccc65)cccc34)cc2)cc1]

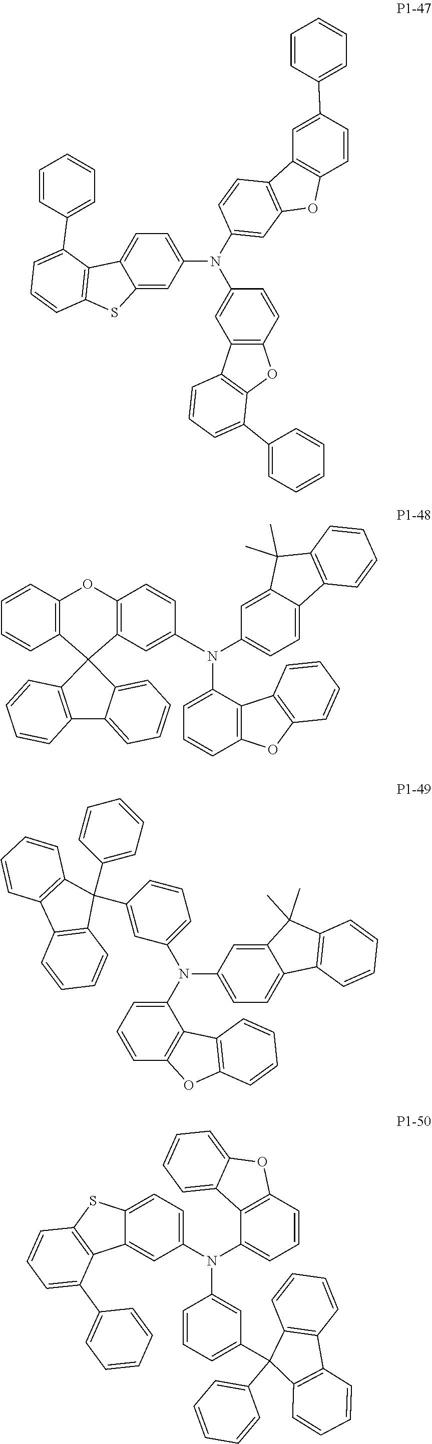

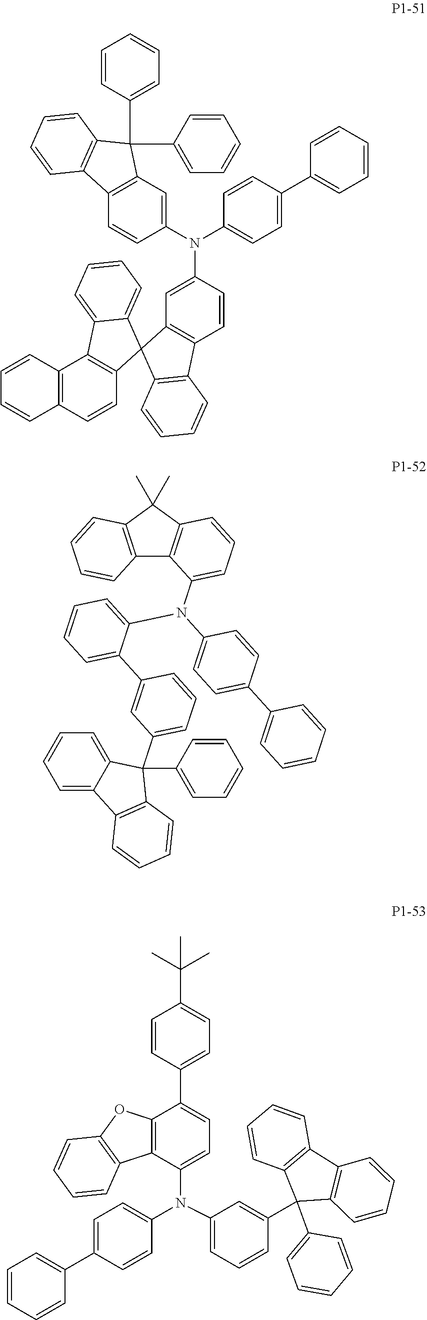

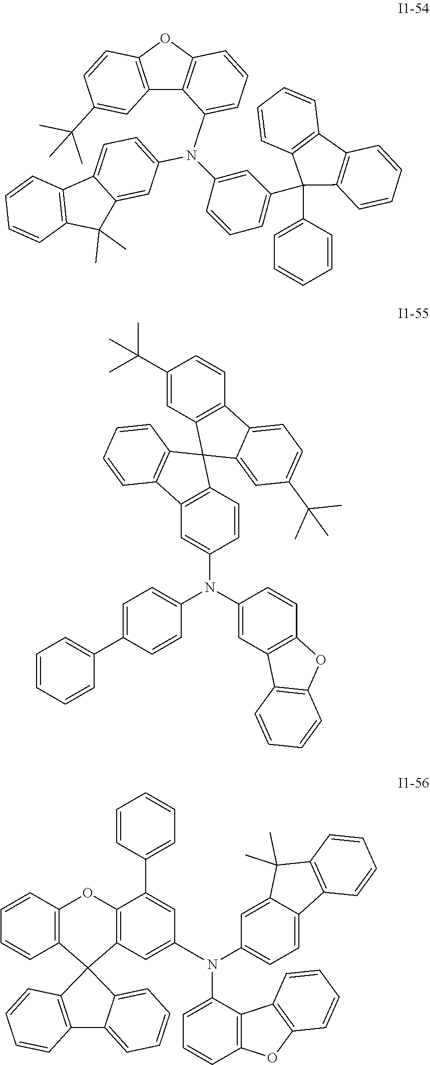 [SMILES: CC(C)(C)c1ccc2oc3cccc(N(c4cccc(C5(c6ccccc6)c6ccccc6-c6ccccc65)c4)c4ccc5c(c4)C(C)(C)c4ccccc4-5)c3c2c1 ; CC(C)(C)c1ccc2c(c1)C1(c3ccccc3-c3cc(N(c4ccc(-c5ccccc5)cc4)c4ccc5oc6ccccc6c5c4)ccc31)c1cc(C(C)(C)C)ccc1-2 ; CC1(C)c2ccccc2-c2ccc(N(c3cc(-c4ccccc4)c4c(c3)C3(c5ccccc5O4)c4ccccc4-c4ccccc43)c3cccc4oc5ccccc5c34)cc21]

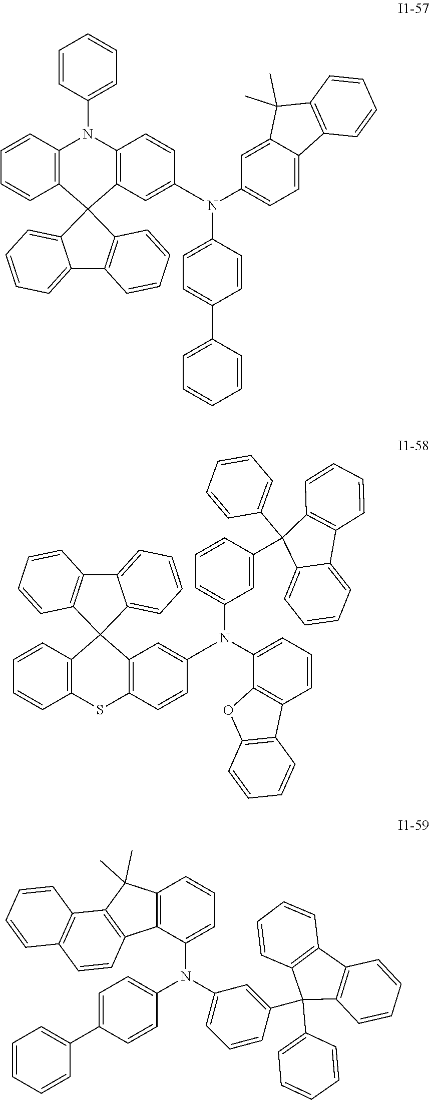 [SMILES: CC1(C)c2ccccc2-c2ccc(N(c3ccc(-c4ccccc4)cc3)c3ccc4c(c3)C3(c5ccccc5-c5ccccc53)c3ccccc3N4c3ccccc3)cc21 ; c1ccc(C2(c3cccc(N(c4ccc5c(c4)C4(c6ccccc6S5)c5ccccc5-c5ccccc54)c4cccc5c4oc4ccccc45)c3)c3ccccc3-c3ccccc32)cc1 ; CC1(C)c2cccc(N(c3ccc(-c4ccccc4)cc3)c3cccc(C4(c5ccccc5)c5ccccc5-c5ccccc54)c3)c2-c2ccc3ccccc3c21]

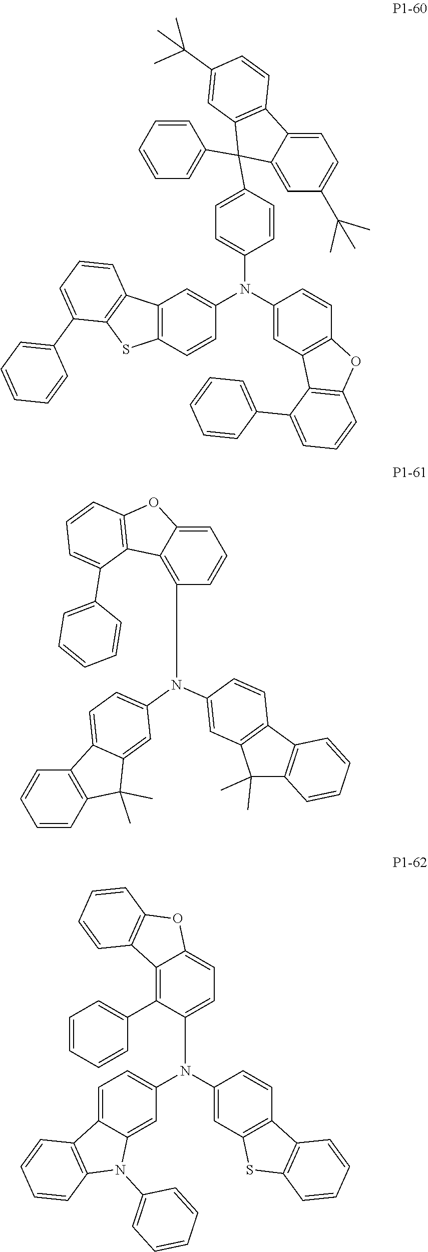 [SMILES: CC(C)(C)c1ccc2c(c1)C(c1ccccc1)(c1ccc(N(c3ccc4sc5c(-c6ccccc6)cccc5c4c3)c3ccc4oc5cccc(-c6ccccc6)c5c4c3)cc1)c1cc(C(C)(C)C)ccc1-2 ; CC1(C)c2ccccc2-c2ccc(N(c3ccc4c(c3)C(C)(C)c3ccccc3-4)c3cccc4oc5cccc(-c6ccccc6)c5c34)cc21 ; c1ccc(-c2c(N(c3ccc4c(c3)sc3ccccc34)c3ccc4c5ccccc5n(-c5ccccc5)c4c3)ccc3oc4ccccc4c23)cc1]

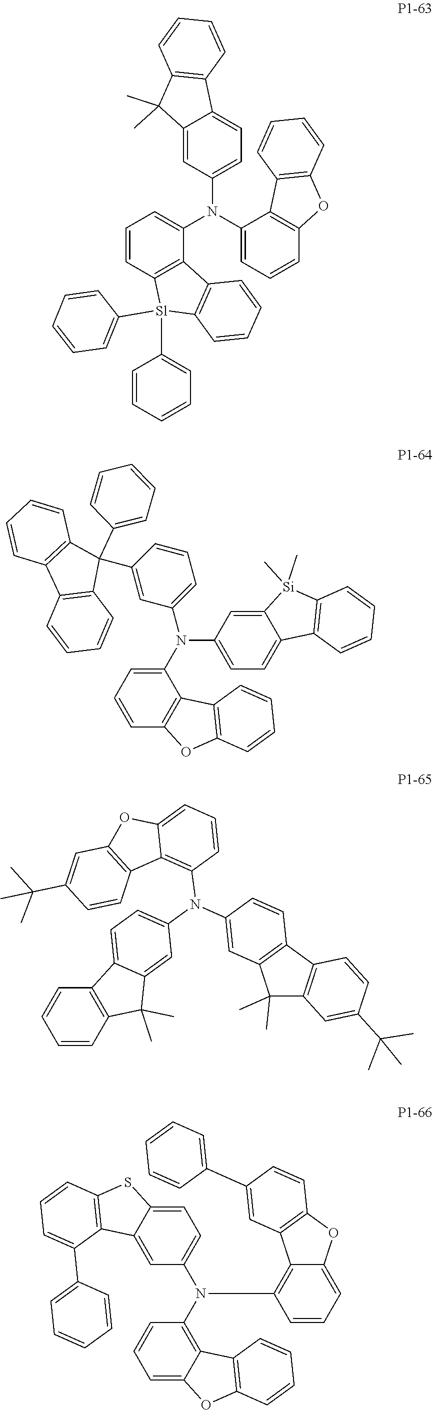

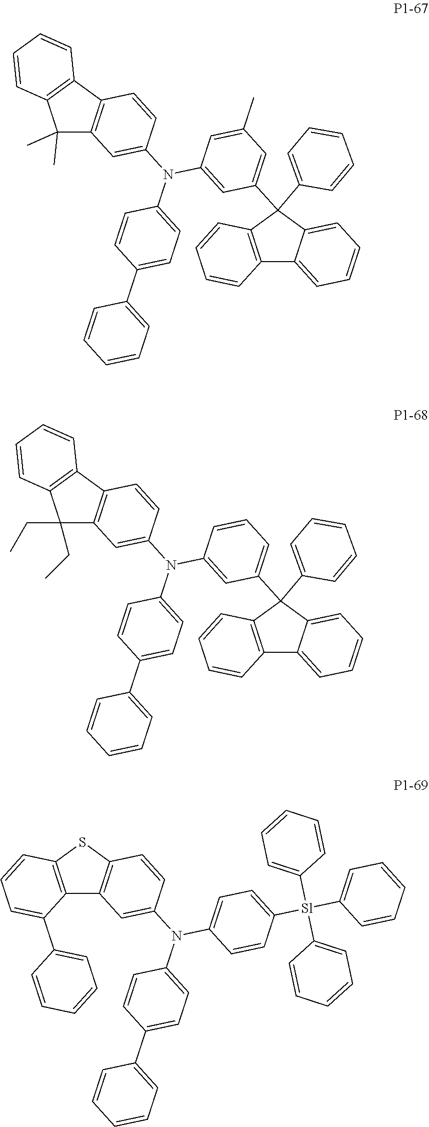

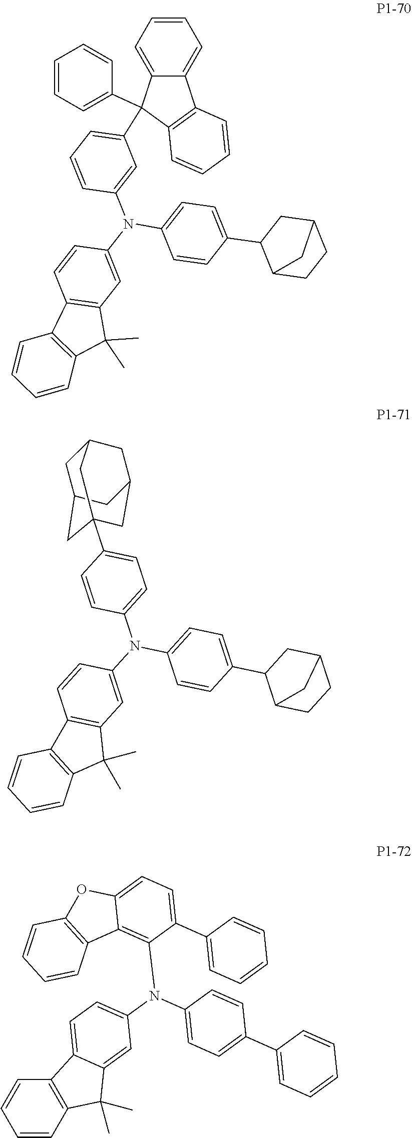 [SMILES: CC1(C)c2ccccc2-c2ccc(N(c3ccc(C4CC5CCC4C5)cc3)c3cccc(C4(c5ccccc5)c5ccccc5-c5ccccc54)c3)cc21 ; CC1(C)c2ccccc2-c2ccc(N(c3ccc(C4CC5CCC4C5)cc3)c3ccc(C45CC6CC(CC(C6)C4)C5)cc3)cc21 ; CC1(C)c2ccccc2-c2ccc(N(c3ccc(-c4ccccc4)cc3)c3c(-c4ccccc4)ccc4oc5ccccc5c34)cc21]

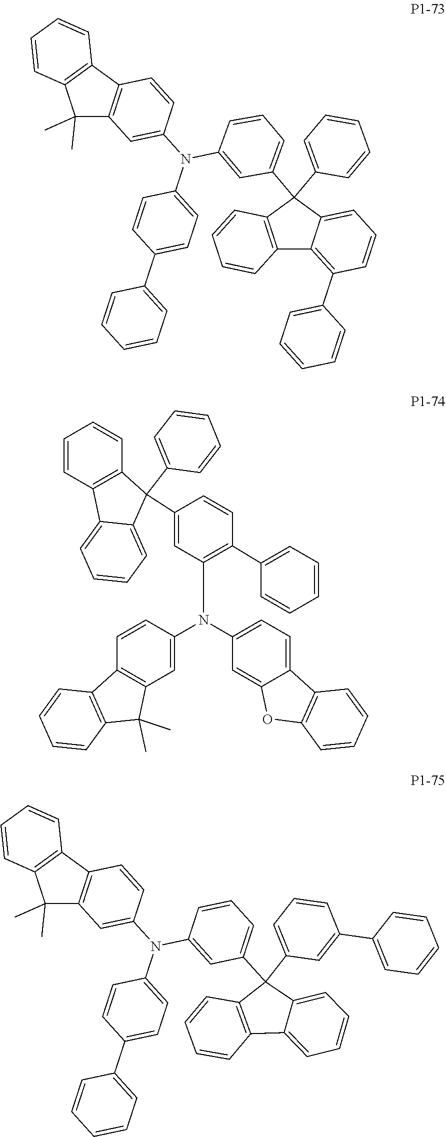 [SMILES: CC1(C)c2ccccc2-c2ccc(N(c3ccc(-c4ccccc4)cc3)c3cccc(C4(c5ccccc5)c5ccccc5-c5c(-c6ccccc6)cccc54)c3)cc21 ; CC1(C)c2ccccc2-c2ccc(N(c3ccc4c(c3)oc3ccccc34)c3cc(C4(c5ccccc5)c5ccccc5-c5ccccc54)ccc3-c3ccccc3)cc21 ; CC1(C)c2ccccc2-c2ccc(N(c3ccc(-c4ccccc4)cc3)c3cccc(C4(c5cccc(-c6ccccc6)c5)c5ccccc5-c5ccccc54)c3)cc21]

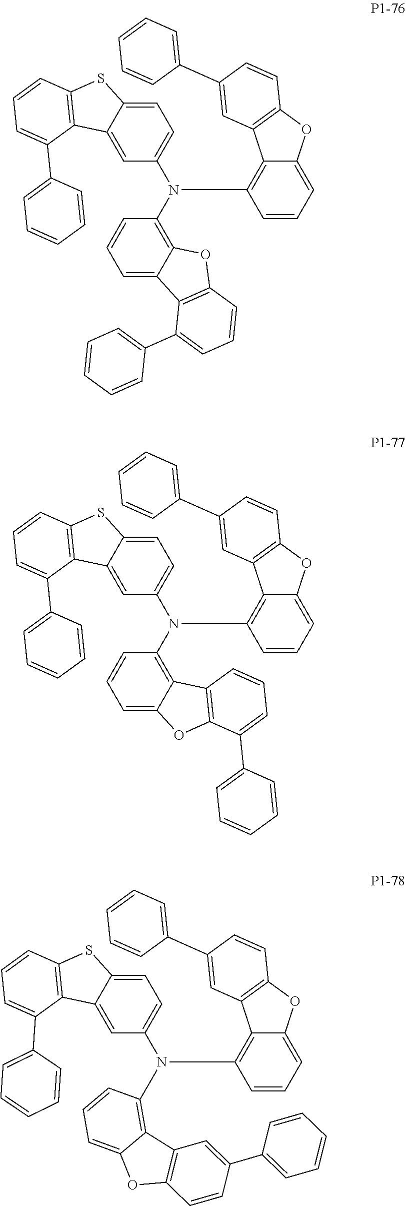 [SMILES: c1ccc(-c2ccc3oc4cccc(N(c5ccc6sc7cccc(-c8ccccc8)c7c6c5)c5cccc6c5oc5cccc(-c7ccccc7)c56)c4c3c2)cc1 ; c1ccc(-c2ccc3oc4cccc(N(c5ccc6sc7cccc(-c8ccccc8)c7c6c5)c5cccc6oc7c(-c8ccccc8)cccc7c56)c4c3c2)cc1 ; c1ccc(-c2ccc3oc4cccc(N(c5ccc6sc7cccc(-c8ccccc8)c7c6c5)c5cccc6oc7ccc(-c8ccccc8)cc7c56)c4c3c2)cc1]

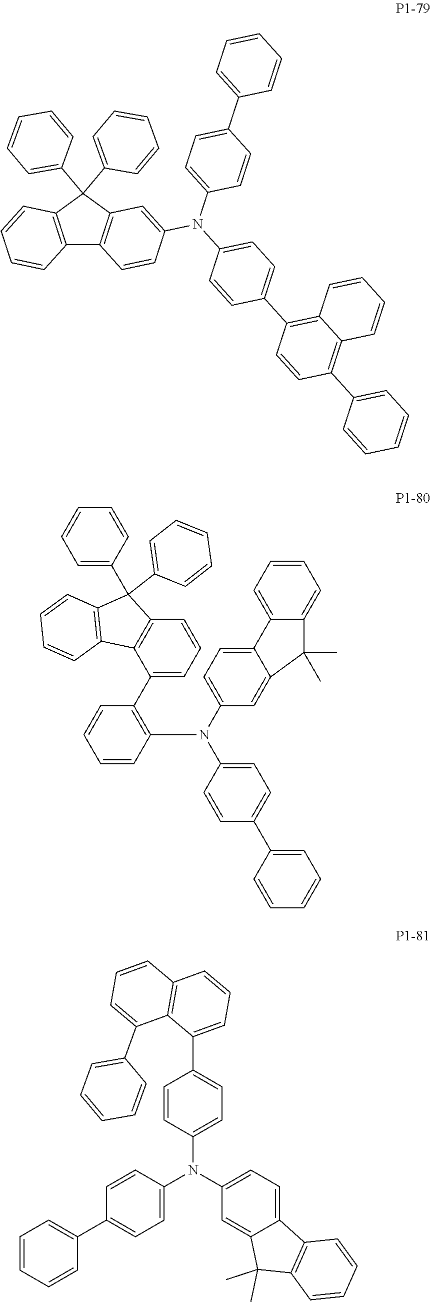 [SMILES: c1ccc(-c2ccc(N(c3ccc(-c4ccc(-c5ccccc5)c5ccccc45)cc3)c3ccc4c(c3)C(c3ccccc3)(c3ccccc3)c3ccccc3-4)cc2)cc1 ; CC1(C)c2ccccc2-c2ccc(N(c3ccc(-c4ccccc4)cc3)c3ccccc3-c3cccc4c3-c3ccccc3C4(c3ccccc3)c3ccccc3)cc21 ; CC1(C)c2ccccc2-c2ccc(N(c3ccc(-c4ccccc4)cc3)c3ccc(-c4cccc5cccc(-c6ccccc6)c45)cc3)cc21]

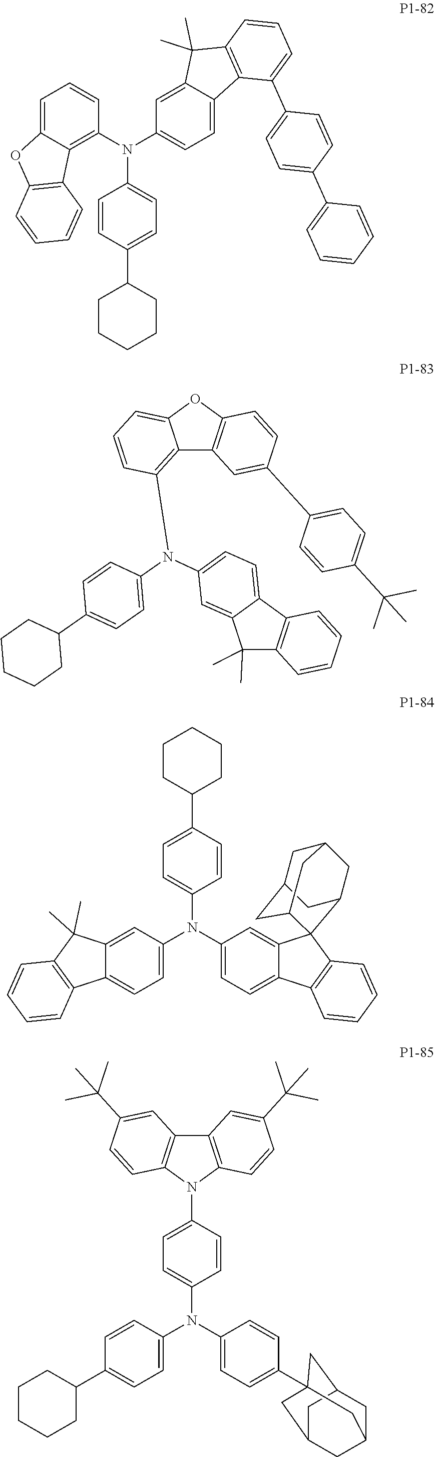 [SMILES: CC1(C)c2cc(N(c3ccc(C4CCCCC4)cc3)c3cccc4oc5ccccc5c34)ccc2-c2c(-c3ccc(-c4ccccc4)cc3)cccc21 ; CC(C)(C)c1ccc(-c2ccc3oc4cccc(N(c5ccc(C6CCCCC6)cc5)c5ccc6c(c5)C(C)(C)c5ccccc5-6)c4c3c2)cc1 ; CC1(C)c2ccccc2-c2ccc(N(c3ccc(C4CCCCC4)cc3)c3ccc4c(c3)C3(c5ccccc5-4)C4CC5CC(C4)CC3C5)cc21 ; CC(C)(C)c1ccc2c(c1)c1cc(C(C)(C)C)ccc1n2-c1ccc(N(c2ccc(C3CCCCC3)cc2)c2ccc(C34CC5CC(CC(C5)C3)C4)cc2)cc1]

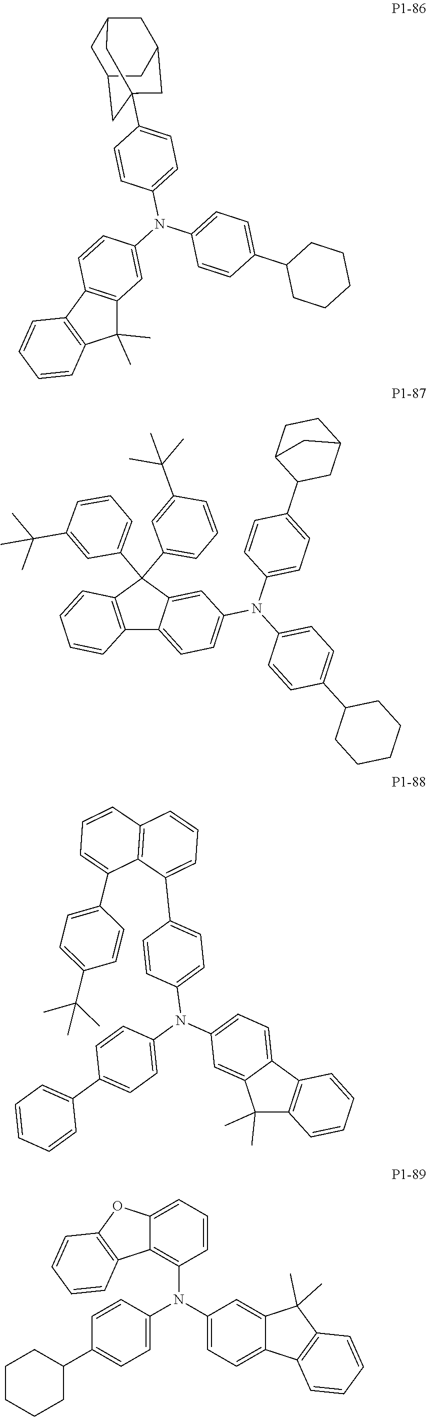 [SMILES: CC1(C)c2ccccc2-c2ccc(N(c3ccc(C4CCCCC4)cc3)c3ccc(C45CC6CC(CC(C6)C4)C5)cc3)cc21 ; CC(C)(C)c1cccc(C2(c3cccc(C(C)(C)C)c3)c3ccccc3-c3ccc(N(c4ccc(C5CCCCC5)cc4)c4ccc(C5CC6CCC5C6)cc4)cc32)c1 ; CC(C)(C)c1ccc(-c2cccc3cccc(-c4ccc(N(c5ccc(-c6ccccc6)cc5)c5ccc6c(c5)C(C)(C)c5ccccc5-6)cc4)c23)cc1 ; CC1(C)c2ccccc2-c2ccc(N(c3ccc(C4CCCCC4)cc3)c3cccc4oc5ccccc5c34)cc21]

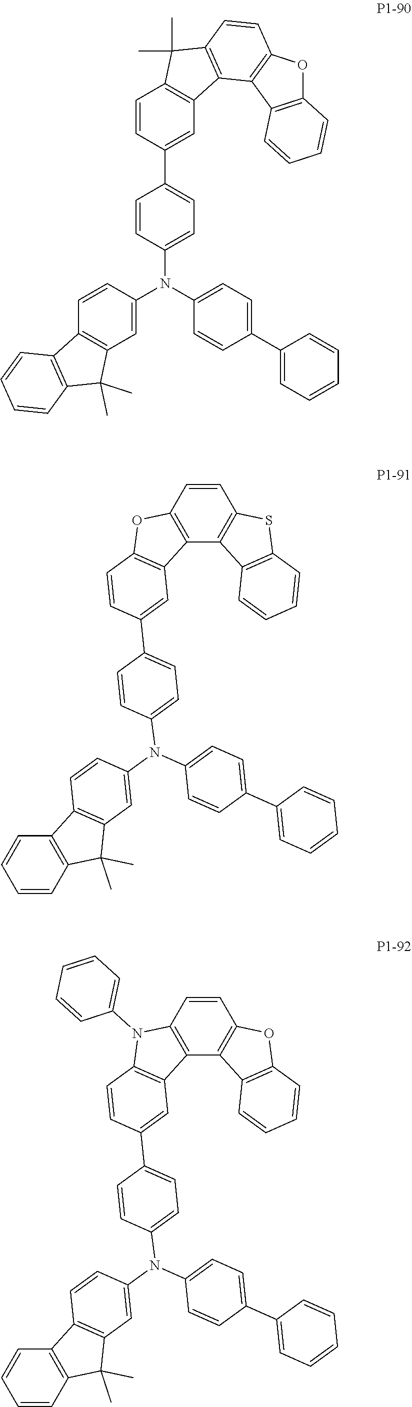 [SMILES: CC1(C)c2ccccc2-c2ccc(N(c3ccc(-c4ccccc4)cc3)c3ccc(-c4ccc5c(c4)-c4c(ccc6oc7ccccc7c46)C5(C)C)cc3)cc21 ; CC1(C)c2ccccc2-c2ccc(N(c3ccc(-c4ccccc4)cc3)c3ccc(-c4ccc5oc6ccc7sc8ccccc8c7c6c5c4)cc3)cc21 ; CC1(C)c2ccccc2-c2ccc(N(c3ccc(-c4ccccc4)cc3)c3ccc(-c4ccc5c(c4)c4c6c(ccc4n5-c4ccccc4)oc4ccccc46)cc3)cc21]

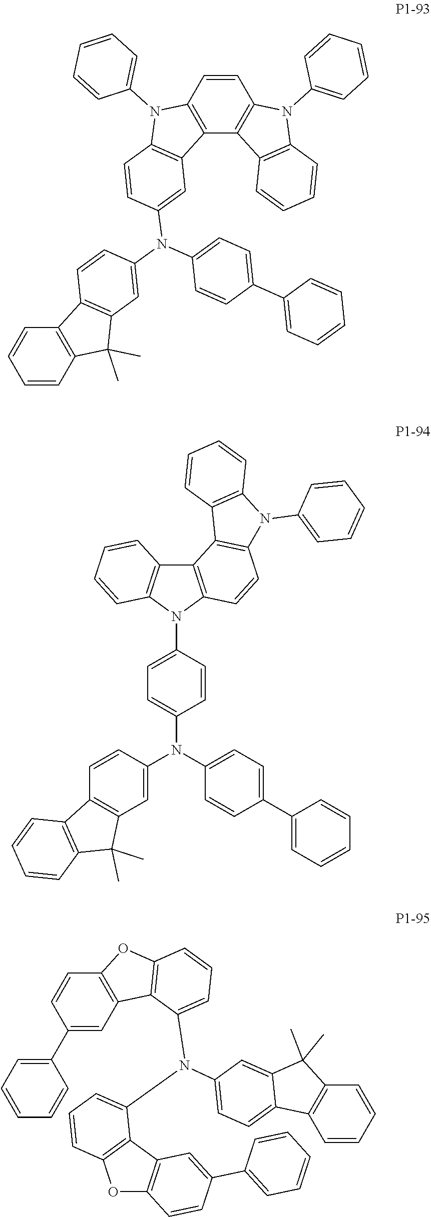 [SMILES: CC1(C)c2ccccc2-c2ccc(N(c3ccc(-c4ccccc4)cc3)c3ccc4c(c3)c3c5c6ccccc6n(-c6ccccc6)c5ccc3n4-c3ccccc3)cc21 ; CC1(C)c2ccccc2-c2ccc(N(c3ccc(-c4ccccc4)cc3)c3ccc(-n4c5ccccc5c5c6c7ccccc7n(-c7ccccc7)c6ccc54)cc3)cc21 ; CC1(C)c2ccccc2-c2ccc(N(c3cccc4oc5ccc(-c6ccccc6)cc5c34)c3cccc4oc5ccc(-c6ccccc6)cc5c34)cc21]

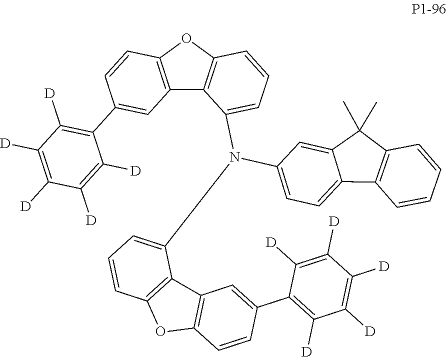 [SMILES: [2H]c1c([2H])c([2H])c(-c2ccc3oc4cccc(N(c5ccc6c(c5)C(C)(C)c5ccccc5-6)c5cccc6oc7ccc(-c8c([2H])c([2H])c([2H])c([2H])c8[2H])cc7c56)c4c3c2)c([2H])c1[2H]]

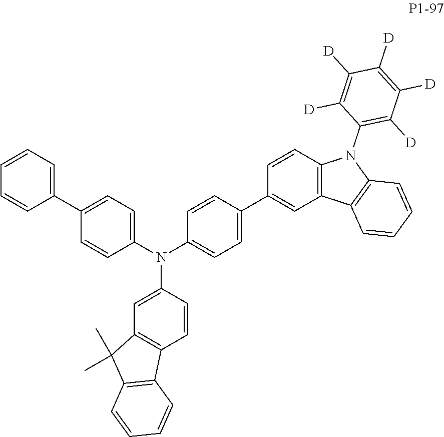 [SMILES: [2H]c1c([2H])c([2H])c(-n2c3ccccc3c3cc(-c4ccc(N(c5ccc(-c6ccccc6)cc5)c5ccc6c(c5)C(C)(C)c5ccccc5-6)cc4)ccc32)c([2H])c1[2H]]

Specifically, the compound represented by Formula 2 may be any one of the following compounds P2-1 to P2-79, but is not limited thereto.

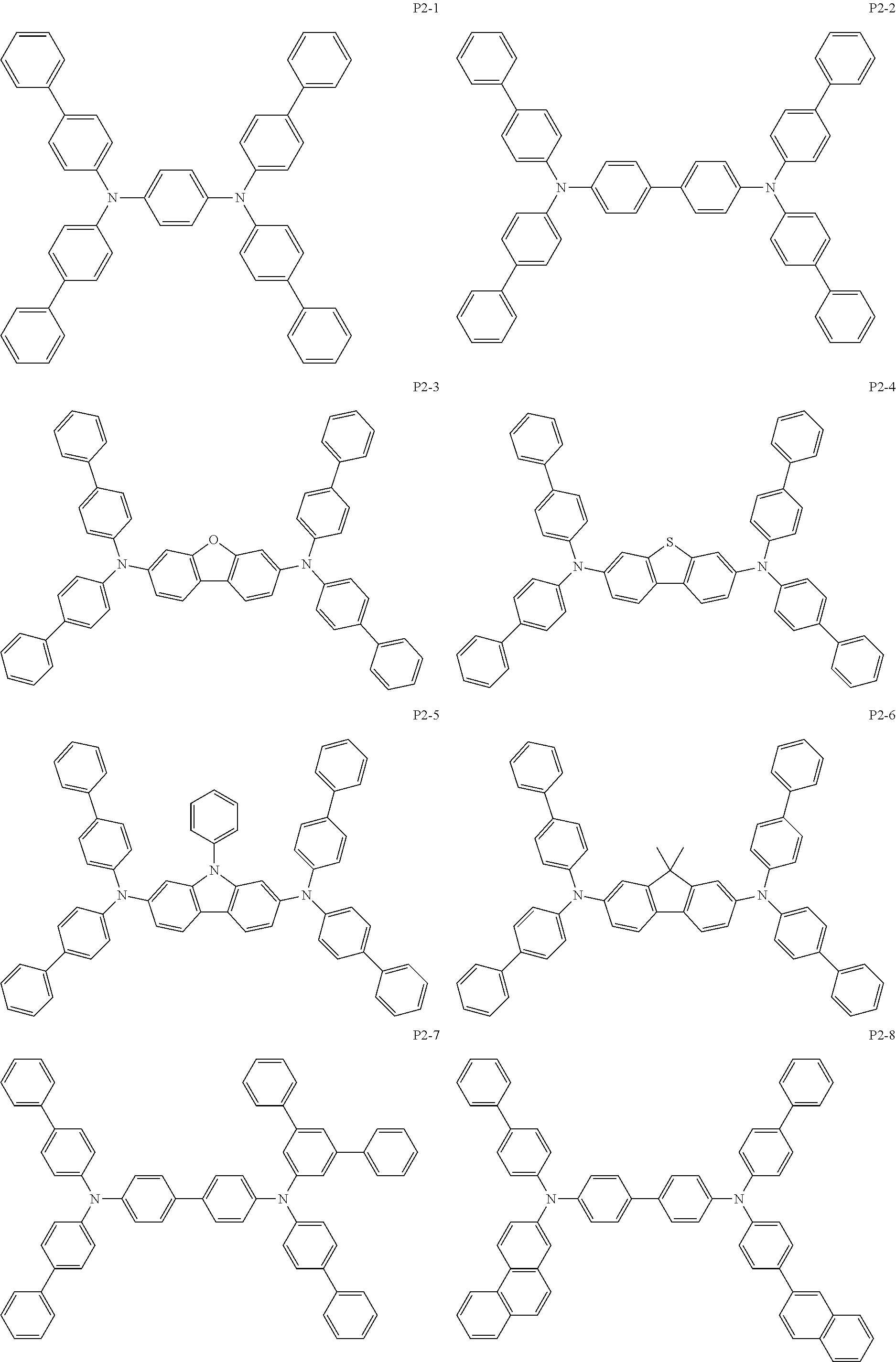

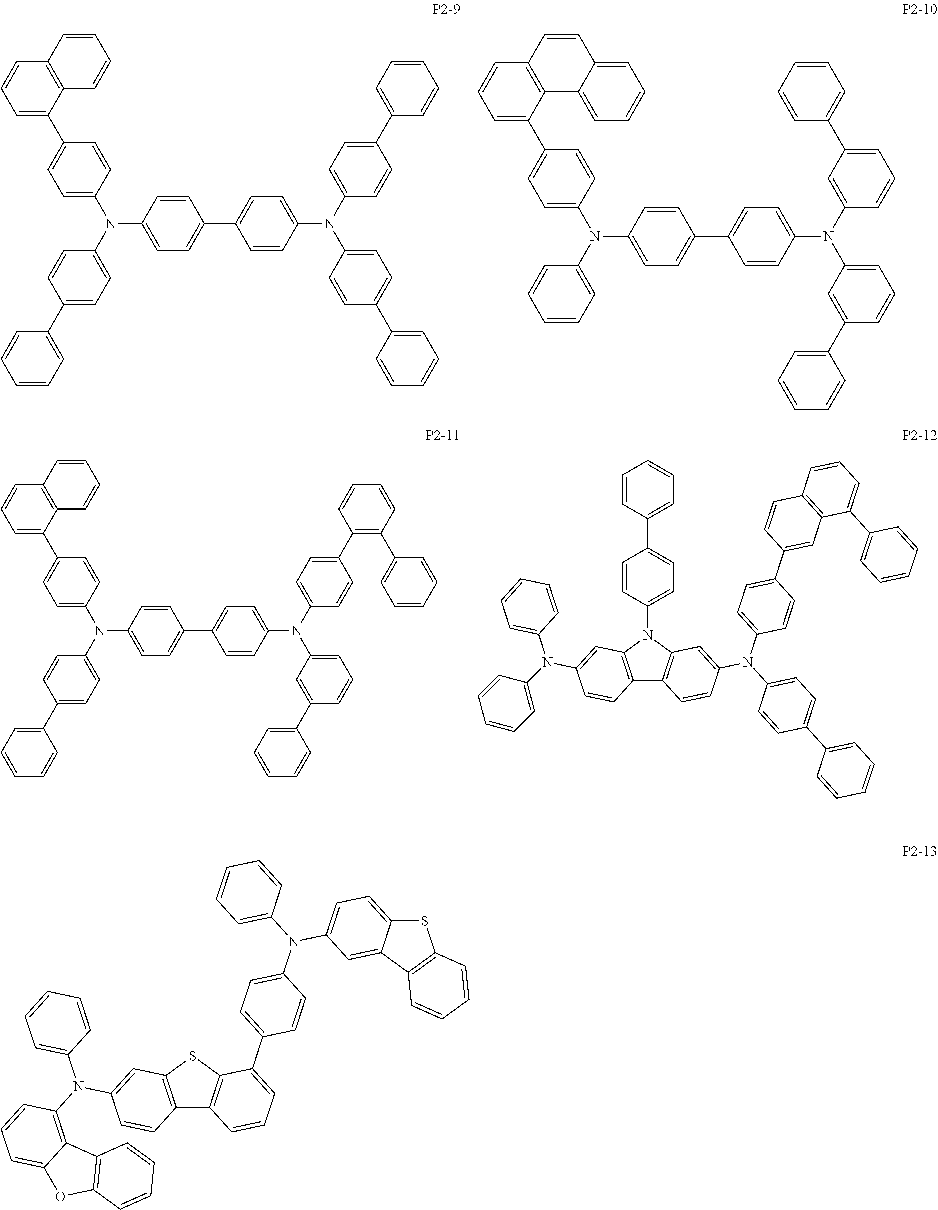

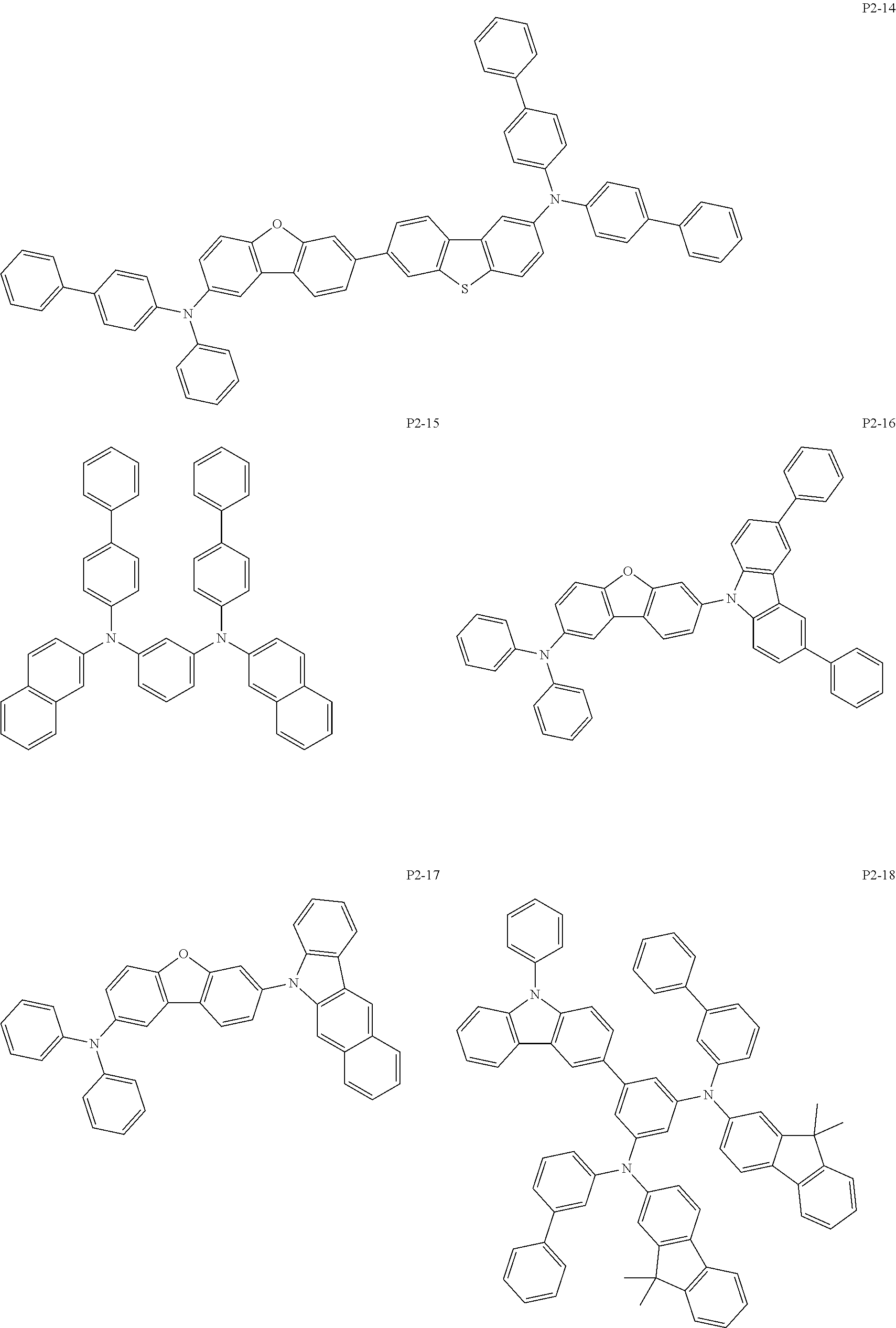

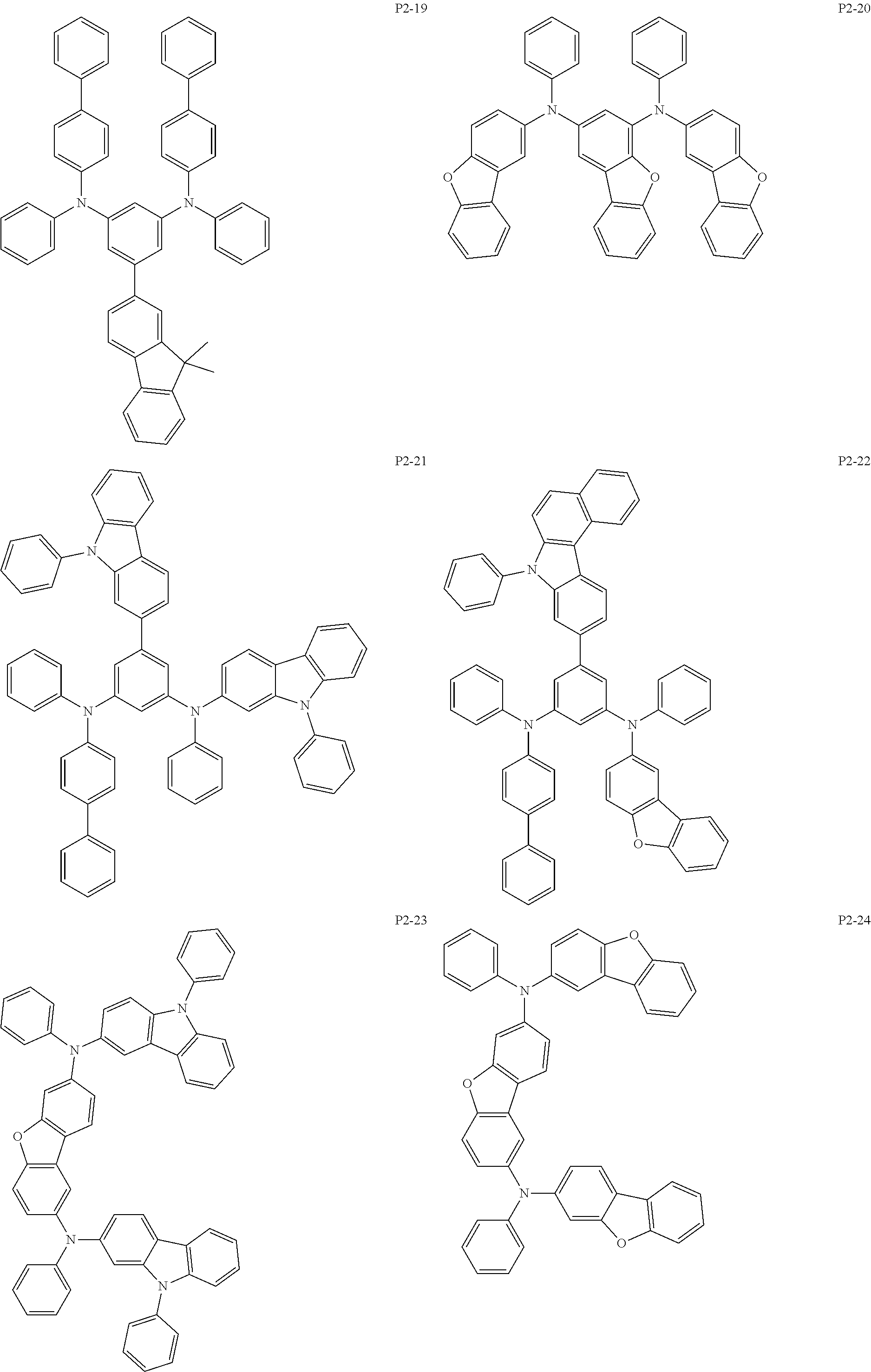

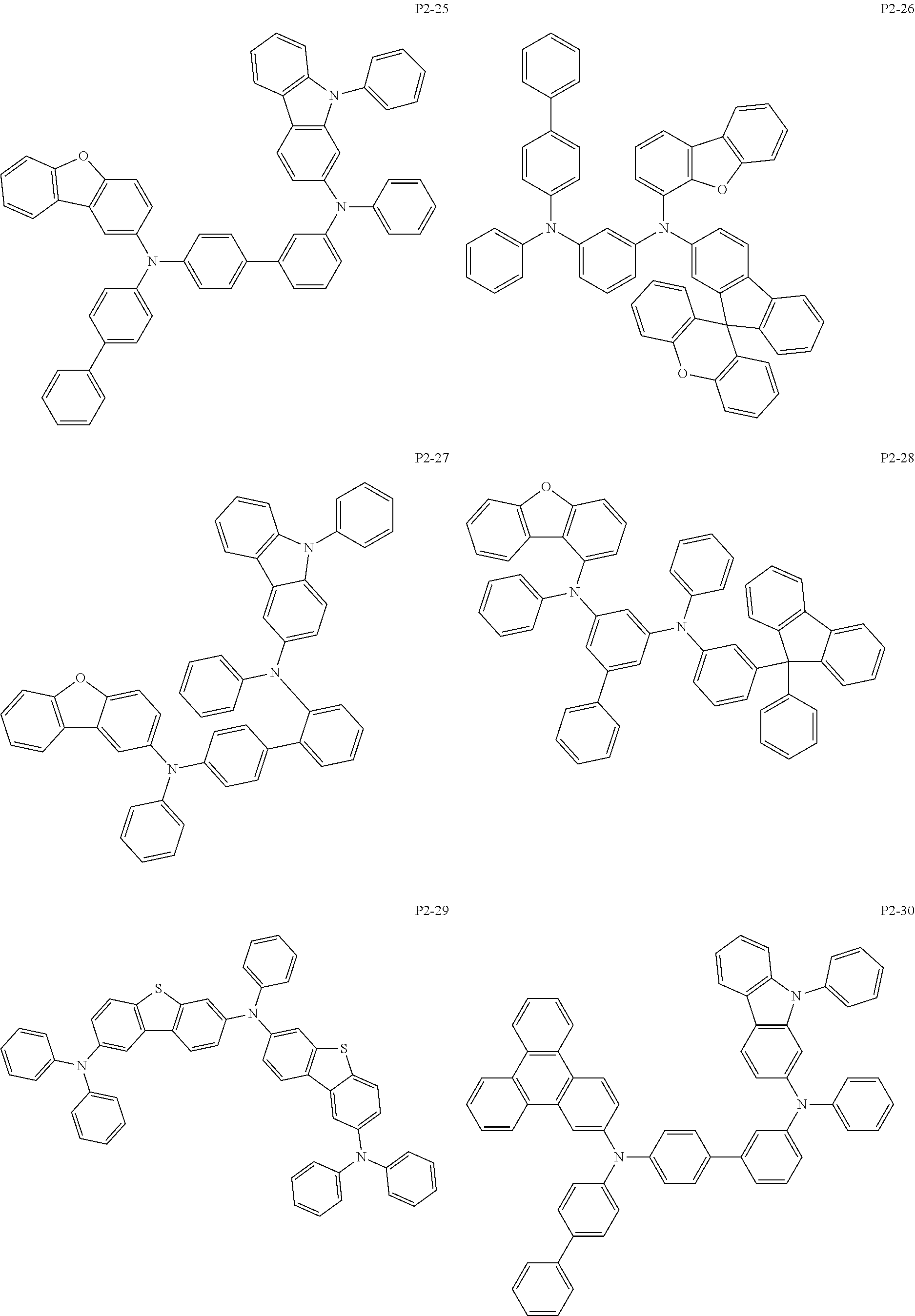

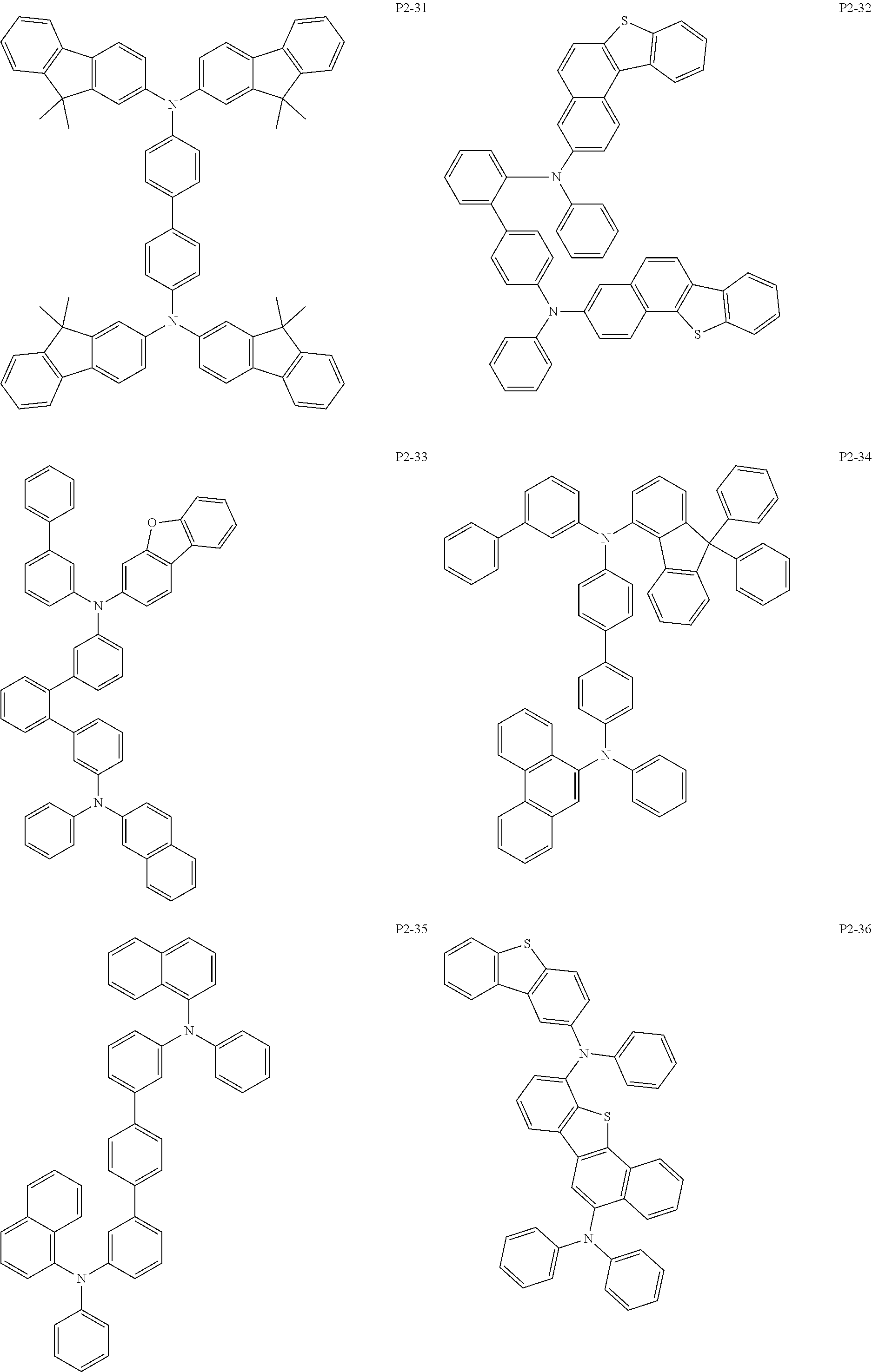

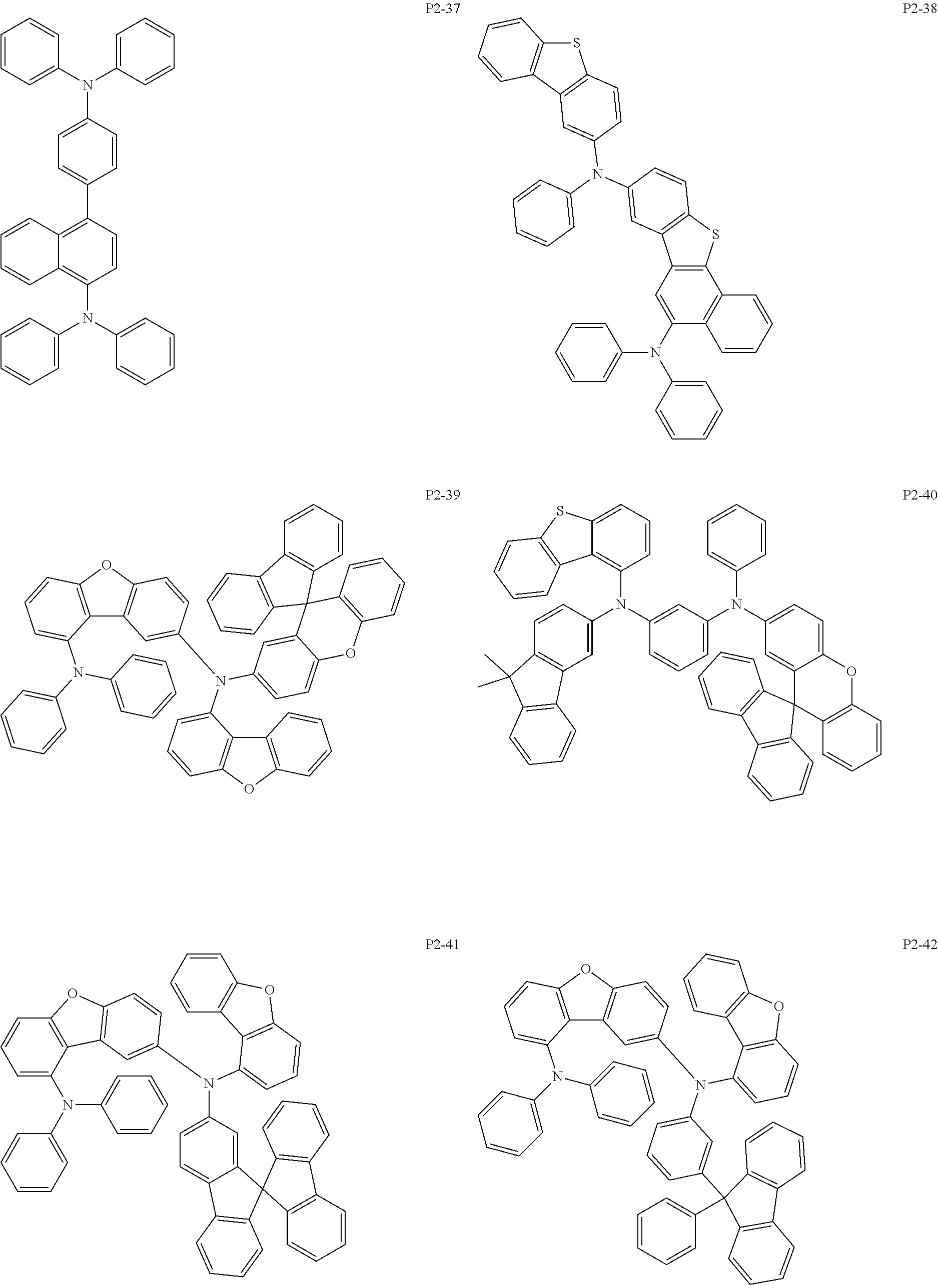

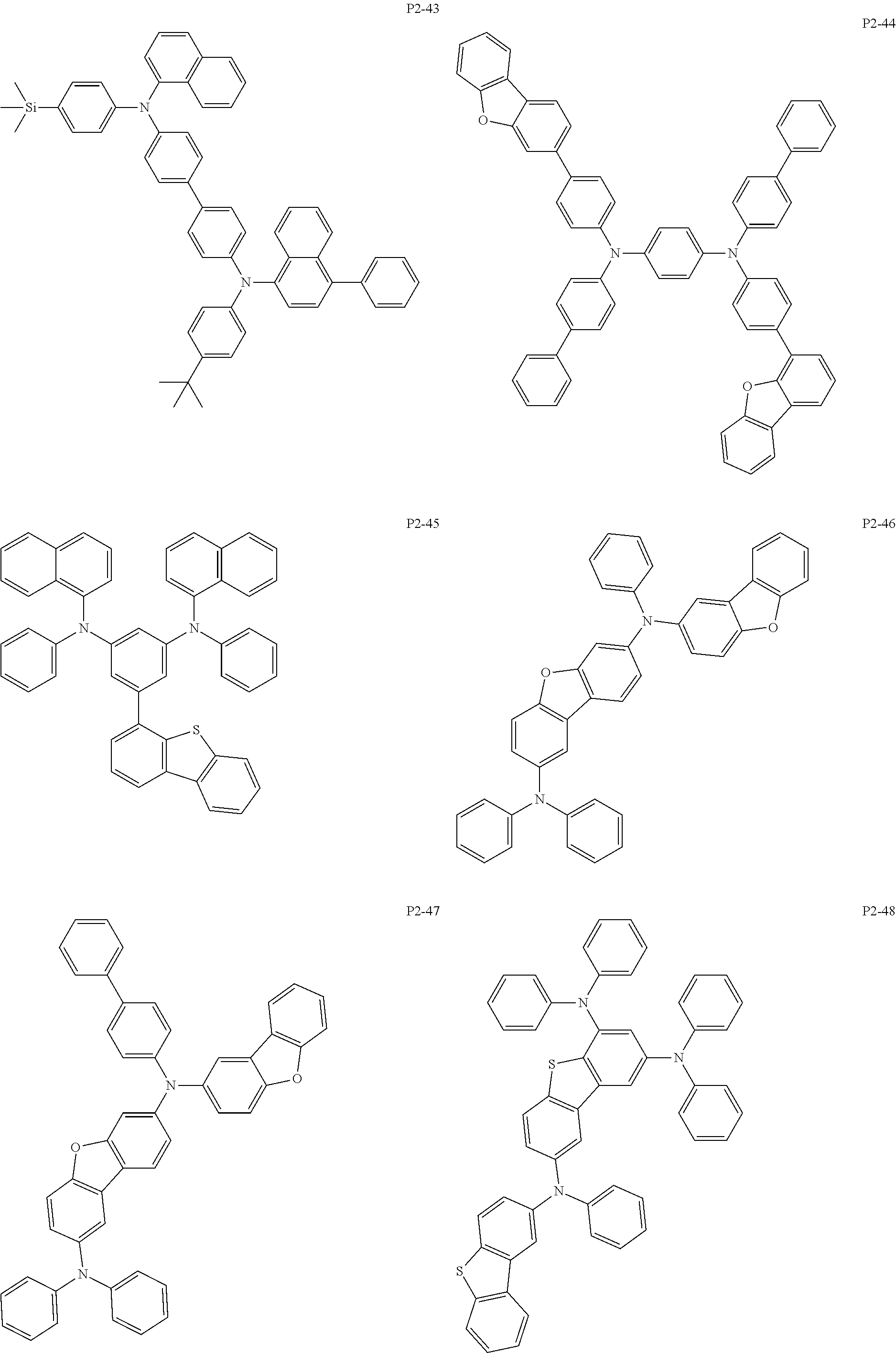

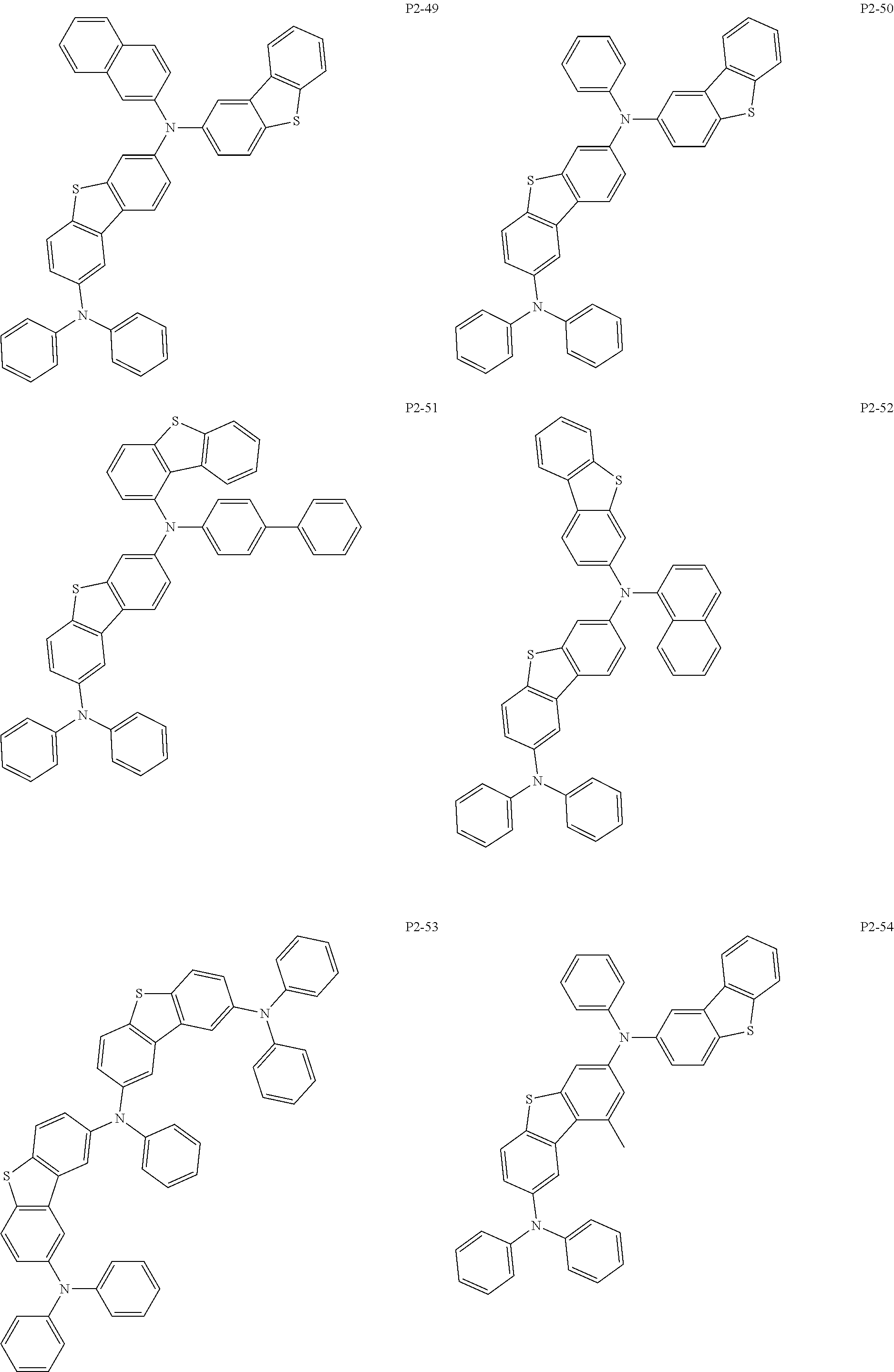 [SMILES: c1ccc(N(c2ccccc2)c2ccc3sc4cc(N(c5ccc6ccccc6c5)c5ccc6sc7ccccc7c6c5)ccc4c3c2)cc1 ; c1ccc(N(c2ccc3c(c2)sc2ccc(N(c4ccccc4)c4ccccc4)cc23)c2ccc3sc4ccccc4c3c2)cc1 ; c1ccc(-c2ccc(N(c3ccc4c(c3)sc3ccc(N(c5ccccc5)c5ccccc5)cc34)c3cccc4sc5ccccc5c34)cc2)cc1 ; c1ccc(N(c2ccccc2)c2ccc3sc4cc(N(c5ccc6c(c5)sc5ccccc56)c5cccc6ccccc56)ccc4c3c2)cc1 ; c1ccc(N(c2ccccc2)c2ccc3sc4ccc(N(c5ccccc5)c5ccc6sc7ccc(N(c8ccccc8)c8ccccc8)cc7c6c5)cc4c3c2)cc1 ; Cc1cc(N(c2ccccc2)c2ccc3sc4ccccc4c3c2)cc2sc3ccc(N(c4ccccc4)c4ccccc4)cc3c12]

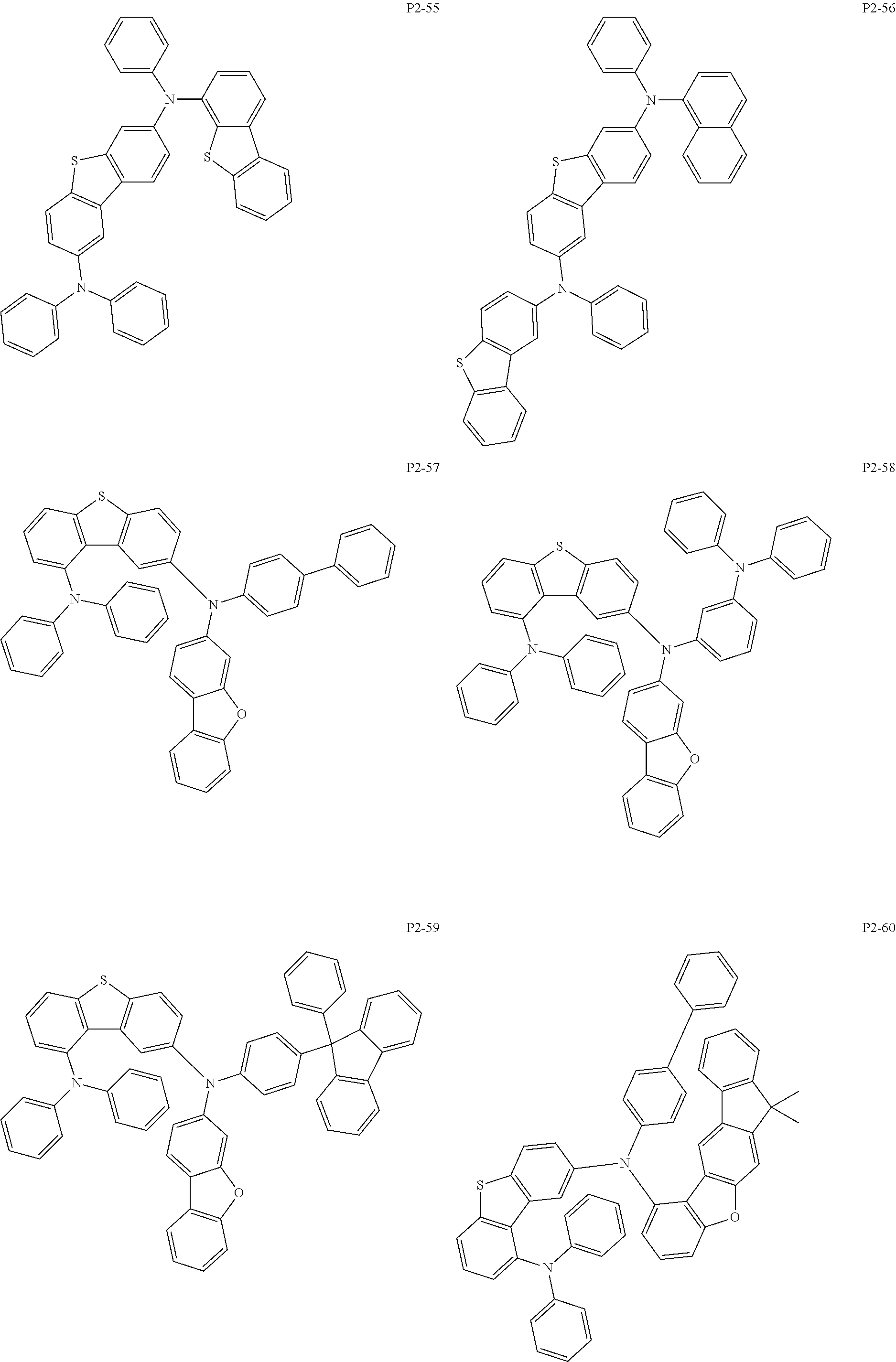

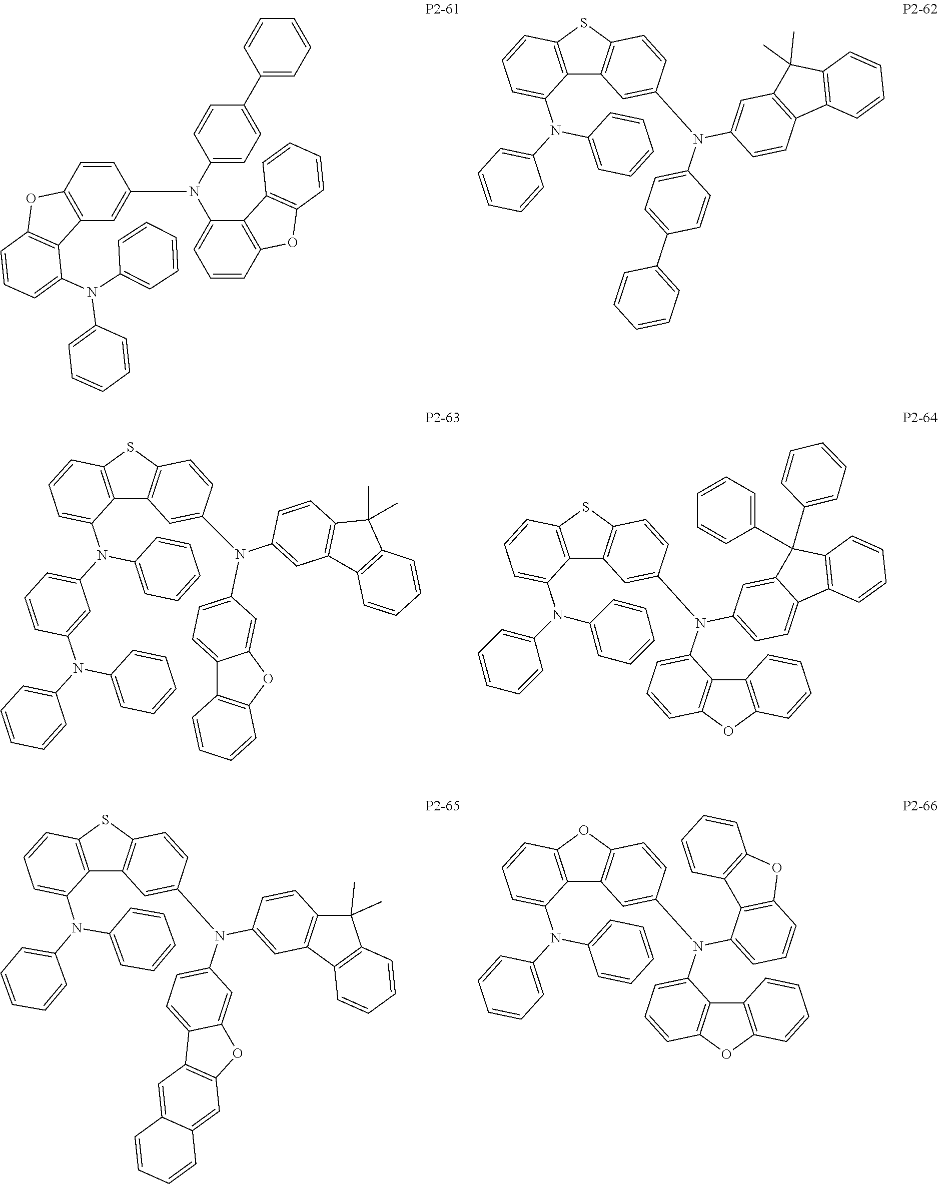

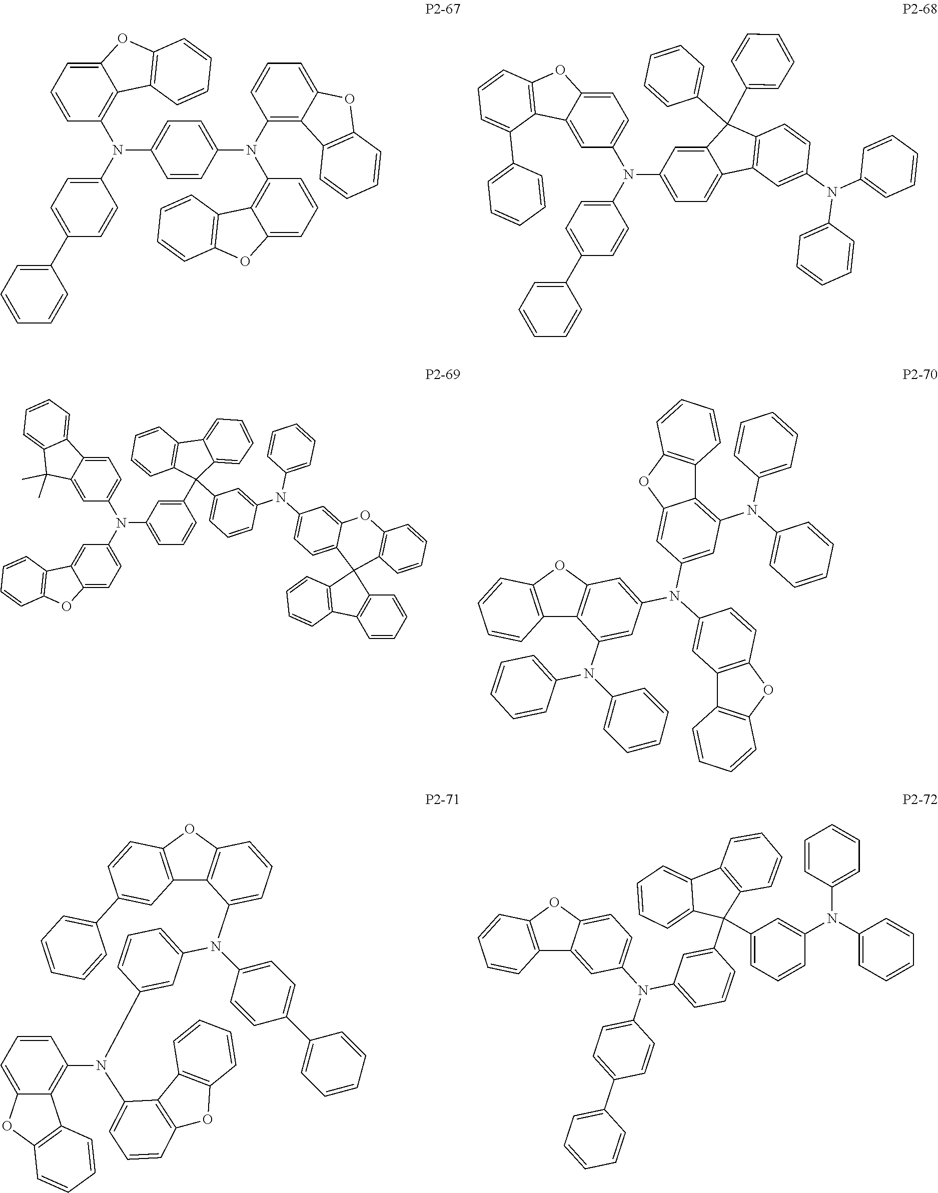

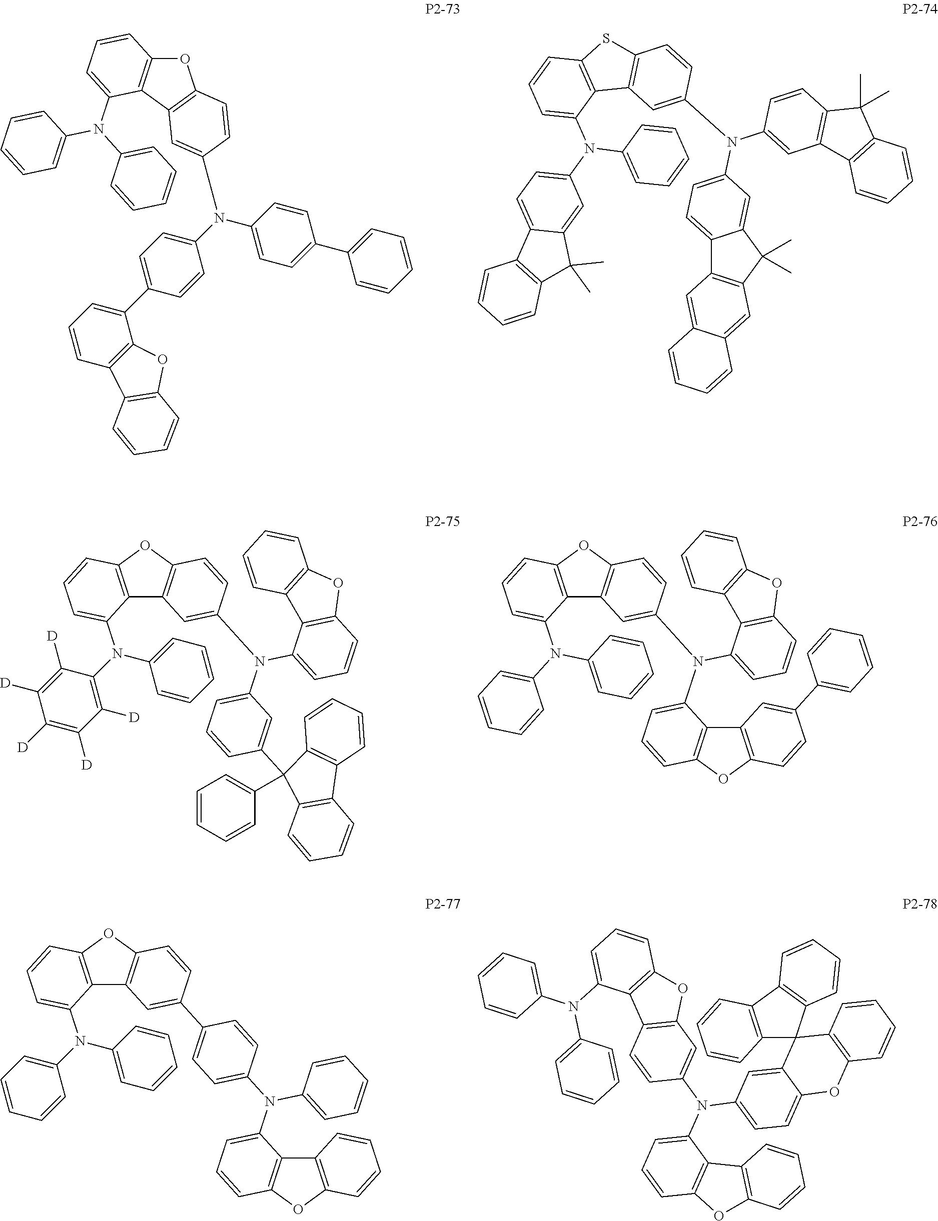

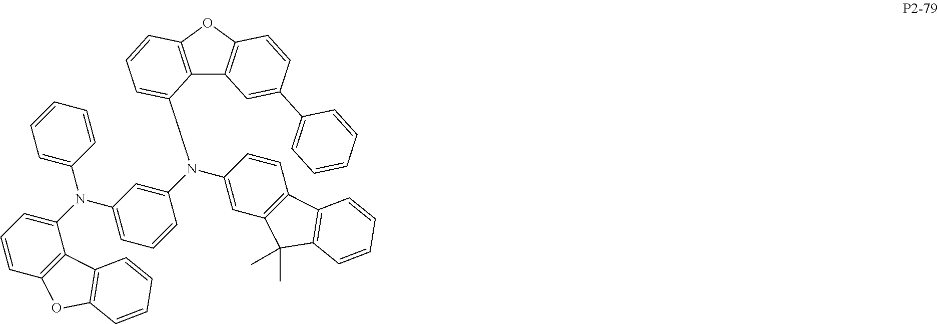 [SMILES: CC1(C)c2ccccc2-c2ccc(N(c3cccc(N(c4ccccc4)c4cccc5oc6ccccc6c45)c3)c3cccc4oc5ccc(-c6ccccc6)cc5c34)cc21]

The emitting auxiliary layer plays a role in transporting holes from the hole transport layer to the emitting layer and injecting holes and blocking electrons from the emitting auxiliary layer to the emitting layer. At this time, by controlling the injection of holes between the hole transport layer and the emitting auxiliary layer, the amount of holes and electrons in the emitting layer can be controlled to be balanced. Wherein, the balance between the amount of holes and the amount of electrons means that the holes and electrons injected into the emitting layer recombine within the emitting layer to effectively form excitons for light emission. For example, when the amount of holes in the emitting layer becomes greater than the amount of electrons, non-luminous annihilating holes are generated in addition to the holes involved in recombination, resulting in a loss of quantum efficiency of the element. Therefore, by achieving a quantitative balance of injected holes and electrons, the amount of holes and electrons that are extinguished without contributing to light emission can be reduced, thereby affecting the element characteristics.

For example, it is important to control the lateral resistance of the organic layer including the hole transport layer and the emitting auxiliary layer as a means to ensure quantitative balance of holes and electrons within the emitting layer. When there is an excess of holes in the emitting layer, the amount of holes injected between the hole transport layer and the emitting auxiliary layer can be reduced to achieve a balance between holes and electrons in the emitting layer. In general, the hole mobility of a material provided between the anode-side end of the emitting unit adjacent to the cathode and the emitting layer and transporting holes exhibits a faster characteristic than the electron mobility of a material provided between the cathode and the emitting layer and transporting electrons.

Therefore, in order to increase the luminescence efficiency of the element, it is important to reduce the amount of holes injected into the emitting layer, and it may be more effective to limit the injection of holes between the hole transport layer and the emitting auxiliary layer than to limit the injection of holes from the emitting auxiliary layer to the emitting layer.

The lateral resistance change ratio can be controlled depending on the hole transport layer and the emitting auxiliary layer. When the hole transport layer and the emitting auxiliary layer are in contact and the lateral resistance change ratio of the emitting auxiliary layer gradually decreases, this means that the hole injection between the hole transport layer and the emitting auxiliary layer has a greater effect than the hole mobility of the emitting auxiliary layer because the lateral resistance change is small depending on the thickness. Therefore, when the lateral resistance change ratio of the emitting auxiliary layer approaches 0, hole injection between the hole transport layer and the emitting auxiliary layer is limited, and the amount of holes injected into the emitting layer is reduced, so that the amount of holes and the amount of electrons within the emitting layer can be balanced. Therefore, the quantitative balance of injected holes and electrons can be achieved, which can increase element efficiency.

In an OLED display, each pixel is made up of different colored subpixels to emit the desired color. Subpixels are fabricated by depositing a white-emitting OLED stack covering the entire surface of the matrix and positioning RGB (red, green, and blue) or RGBW (red, green, blue, and white) color filters on top of the OLED stack. Alternatively, different primary color OLED layers are configured within the subpixels. In this case, it is desirable to structure only the emitting layer after depositing common layers (layers prior to the emitting layer, hole injection layer, hole transport layer, emitting auxiliary layer, etc.). However, it is observed that in the above two cases, they can interact through parasitic currents passing through the common layer of the OLED stack. Undesirable interaction between adjacent pixels or subpixels is known as “crosstalk”. Crosstalk leads to undesirable color shifts, especially in the case of color screens. (See Korean Patent No. 10-1647160)

In the case of an OLED device such as FIG. 1, parasitic currents are observed in adjacent pixels or subpixels, not only in common layers but also in layers formed by overlapping layers of each color without being deposited perfectly separately during the process.

In this case, it is thought that the stability of the OLED device will be improved by limiting the parasitic current by controlling the lateral resistance change ratio.

Preferably, the emitting layer according to the present invention is a red emitting layer or a green emitting layer, and preferably comprises a phosphorescent emitting body.

According to another embodiment of the present invention, the organic material layer may be formed in a form in which a plurality of stacks comprising a hole transport layer, an emitting auxiliary layer, an emitting layer, and an electron transport layer are formed.

In general, organic light-emitting devices can be divided into single-light-emitting structure elements (Single OLED) and multilayer light-emitting structure elements (Tandem OLED) depending on the number of light-emitting parts. Tandem OLED is an OLED element composed of 2 or more light-emitting parts (stacks), and can easily improve efficiency and lifespan compared to existing single OLEDs.

Specifically, an organic electronic element according to one embodiment of the present invention may comprise a first electrode, a first stack formed on the first electrode, a second stack formed on the first stack, and a second electrode. Wherein, the stack may correspond to an organic material layer, and a light efficiency enhancing layer may be further formed among both surfaces of the first electrode and/or the second electrode, the surface not in contact with the organic material layer.

The first stack and the second stack are organic material layers comprising a hole transport layer, an emitting layer, and an electron transport layer, respectively, and the first stack and the second stack can be formed with the same or different laminated structures.

At least one of the first stack and the second stack comprises an emitting auxiliary layer mixing a third compound adjacent to the emitting layer according to the present invention. That is, a plurality of emitting auxiliary layers according to the present invention are comprised between the hole transport layer and the emitting layer, and the emitting auxiliary layers may be comprised in the first stack and/or the second stack.

Additionally, a charge generation layer (CGL) can be formed between the first stack and the second stack. The charge generation layer (CGL) may comprise a first charge generation layer and a second charge generation layer. The charge generation layers (CGLs) are formed between the emitting layers of the first stack and the emitting layers of the second stack to increase the current efficiency generated in each emitting layer and to smoothly distribute charges.

These organic layer stacks can be formed in 2 or more layers. For example, when 3 stacks are formed, a charge generation layer (CGL) and a third stack can be additionally laminated on the second stack.

In this way, when multiple emitting layers are formed by a multilayer stack structure, it is possible to manufacture an organic light-emitting device that emits white light through the mixing effect of the light emitted from each emitting layer, and it is also possible to manufacture an organic light-emitting device that emits light of various colors.

The present invention may further include a light efficiency enhancing layer formed on at least one surface of the first electrode and the second electrode, which is opposite to the organic material layer.

Additionally, the organic material layer may comprise 2 or more stacks comprising a hole transport layer, an emitting layer, and an electron transport layer sequentially formed on the anode, wherein the organic material layer may further comprise a charge generation layer formed between the 2 or more stacks.

The organic material layer according to the present invention may be manufactured with a smaller number of layers by using various polymer materials and not by a deposition method, but by a solution process or a solvent process, such as a spin coating process, a nozzle printing process, an inkjet printing process, a slot coating process, a dip coating process or a roll-to-roll process, doctor blading process, screen printing process, or a thermal transfer method, etc. Since the organic material layer according to the present invention can be formed by various methods, the scope of the present invention is not limited by the forming method.

The organic electronic element according to one embodiment of the present invention may be a front-emitting, back-emitting, or both-sided emitting type depending on the material used.

Additionally, the organic electronic element according to an embodiment of the present invention may be selected from the group consisting of an organic electroluminescent device, an organic solar cell, an organic photoreceptor, an organic transistor, a monochromatic lighting device, and a quantum dot display device.

Another embodiment of the present invention may comprise an electronic device comprising a display device including the organic electronic element of the present invention; and a control unit for driving the display device. At this time, the electronic device may be a current or future wired/wireless communication terminal, and covers all kinds of electronic devices including a mobile communication terminal such as a cellular phone, a personal digital assistant(PDA), an electronic dictionary, a PMP, a remote controller, a navigation unit, a game player, various kinds of TVs, and various kinds of computers.

Hereinafter, examples of synthesis of compounds represented by Formulas 1 and 2 according to the present invention and examples of manufacturing organic electronic elements are described in detail by way of examples, but the present invention is not limited to the following examples.

### [Synthesis Example 1] Synthesis Example of Formula 1

The compound represented by Formula 1 according to the present invention (final product 1) can be synthesized according to the reaction path of the following reaction scheme 1, but is not limited thereto.

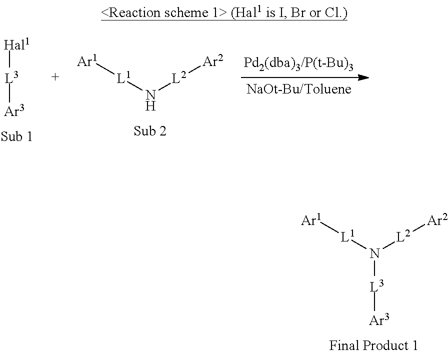

Compounds belonging to Sub 1 of the reaction scheme 1 may be, but are not limited to, the compounds, and Table 1 shows the FD-MS (Field Desorption-Mass Spectrometry) values of the compounds.

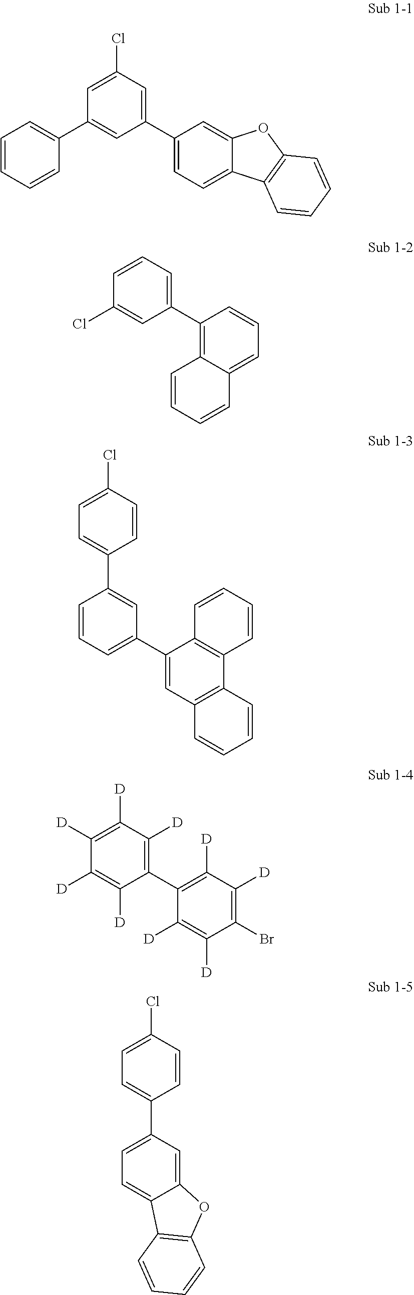 [SMILES: Clc1cc(-c2ccccc2)cc(-c2ccc3c(c2)oc2ccccc23)c1 ; Clc1cccc(-c2cccc3ccccc23)c1 ; Clc1ccc(-c2cccc(-c3cc4ccccc4c4ccccc34)c2)cc1 ; [2H]c1c([2H])c([2H])c(-c2c([2H])c([2H])c(Br)c([2H])c2[2H])c([2H])c1[2H] ; Clc1ccc(-c2ccc3c(c2)oc2ccccc23)cc1]

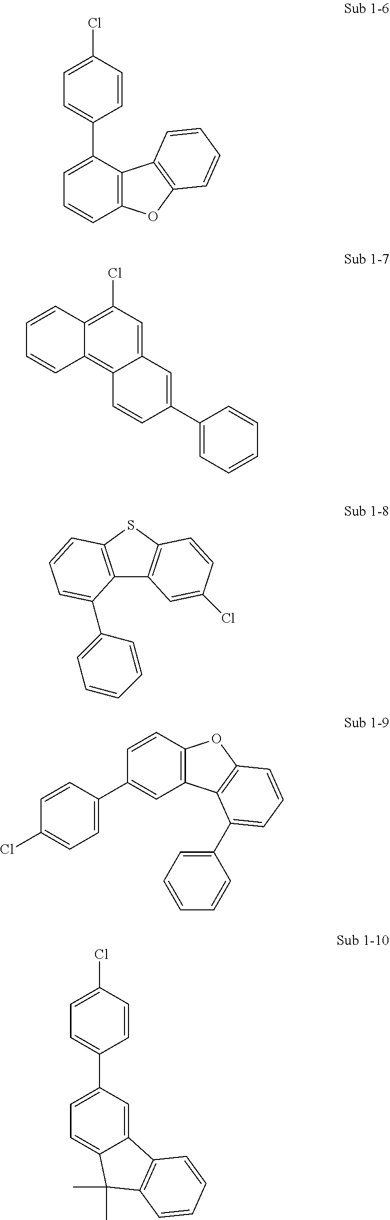 [SMILES: Clc1ccc(-c2cccc3oc4ccccc4c23)cc1 ; Clc1cc2cc(-c3ccccc3)ccc2c2ccccc12 ; Clc1ccc2sc3cccc(-c4ccccc4)c3c2c1 ; Clc1ccc(-c2ccc3oc4cccc(-c5ccccc5)c4c3c2)cc1 ; CC1(C)c2ccccc2-c2cc(-c3ccc(Cl)cc3)ccc21]

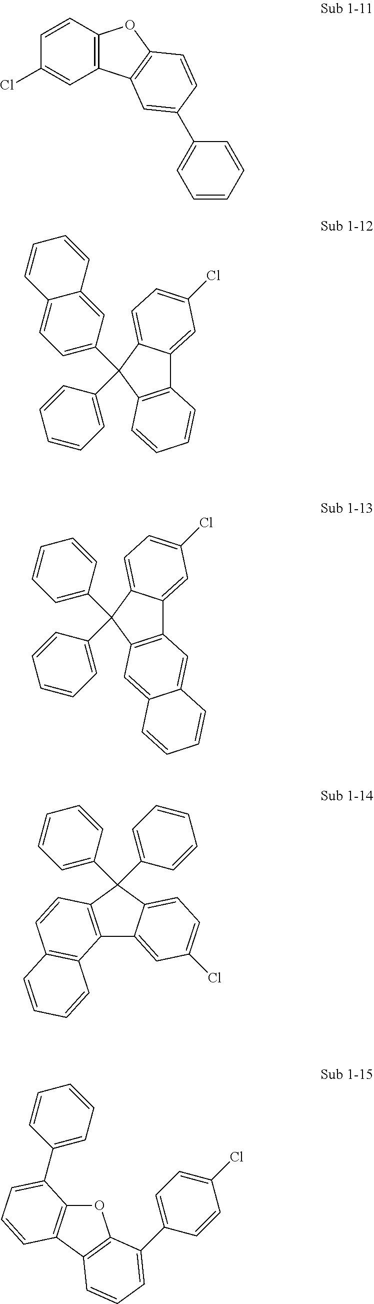 [SMILES: Clc1ccc2oc3ccc(-c4ccccc4)cc3c2c1 ; Clc1ccc2c(c1)-c1ccccc1C2(c1ccccc1)c1ccc2ccccc2c1 ; Clc1ccc2c(c1)-c1cc3ccccc3cc1C2(c1ccccc1)c1ccccc1 ; Clc1ccc2c(c1)-c1c(ccc3ccccc13)C2(c1ccccc1)c1ccccc1 ; Clc1ccc(-c2cccc3c2oc2c(-c4ccccc4)cccc23)cc1]

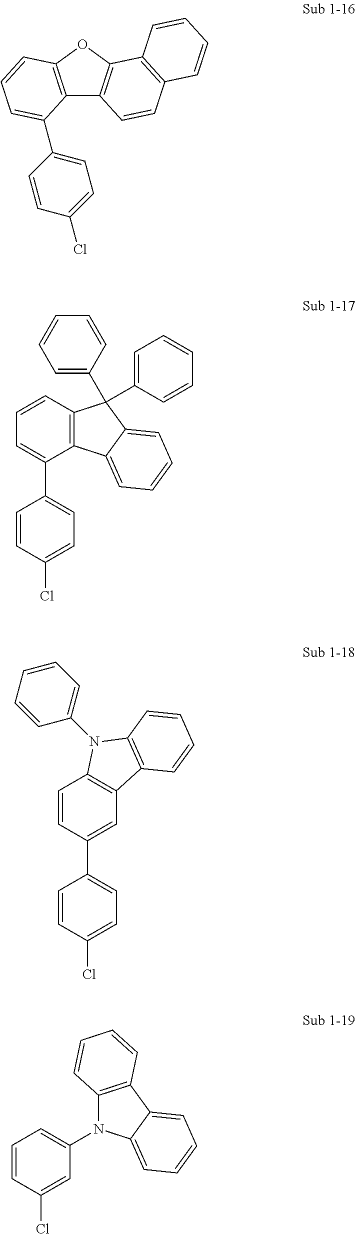 [SMILES: Clc1ccc(-c2cccc3oc4c5ccccc5ccc4c23)cc1 ; Clc1ccc(-c2cccc3c2-c2ccccc2C3(c2ccccc2)c2ccccc2)cc1 ; Clc1ccc(-c2ccc3c(c2)c2ccccc2n3-c2ccccc2)cc1 ; Clc1cccc(-n2c3ccccc3c3ccccc32)c1]

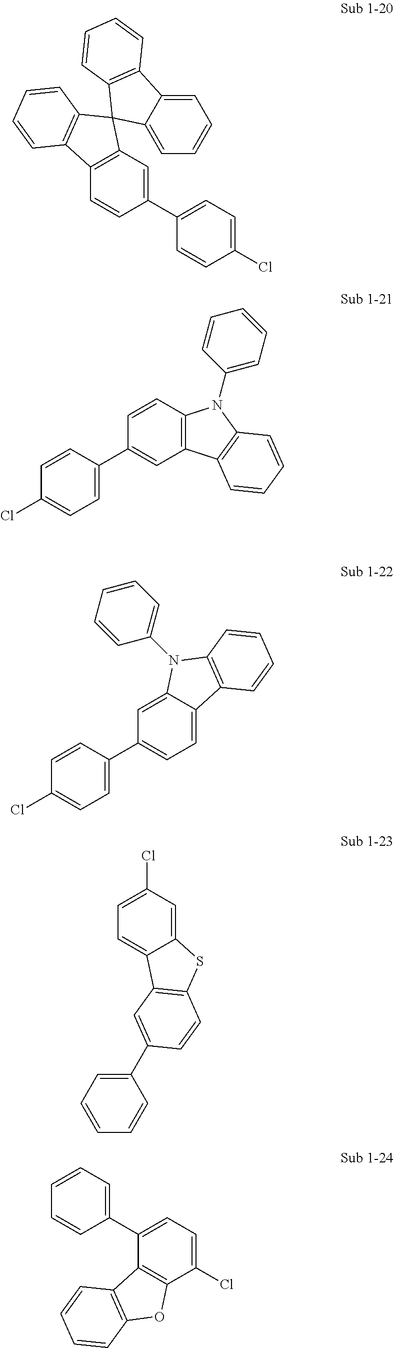

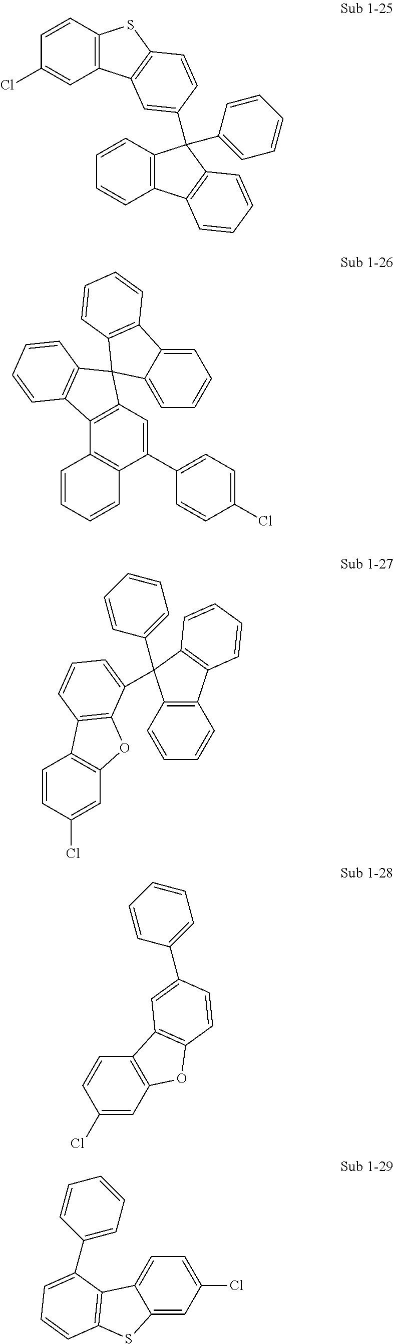

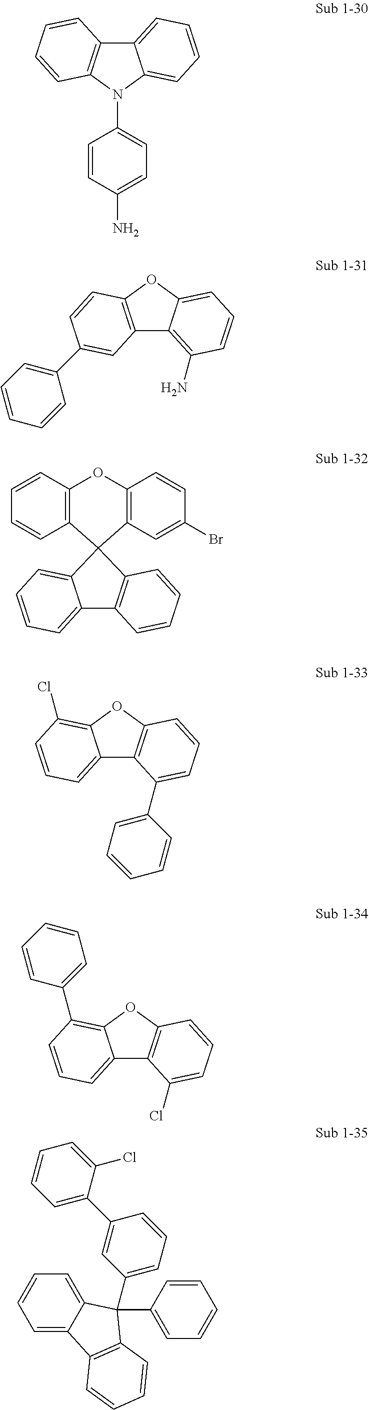

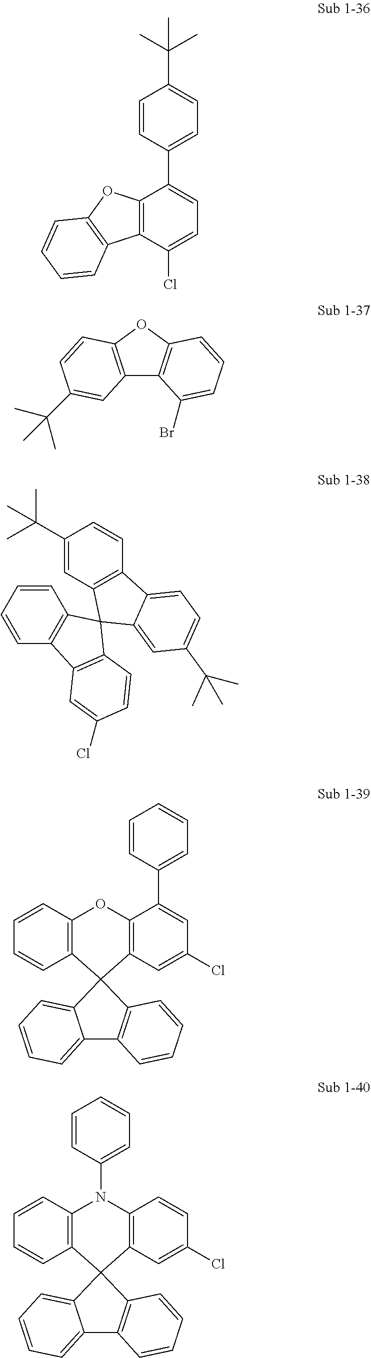

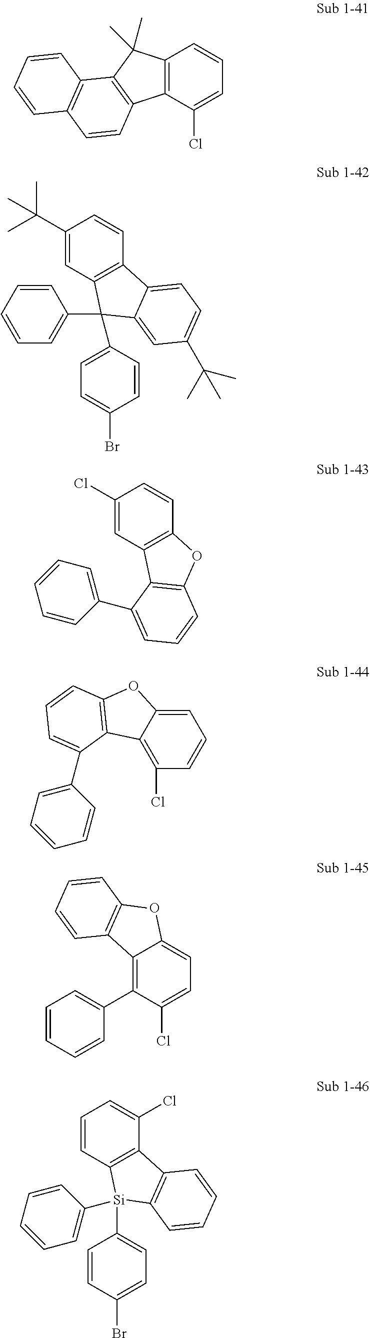

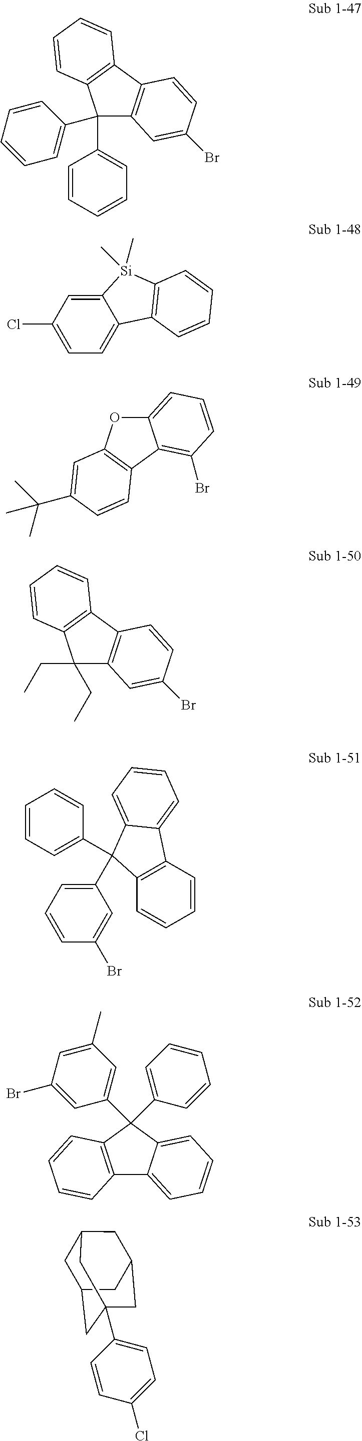

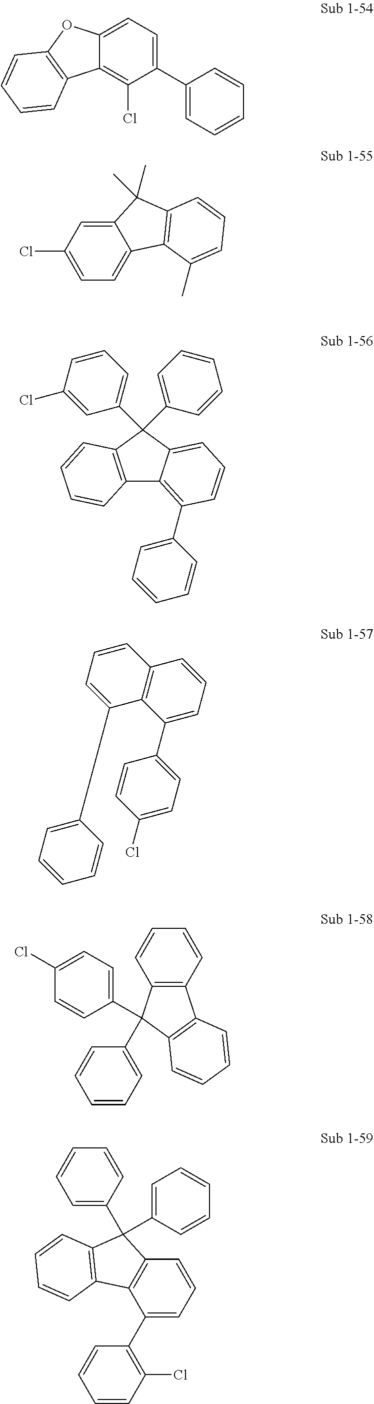

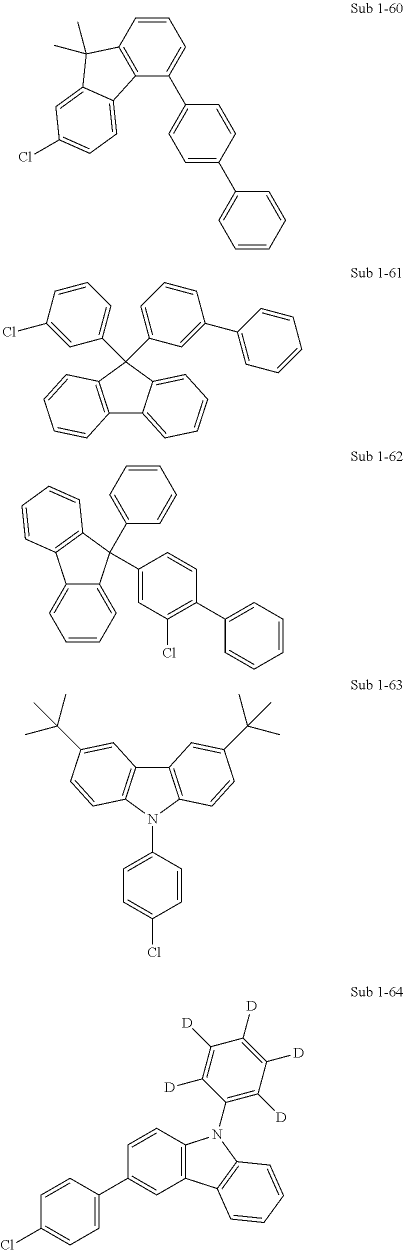

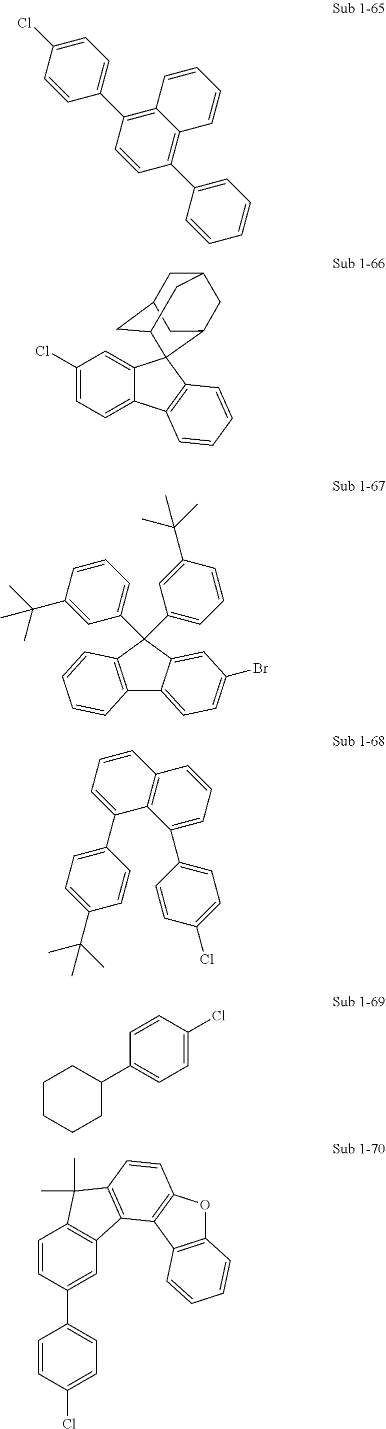

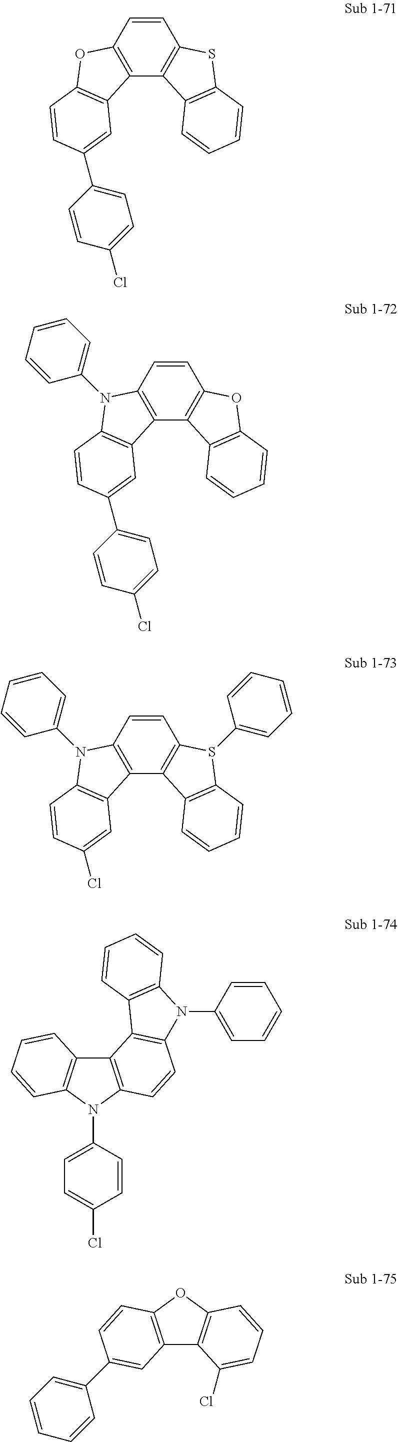

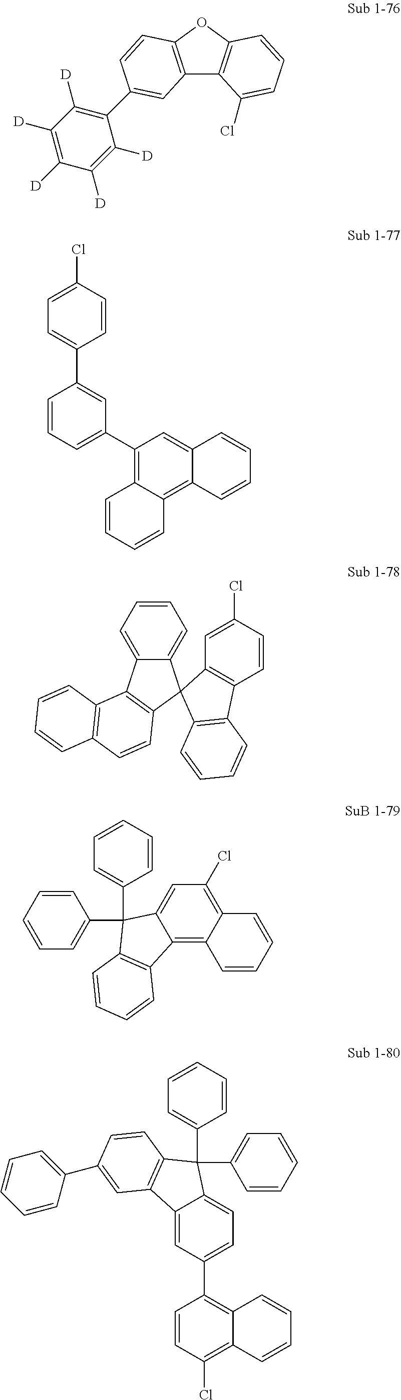 [SMILES: [2H]c1c([2H])c([2H])c(-c2ccc3oc4cccc(Cl)c4c3c2)c([2H])c1[2H] ; Clc1ccc(-c2cccc(-c3cc4ccccc4c4ccccc34)c2)cc1 ; Clc1ccc2c(c1)C1(c3ccccc3-2)c2ccccc2-c2c1ccc1ccccc21 ; Clc1cc2c(c3ccccc13)-c1ccccc1C2(c1ccccc1)c1ccccc1 ; Clc1ccc(-c2ccc3c(c2)-c2cc(-c4ccccc4)ccc2C3(c2ccccc2)c2ccccc2)c2ccccc12]

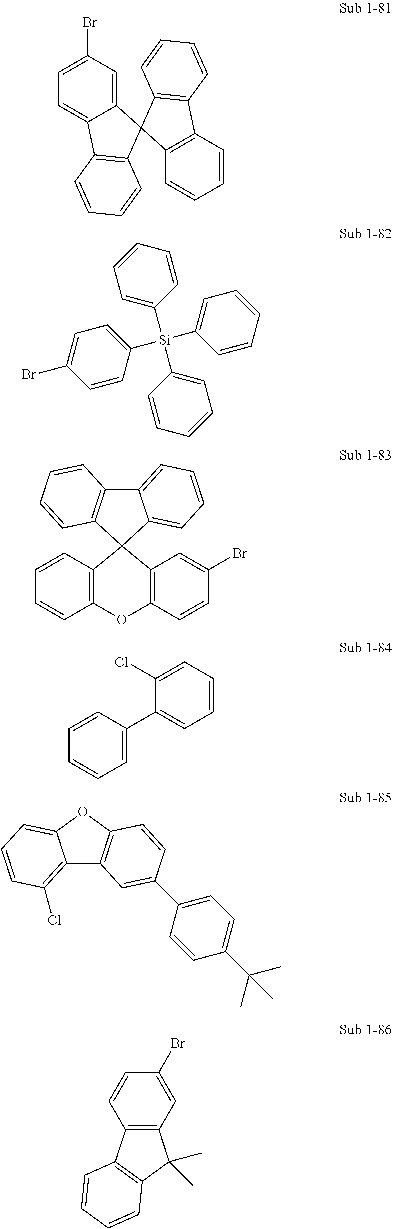

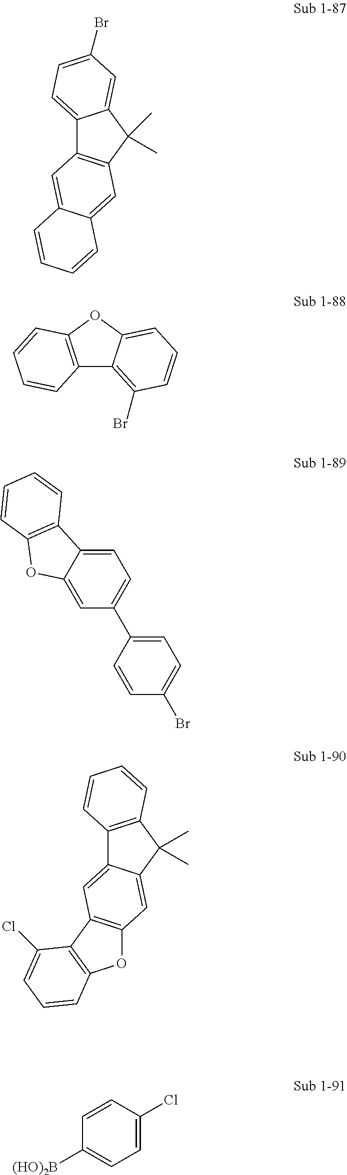 [SMILES: CC1(C)c2cc(Br)ccc2-c2cc3ccccc3cc21 ; Brc1cccc2oc3ccccc3c12 ; Brc1ccc(-c2ccc3c(c2)oc2ccccc23)cc1 ; CC1(C)c2ccccc2-c2cc3c(cc21)oc1cccc(Cl)c13 ; OB(O)c1ccc(Cl)cc1]

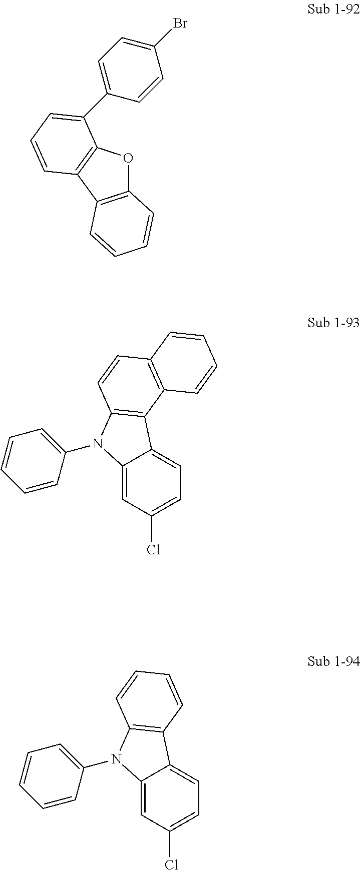 [SMILES: Brc1ccc(-c2cccc3c2oc2ccccc23)cc1 ; Clc1ccc2c3c4ccccc4ccc3n(-c3ccccc3)c2c1 ; Clc1ccc2c3ccccc3n(-c3ccccc3)c2c1]

TABLE 1

| compound | FD-MS | compound | FD-MS |
|---|---|---|---|
| Sub 1-1 | m/z = 354.08(C₂₄H₁₅ClO = 354.83) | Sub 1-2 | m/z = 238.05(C₁₆H₁₁Cl = 238.71) |
| Sub 1-3 | m/z = 364.10(C₂₆H₁₇Cl = 364.87) | Sub 1-4 | m/z = 241.05(C₁₂D₉Br = 242.16) |
| Sub 1-5 | m/z = 278.05(C₁₈H₁₁ClO = 278.74) | Sub 1-6 | m/z = 278.05(C₁₈H₁₁ClO = 278.74) |
| Sub 1-7 | m/z = 288.07(C₂₀H₁₃Cl = 288.77) | Sub 1-8 | m/z = 294.03(C₁₈H₁₁ClS = 294.80) |
| Sub 1-9 | m/z = 354.08(C₂₄H₁₅ClO = 354.83) | Sub 1-10 | m/z = 304.10(C₂₁H₁₇Cl = 304.82) |
| Sub 1-11 | m/Z = 278.05(C₁₈H₁₁ClO = 278.74) | Sub 1-12 | m/z = 402.12(C₂₉H₁₉Cl = 402.92) |
| Sub 1-13 | m/z = 402.12(C₂₉H₁₉Cl = 402.92) | Sub 1-14 | m/z = 402.12(C₂₉H₁₉Cl = 402.92) |
| Sub 1-15 | m/z = 354.08(C₂₄H₁₅ClO = 354.83) | Sub 1-16 | m/z = 328.07(C₂₂H₁₃ClO = 328.79) |
| Sub 1-17 | m/z = 428.13(C₃₁H₂₁Cl = 428.96) | Sub 1-18 | m/z = 353.10(C₂₄H₁₆ClN = 353.85) |
| Sub 1-19 | m/z = 277.07(C₁₈H₁₂ClN = 277.75) | Sub 1-20 | m/z = 426.12(C₃₁H₁₉Cl = 426.94) |
| Sub 1-21 | m/z = 353.10(C₂₄H₁₆ClN = 353.85) | Sub 1-22 | m/z = 353.10(C₂₄H₁₆ClN = 353.85) |
| Sub 1-23 | m/z = 294.03(C₁₈H₁₁ClS = 294.80) | Sub 1-24 | m/z = 278.05(C₁₈H₁₁ClO = 278.74) |
| Sub 1-25 | m/z = 458.09(C₃₁H₁₉ClS = 459.00) | Sub 1-26 | m/z = 476.13(C₃₅H₂₁Cl = 477.00) |
| Sub 1-27 | m/z = 442.11(C₃₁H₁₉ClO = 442.94) | Sub 1-28 | m/z = 278.05(C₁₈H₁₁ClO = 278.74) |
| Sub 1-29 | m/z = 294.03(C₁₈H₁₁ClS = 294.80) | Sub 1-30 | m/z = 258.12(C₁₈H₁₄N₂ = 258.32) |
| Sub 1-31 | m/z = 259.10(C₁₈H₁₃NO = 259.31) | Sub 1-32 | m/z = 410.03(C₂₅H₁₅BrO = 411.30) |
| Sub 1-33 | m/z = 278.05(C₁₈H₁₁ClO = 278.74) | Sub 1-34 | m/z = 278.05(C₁₈H₁₁ClO = 278.74) |
| Sub 1-35 | m/z = 428.13(C₃₁H₂₁Cl = 428.96) | Sub 1-36 | m/z = 334.11(C₂₂H₁₉ClO = 334.84) |
| Sub 1-37 | m/z = 302.03(C₁₆H₁₅BrO = 303.20) | Sub 1-38 | m/z = 462.21(C₃₃H₃₁Cl = 463.06) |
| Sub 1-39 | m/z = 442.11(C₃₁H₁₉ClO = 442.94) | Sub 1-40 | m/z = 441.13(C₃₁H₂₀ClN = 441.96) |
| Sub 1-41 | m/z = 278.09(C₁₉H₁₅Cl = 278.78) | Sub 1-42 | m/z = 508.18(C₃₃H₃₃Br = 509.53) |
| Sub 1-43 | m/z = 278.05(C₁₈H₁₁ClO = 278.74) | Sub 1-44 | m/z = 278.05(C₁₈H₁₁ClO = 278.74) |
| Sub 1-45 | m/z = 278.05(C₁₈H₁₁ClO = 278.74) | Sub 1-46 | m/z = 368.08(C₂₄H₁₇ClSi = 368.94) |
| Sub 1-47 | m/z = 396.05(C₂₅H₁₇Br = 397.32) | Sub 1-48 | m/z = 244.05(C₁₄H₁₃ClSi = 244.79) |
| Sub 1-49 | m/z = 302.03(C₁₆H₁₅BrO = 303.20) | Sub 1-50 | m/z = 300.05(C₁₇H₁₇Br = 301.23) |
| Sub 1-51 | m/z = 396.05(C₂₅H₁₇Br = 397.31) | Sub 1-52 | m/z = 410.07(C₂₆H₁₉Br = 411.34) |
| Sub 1-53 | m/z = 246.12(C₁₆H₁₉Cl = 246.78) | Sub 1-54 | m/z = 278.05(C₁₈H₁₁ClO = 278.74) |
| Sub 1-55 | m/z = 242.09(C₁₆H₁₅Cl = 242.75) | Sub 1-56 | m/z = 428.13(C₃₁H₂₁Cl = 428.96) |
| Sub 1-57 | m/z = 314.09(C₂₂H₁₅Cl = 314.81) | Sub 1-58 | m/z = 352.10(C₂₅H₁₇Cl = 352.86) |
| Sub 1-59 | m/z = 428.13(C₃₁H₂₁Cl = 428.96) | Sub 1-60 | m/z = 380.13(C₂₇H₂₁Cl = 380.91) |
| Sub 1-61 | m/z = 428.13(C₃₁H₂₁Cl = 428.96) | Sub 1-62 | m/z = 428.13(C₃₁H₂₁Cl = 428.96) |
| Sub 1-63 | m/z = 389.19(C₂₆H₂₈ClN = 389.97) | Sub 1-64 | m/z = 358.13(C₂₄H₁₁D₅ClN = 358.88) |
| Sub 1-65 | m/z = 314.09(C₂₂H₁₅Cl = 314.81) | Sub 1-66 | m/z = 320.13(C₂₂H₂₁Cl = 320.86) |
| Sub 1-67 | m/z = 508.18(C₃₃H₃₃Br = 509.53) | Sub 1-68 | m/z = 370.15(C₂₆H₂₃Cl = 370.92) |
| Sub 1-69 | m/z = 194.09(C₁₂H₁₅Cl = 194.70) | Sub 1-70 | m/z = 394.11(C₂₇H₁₉ClO = 394.90) |
| Sub 1-71 | m/z = 384.04(C₂₄H₁₃ClOS = 384.88) | Sub 1-72 | m/z = 443.11(C₃₀H₁₈ClNO = 443.93) |
| Sub 1-73 | m/z = 442.12(C₃₀H₁₉ClN₂ = 442.95) | Sub 1-74 | m/z = 442.12(C₃₀H₁₉ClN₂ = 442.95) |
| Sub 1-75 | m/z = 278.05(C₁₈H₁₁ClO = 278.74) | Sub 1-76 | m/z = 283.08(C₁₈H₆D₅ClO = 283.77) |
| Sub 1-77 | m/z = 364.10(C₂₆H₁₇Cl = 364.87) | Sub 1-78 | m/z = 400.10(C₂₉H₁₇Cl = 400.90) |
| Sub 1-79 | m/z = 402.12(C₂₉H₁₉Cl = 402.92) | Sub 1-80 | m/z = 554.18(C₄₁H₂₇Cl = 555.12) |
| Sub 1-81 | m/z = 394.04(C₂₅H₁₅Br = 395.30) | Sub 1-82 | m/z = 416.04(C₂₄H₁₉BrSi = 415.40) |
| Sub 1-83 | m/z = 410.03(C₂₅H₁₅BrO = 411.30) | Sub 1-84 | m/z = 188.04(C₁₂H₉Cl = 188.65) |
| Sub 1-85 | m/z = 334.11(C₂₂H₁₉ClO = 334.84) | Sub 1-86 | m/z = 272.02(C₁₅H₁₃Br = 273.17) |
| Sub 1-87 | m/z = 322.04(C₁₉H₁₅Br = 323.23) | Sub 1-88 | m/z = 245.97(C₁₂H₇BrO = 247.09) |
| Sub 1-89 | m/z = 322.00(C₁₈H₁₁BrO = 323.19) | Sub 1-90 | m/z = 318.08(C₂₁H₁₅ClO = 318.80) |
| Sub 1-91 | m/z = 156.01(C₆H₆BClO₂ = 156.37) | Sub 1-92 | m/z = 322.00(C₁₈H₁₁BrO = 323.19) |
| Sub 1-93 | m/z = 327.08(C₂₂H₁₄ClN = 327.81) | Sub 1-94 | m/z = 277.07(C₁₈H₁₂ClN = 277.75) |

Compounds belonging to Sub 2 of the Reaction scheme 1 may be, but are not limited to, the compounds, and Table 2 shows the FD-MS (Field Desorption-Mass Spectrometry) values of the compounds.

[chemical structure]

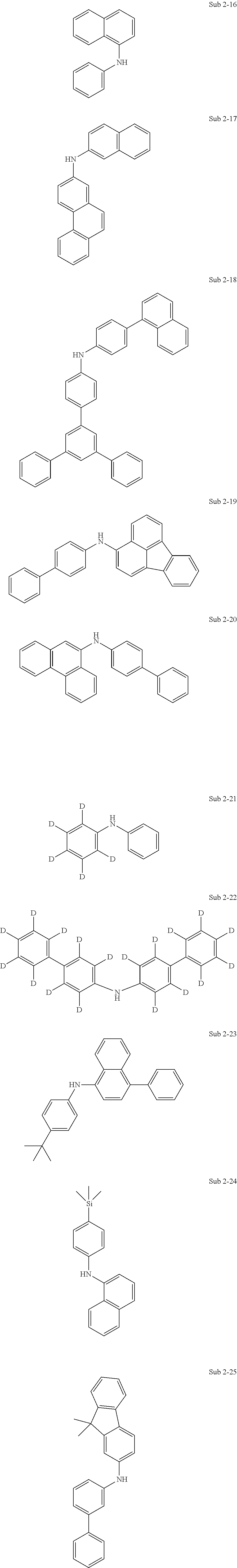

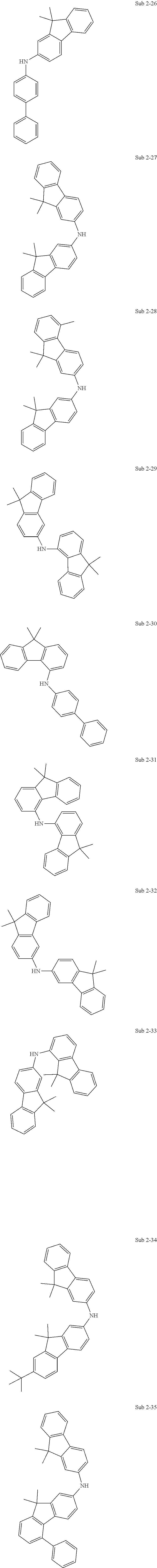

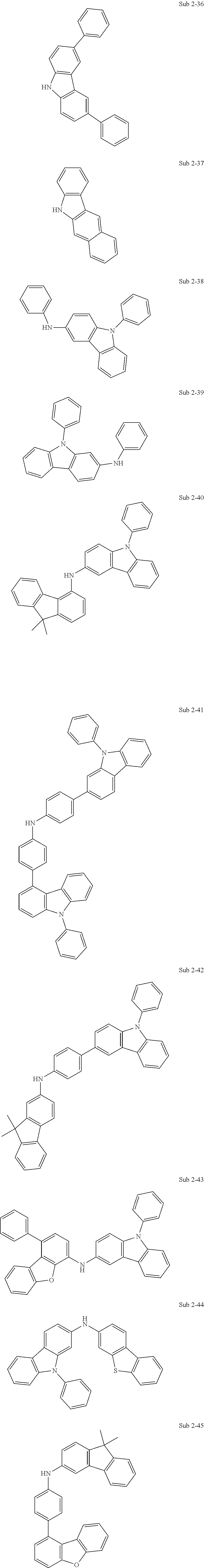

[chemical structure]

[chemical structure]

[chemical structure]

TABLE 2

| compound | FD-MS | compound | FD-MS |
|---|---|---|---|
| Sub 2-1 | m/z = 321.15(C₂₄H₁₉N = 321.42) | Sub 2-2 | m/z = 397.18(C₃₀H₂₃N = 397.52) |
| Sub 2-3 | m/z = 345.15(C₂₆H₁₉N = 345.44) | Sub 2-4 | m/z = 371.17(C₂₈H₂₁N = 371.48) |
| Sub 2-5 | m/z = 321.15(C₂₄H₁₉N = 321.42) | Sub 2-6 | m/z = 345.15(C₂₆H₁₉N = 345.44) |
| Sub 2-7 | m/z = 371.17(C₂₈H₂₁N = 371.48) | Sub 2-8 | m/z = 397.18(C₃₀H₂₃N = 397.52) |
| Sub 2-9 | m/z = 447.20(C₃₄H₂₅N = 447.58) | Sub 2-10 | m/z = 295.14(C₂₂H₁₇N = 295.38) |
| Sub 2-11 | m/z = 245.12(C₁₈H₁₅N = 245.32) | Sub 2-12 | m/z = 169.09(C₁₂H₁₁N = 169.23) |
| Sub 2-13 | m/z = 395.17(C₃₀H₂₁N = 395.50) | Sub 2-14 | m/z = 219.10(C₁₆H₁₃N = 219.29) |
| Sub 2-15 | m/z = 219.10(C₁₆H₁₃N = 219.29) | Sub 2-16 | m/z = 219.10(C₁₆H₁₃N = 219.29) |
| Sub 2-17 | m/z = 319.14(C₂₄H₁₇N = 319.41) | Sub 2-18 | m/z = 523.23(C₄₀H₂₉N = 523.68) |
| Sub 2-19 | m/z = 369.15(C₂₈H₁₉N = 369.47) | Sub 2-20 | m/z = 345.15(C₂₆H₁₉N = 345.44) |
| Sub 2-21 | m/z = 174.12(C₁₂H₆D₅N = 174.26) | Sub 2-22 | m/z = 339.26(C₂₄HD₁₈N = 339.53) |
| Sub 2-23 | m/z = 351.20(C₂₆H₂₅N = 351.49) | Sub 2-24 | m/z = 291.14(C₁₉H₂₁NSi = 291.47) |
| Sub 2-25 | m/z = 361.18(C₂₇H₂₃N = 361.49) | Sub 2-26 | m/z = 361.18(C₂₇H₂₃N = 361.49) |
| Sub 2-27 | m/z = 401.21(C₃₀H₂₇N = 401.55) | Sub 2-28 | m/z = 415.23(C₃₁H₂₉N = 415.58) |
| Sub 2-29 | m/z = 401.21(C₃₀H₂₇N = 401.55) | Sub 2-30 | m/z = 361.18(C₂₇H₂₃N = 361.49) |
| Sub 2-31 | m/z = 401.21 (C₃₀H₂₇N = 401.55) | Sub 2-32 | m/z = 401.21 (C₃₀H₂₇N = 401.55) |
| Sub 2-33 | m/z = 401.21(C₃₀H₂₇N = 401.55) | Sub 2-34 | m/z = 457.28(C₃₄H₃₅N = 457.66) |
| Sub 2-35 | m/z = 477.25(C₃₆H₃₁N = 477.65) | Sub 2-36 | m/z = 319.14(C₂₄H₁₇N = 319.41) |
| Sub 2-37 | m/z = 217.09(C₁₆H₁₁N = 217.27) | Sub 2-38 | m/z = 334.15(C₂₄H₁₈N₂ = 334.42) |
| Sub 2-39 | m/z = 334.15(C₂₄H₁₈N₂ = 334.42) | Sub 2-40 | m/z = 450.21(C₃₃H₂₆N₂ = 450.59) |
| Sub 2-41 | m/z = 651.27(C₄₈H₃₃N₃ = 651.81) | Sub 2-42 | m/z = 526.24(C₃₉H₃₀N₂ = 526.68) |
| Sub 2-43 | m/z = 500.19(C₃₆H₂₄N₂O = 500.60) | Sub 2-44 | m/z = 440.13(C₃₀H₂₀N₂S = 440.56) |
| Sub 2-45 | m/z = 451.19(C₃₃H₂₅NO = 451.57) | Sub 2-46 | m/z = 451.19(C₃₃H₂₅NO = 451.57) |
| Sub 2-47 | m/z = 451.19(C₃₃H₂₅NO = 451.57) | Sub 2-48 | m/z = 451.19(C₃₃H₂₅NO = 451.57) |
| Sub 2-49 | m/z = 501.21(C₃₇H₂₇NO = 501.63) | Sub 2-50 | m/z = 375.16(C₂₇H₂₁NO = 375.47) |
| Sub 2-51 | m/z = 375.16(C₂₇H₂₁NO = 375.47) | Sub 2-52 | m/z = 375.16(C₂₇H₂₁NO = 375.47) |
| Sub 2-53 | m/z = 375.16(C₂₇H₂₁NO = 375.47) | Sub 2-54 | m/z = 425.18(C₃₁H₂₃NO = 425.53) |
| Sub 2-55 | m/z = 437.18(C₃₂H₂₃NO = 437.54) | Sub 2-56 | m/z = 259.10(C₁₈H₁₃NO = 259.31) |
| Sub 2-57 | m/z = 259.10(C₁₈H₁₃NO = 259.31) | Sub 2-58 | m/z = 259.10(C₁₈H₁₃NO = 259.31) |
| Sub 2-59 | m/z = 335.13(C₂₄H₁₇NO = 335.41) | Sub 2-60 | m/z = 335.13(C₂₄H₁₇NO = 335.41) |
| Sub 2-61 | m/z = 335.13(C₂₄H₁₇NO = 335.41) | Sub 2-62 | m/z = 335.13(C₂₄H₁₇NO = 335.41) |
| Sub 2-63 | m/z = 309.12(C₂₂H₁₅NO = 309.37) | Sub 2-64 | m/z = 309.12(C₂₂H₁₅NO = 309.37) |
| Sub 2-65 | m/z = 385.15(C₂₈H₁₉NO = 385.47) | Sub 2-66 | m/z = 411.16(C₃₀H₂₁NO = 411.50) |
| Sub 2-67 | m/z = 359.13(C₂₆H₁₇NO = 359.43) | Sub 2-68 | m/z = 411.16(C₃₀H₂₁NO = 411.50) |
| Sub 2-69 | m/z = 411.16(C₃₀H₂₁NO = 411.50) | Sub 2-70 | m/z = 411.16(C₃₀H₂₁NO = 411.50) |
| Sub 2-71 | m/z = 335.13(C₂₄H₁₇NO = 335.41) | Sub 2-72 | m/z = 411.16(C₃₀H₂₁NO = 411.50) |
| Sub 2-73 | m/z = 385.15(C₂₈H₁₉NO = 385.47) | Sub 2-74 | m/z = 411.16(C₃₀H₂₁NO = 411.50) |
| Sub 2-75 | m/z = 349.11(C₂₄H₁₅NO₂ = 349.39) | Sub 2-76 | m/z = 441.12(C₃₀H₁₉NOS = 441.55) |
| Sub 2-77 | m/z = 529.15(C₃₇H₂₃NOS = 529.66) | Sub 2-78 | m/z = 525.25(C₄₀H₃₁N = 525.69) |
| Sub 2-79 | m/z = 499.19(C₃₇H₂₅NO = 499.61) | Sub 2-80 | m/z = 517.15(C₃₆H₂₃NOS = 517.65) |
| Sub 2-81 | m/z = 517.15(C₃₆H₂₃NOS = 517.65) | Sub 2-82 | m/z = 275.08(C₁₈H₁₃NS = 275.37) |
| Sub 2-83 | m/z = 351.11(C₂₄H₁₇NS = 351.47) | Sub 2-84 | m/z = 275.08(C₁₈H₁₃NS = 275.37) |
| Sub 2-85 | m/z = 325.09(C₂₂H₁₅NS = 325.43) | Sub 2-86 | m/z = 325.09(C₂₂H₁₅NS = 325.43) |
| Sub 2-87 | m/z = 427.14(C₃₀H₂₁NS = 427.56) | Sub 2-88 | m/z = 391.14(C₂₇H₂₁NS = 391.53) |
| Sub 2-89 | m/z = 409.18(C₃₁H₂₃N = 409.53) | Sub 2-90 | m/z = 485.21(C₃₇H₂₇N = 485.63) |
| Sub 2-91 | m/z = 517.15(C₃₆H₂₃NOS = 517.65) | Sub 2-92 | m/z = 485.21(C₃₇H₂₇N = 485.63) |
| Sub 2-93 | m/z = 485.21(C₃₇H₂₇N = 485.63) | Sub 2-94 | m/z = 369.09(C₂₄H₁₆ClNO = 369.85) |
| Sub 2-95 | m/z = 445.12(C₃₀H₂₀ClNO = 445.95) | Sub 2-96 | m/z = 423.16(C₃₁H₂₁NO = 423.51) |
| Sub 2-97 | m/z = 379.23(C₂₈H₂₉N = 379.55) | Sub 2-98 | m/z = 367.23(C₂₇H₂₉N = 367.54) |
| Sub 2-99 | m/z = 367.23(C₂₇H₂₉N = 367.54) | Sub 2-100 | m/z = 341.18(C₂₄H₂₃NO = 341.45) |
| Sub 2-101 | m/z = 385.28(C₂₈H₃₅N = 385.59) | Sub 2-102 | m/z = 345.25(C₂₅H₃₁N = 345.53) |
| Sub 2-103 | m/z = 397.28(C₂₉H₃₅N = 397.61) | Sub 2-104 | m/z = 209.12(C₁₅H₁₅N = 209.29) |
| Sub 2-105 | m/z = 411.16(C₃₀H₂₁NO = 411.50) | | |

### Synthesis Example of Final Compound

### 1. Synthesis Example of P1-21

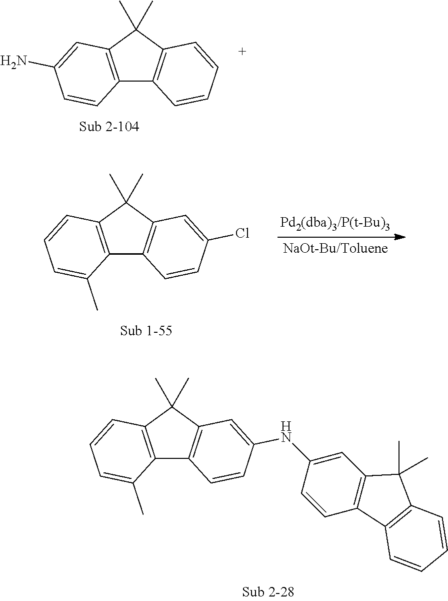 [SMILES: CC1(C)c2ccccc2-c2ccc(N)cc21 ; Cc1cccc2c1-c1ccc(Cl)cc1C2(C)C ; Cc1cccc2c1-c1ccc(Nc3ccc4c(c3)C(C)(C)c3ccccc3-4)cc1C2(C)C]

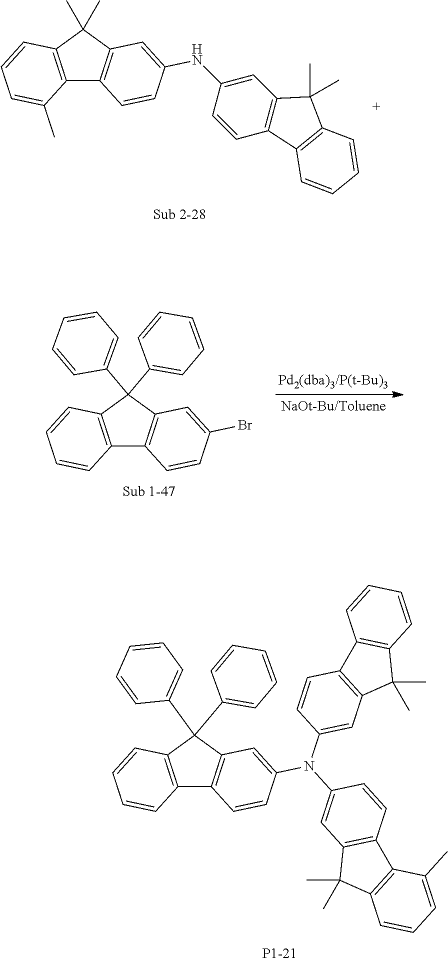 [SMILES: Cc1cccc2c1-c1ccc(Nc3ccc4c(c3)C(C)(C)c3ccccc3-4)cc1C2(C)C ; Brc1ccc2c(c1)C(c1ccccc1)(c1ccccc1)c1ccccc1-2 ; Cc1cccc2c1-c1ccc(N(c3ccc4c(c3)C(C)(C)c3ccccc3-4)c3ccc4c(c3)C(c3ccccc3)(c3ccccc3)c3ccccc3-4)cc1C2(C)C]

### (1) Synthesis of Sub 2-28

Sub 2-104 (23.7 g, 113.3 mmol), Toluene (340 mL), Sub 1-55 (25 g, 103.0 mmol), Pd₂(dba)₃ (2.83 g, 3.09 mmol), P(t-Bu)₃ (1.25 g, 6.18 mmol), NaOt-Bu (19.8 g, 206.0 mmol) were added and stirred at 100° C. After the reaction was completed, the organic layer was extracted with toluene and water, dried over MgSO₄, concentrated, and the resulting compound was recrystallized using a silica gel column to obtain the product (26.1 g, 61%).

### (2) Synthesis of P1-21

Sub 2-28 (26.1 g, 62.8 mmol), Toluene (210 mL), Sub 1-47 (25.0 g, 62.8 mmol), Pd₂(dba)₃ (1.73 g, 1.88 mmol), P(t-Bu)₃ (0.76 g, 3.77 mmol), NaOt-Bu (12.1 g, 125.6 mmol) were added and stirred at 100° C. After the reaction was completed, the organic layer was extracted with toluene and water, dried over MgSO₄, concentrated, and the resulting compound was recrystallized using a silica gel column to obtain the product (31.3 g, 68%).

### 2. Synthesis Example of P1-48

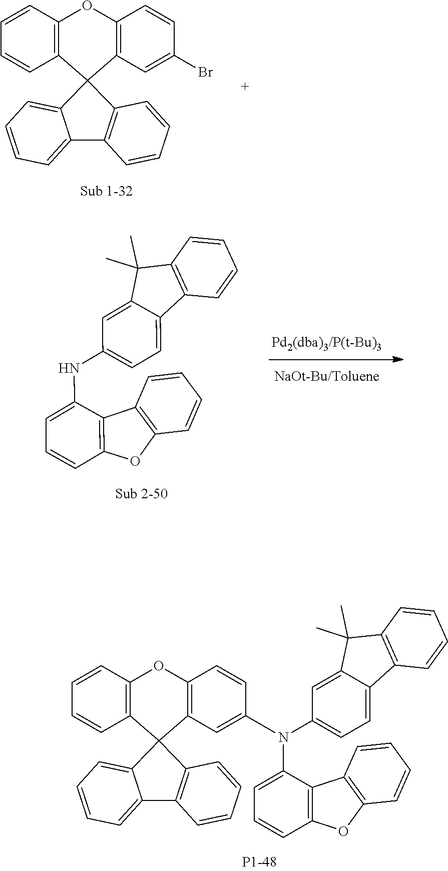 [SMILES: Brc1ccc2c(c1)C1(c3ccccc3O2)c2ccccc2-c2ccccc21 ; CC1(C)c2ccccc2-c2ccc(Nc3cccc4oc5ccccc5c34)cc21 ; CC1(C)c2ccccc2-c2ccc(N(c3ccc4c(c3)C3(c5ccccc5O4)c4ccccc4-c4ccccc43)c3cccc4oc5ccccc5c34)cc21]

Sub 1-32 (16 g, 42.6 mmol), Toluene (140 mL), Sub 2-50 (17.5 g, 42.6 mmol), Pd₂(dba)₃ (1.17 g, 1.28 mmol), P(t-Bu)₃ (0.52 g, 2.56 mmol), NaOt-Bu (8.20 g, 85.2 mmol) were added and stirred at 100° C. After the reaction was completed, the organic layer was extracted with toluene and water, dried over MgSO₄, concentrated, and the resulting compound was recrystallized using a silica gel column to obtain the product (23.5 g, 78%).

### 3. Synthesis Example of P1-49

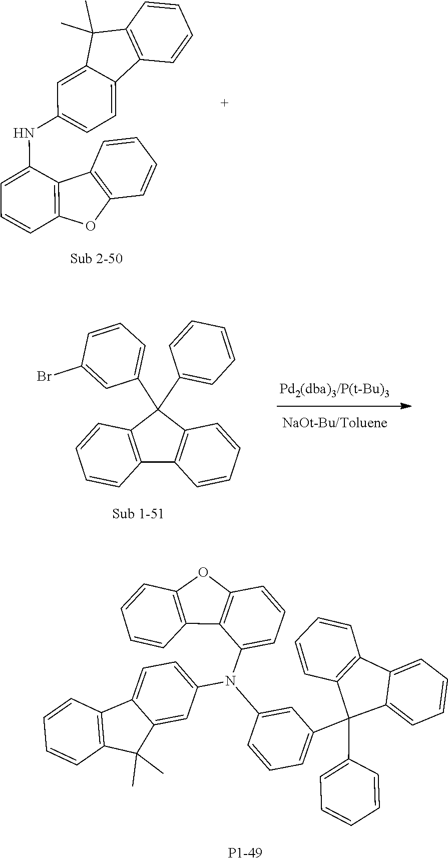 [SMILES: CC1(C)c2ccccc2-c2ccc(Nc3cccc4oc5ccccc5c34)cc21 ; Brc1cccc(C2(c3ccccc3)c3ccccc3-c3ccccc32)c1 ; CC1(C)c2ccccc2-c2ccc(N(c3cccc(C4(c5ccccc5)c5ccccc5-c5ccccc54)c3)c3cccc4oc5ccccc5c34)cc21]

Sub 2-50 (25 g, 66.6 mmol), Toluene (220 mL), Sub 1-51 (26.4 g, 66.6 mmol), Pd₂(dba)₃ (1.83 g, 2.00 mmol), P(t-Bu)₃ (0.81 g, 3.99 mmol), NaOt-Bu (12.8 g, 133.2 mmol) were added and stirred at 100° C. After the reaction was completed, the organic layer was extracted with toluene and water, dried over MgSO₄, concentrated, and the resulting compound was recrystallized using a silica gel column to obtain the product (33.2 g, 72%).

### 4. Synthesis Example of P1-50

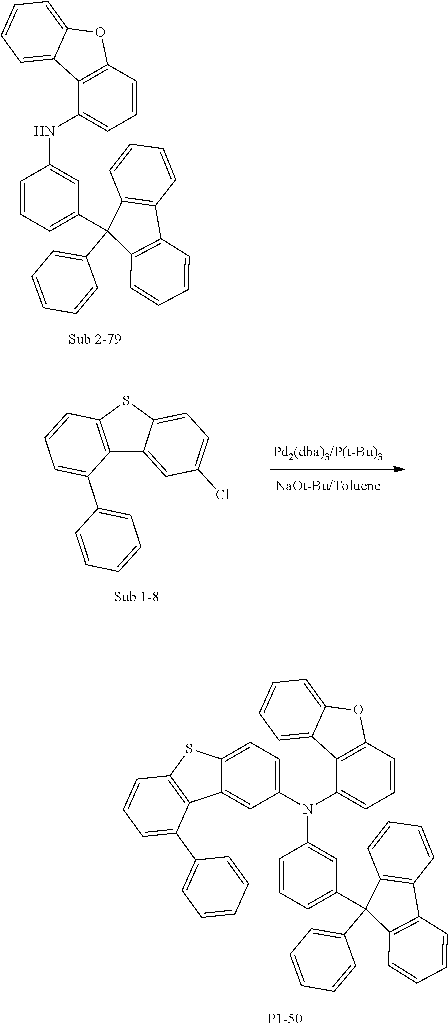 [SMILES: c1ccc(C2(c3cccc(Nc4cccc5oc6ccccc6c45)c3)c3ccccc3-c3ccccc32)cc1 ; Clc1ccc2sc3cccc(-c4ccccc4)c3c2c1 ; c1ccc(-c2cccc3sc4ccc(N(c5cccc(C6(c7ccccc7)c7ccccc7-c7ccccc76)c5)c5cccc6oc7ccccc7c56)cc4c23)cc1]

Sub 2-79 (20 g, 40.0 mmol), Toluene (130 mL), Sub 1-8 (11.8 g, 40.0 mmol), Pd₂(dba)₃ (1.10 g, 1.20 mmol), P(t-Bu)₃ (0.49 g, 2.40 mmol), NaOt-Bu (7.69 g, 80.1 mmol) were added and stirred at 100° C. After the reaction was completed, the organic layer was extracted with toluene and water, dried over MgSO₄, concentrated, and the resulting compound was recrystallized using a silica gel column to obtain the product (24.6 g, 81%).

### 5. Synthesis Example of P1-54

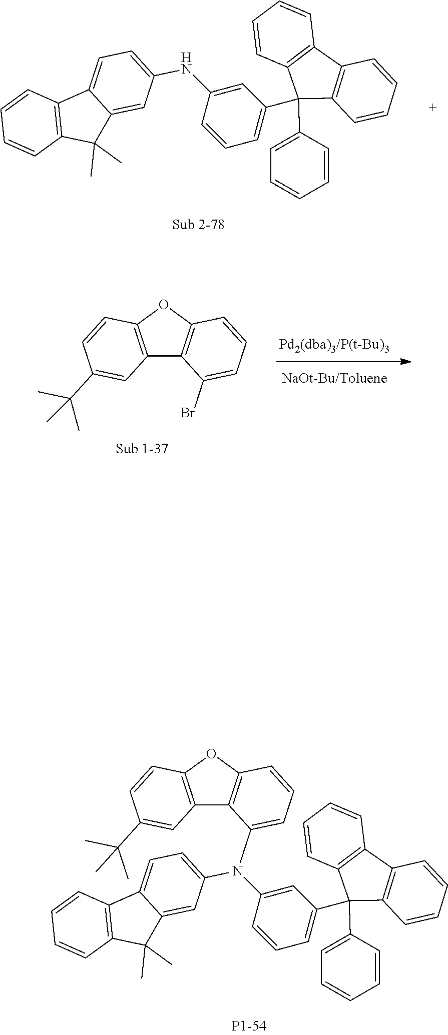 [SMILES: CC1(C)c2ccccc2-c2ccc(Nc3cccc(C4(c5ccccc5)c5ccccc5-c5ccccc54)c3)cc21 ; CC(C)(C)c1ccc2oc3cccc(Br)c3c2c1 ; CC(C)(C)c1ccc2oc3cccc(N(c4cccc(C5(c6ccccc6)c6ccccc6-c6ccccc65)c4)c4ccc5c(c4)C(C)(C)c4ccccc4-5)c3c2c1]

Sub 2-78 (25.0 g, 47.6 mmol), Toluene (160 mL), Sub 1-37 (14.4 g, 47.6 mmol), Pd₂(dba)₃ (1.3 g, 1.43 mmol), P(t-Bu)₃ (0.58 g, 2.85 mmol), NaOt-Bu (9.14 g, 95.1 mmol) were added and stirred at 100° C. After the reaction was completed, the organic layer was extracted with toluene and water, dried over MgSO₄, concentrated, and the resulting compound was recrystallized using a silica gel column to obtain the product (29.2 g, 82%).

### 6. Synthesis Example of P1-66

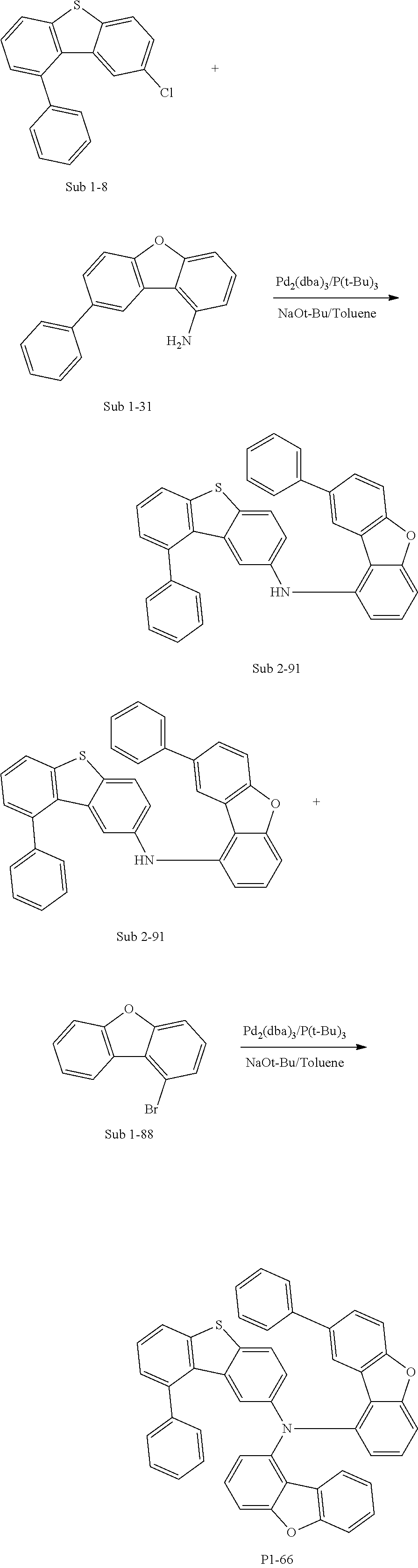 [SMILES: Clc1ccc2sc3cccc(-c4ccccc4)c3c2c1 ; Nc1cccc2oc3ccc(-c4ccccc4)cc3c12 ; c1ccc(-c2ccc3oc4cccc(Nc5ccc6sc7cccc(-c8ccccc8)c7c6c5)c4c3c2)cc1 ; c1ccc(-c2ccc3oc4cccc(Nc5ccc6sc7cccc(-c8ccccc8)c7c6c5)c4c3c2)cc1 ; Brc1cccc2oc3ccccc3c12 ; c1ccc(-c2ccc3oc4cccc(N(c5ccc6sc7cccc(-c8ccccc8)c7c6c5)c5cccc6oc7ccccc7c56)c4c3c2)cc1]

### (1) Synthesis of Sub 2-91

Sub 1-8 (20 g, 67.8 mmol), Toluene (230 mL), Sub 1-31 (19.3 g, 74.6 mmol), Pd₂(dba)₃ (1.86 g, 2.04 mmol), P(t-Bu)₃ (0.82 g, 4.07 mmol), NaOt-Bu (13.0 g, 135.7 mmol) were added and stirred at 70° C. After the reaction was completed, the organic layer was extracted with toluene and water, dried over MgSO₄, concentrated, and the resulting compound was recrystallized using a silica gel column to obtain the product (26.7 g, 76%).

### (2) Synthesis of P1-66

Sub 2-91 (26.7 g, 51.6 mmol), Toluene (170 mL), Sub 1-88 (12.7 g, 51.6 mmol), Pd₂(dba)₃ (1.4 g, 1.55 mmol), P(t-Bu)₃ (0.63 g, 3.09 mmol), NaOt-Bu (9.91 g, 103.2 mmol) were added and stirred at 100° C. After the reaction was completed, the organic layer was extracted with toluene and water, dried over MgSO₄, concentrated, and the resulting compound was recrystallized using a silica gel column to obtain the product (26.5 g, 75%).

### 7. Synthesis Example of P1-76

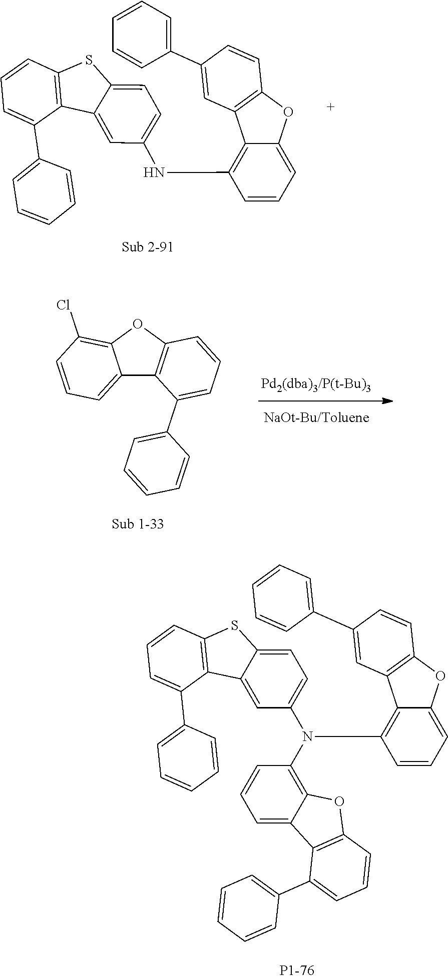 [SMILES: c1ccc(-c2ccc3oc4cccc(Nc5ccc6sc7cccc(-c8ccccc8)c7c6c5)c4c3c2)cc1 ; Clc1cccc2c1oc1cccc(-c3ccccc3)c12 ; c1ccc(-c2ccc3oc4cccc(N(c5ccc6sc7cccc(-c8ccccc8)c7c6c5)c5cccc6c5oc5cccc(-c7ccccc7)c56)c4c3c2)cc1]

Sub 2-91 (25 g, 48.3 mmol), Toluene (160 mL), Sub 1-33 (13.5 g, 48.3 mmol), Pd₂(dba)₃ (1.33 g, 1.45 mmol), P(t-Bu)₃ (0.59 g, 2.90 mmol), NaOt-Bu (9.28 g, 96.6 mmol) were added and stirred at 100° C. After the reaction was completed, the organic layer was extracted with toluene and water, dried over MgSO₄, concentrated, and the resulting compound was recrystallized using a silica gel column to obtain the product (23.9 g, 65%).

### 8. Synthesis Example of P1-77

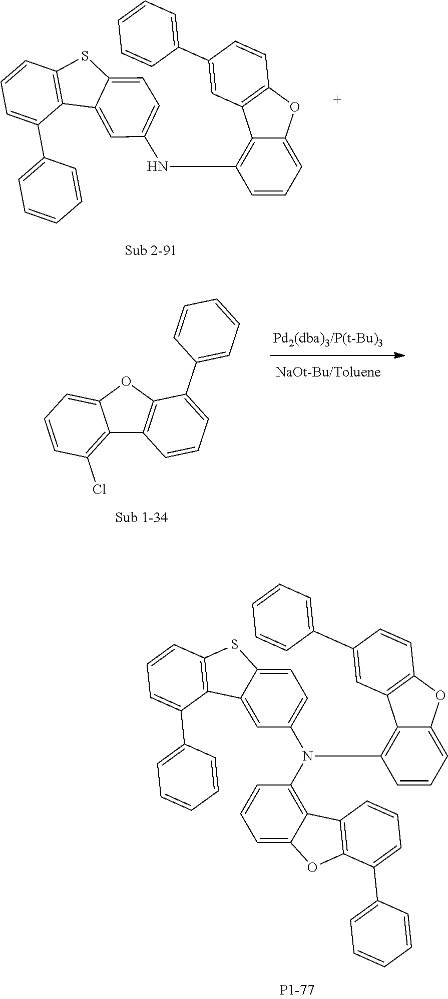 [SMILES: c1ccc(-c2ccc3oc4cccc(Nc5ccc6sc7cccc(-c8ccccc8)c7c6c5)c4c3c2)cc1 ; Clc1cccc2oc3c(-c4ccccc4)cccc3c12 ; c1ccc(-c2ccc3oc4cccc(N(c5ccc6sc7cccc(-c8ccccc8)c7c6c5)c5cccc6oc7c(-c8ccccc8)cccc7c56)c4c3c2)cc1]

Sub 2-91 (25 g, 48.3 mmol), Toluene (160 mL), Sub 1-34 (13.5 g, 48.3 mmol), Pd₂(dba)₃ (1.33 g, 1.45 mmol), P(t-Bu)₃ (0.59 g, 2.90 mmol), NaOt-Bu (9.28 g, 96.6 mmol) were added and stirred at 100° C. After the reaction was completed, the organic layer was extracted with toluene and water, dried over MgSO₄, concentrated, and the resulting compound was recrystallized using a silica gel column to obtain the product (25.3 g, 69%).

### 9. Synthesis Example of P1-78

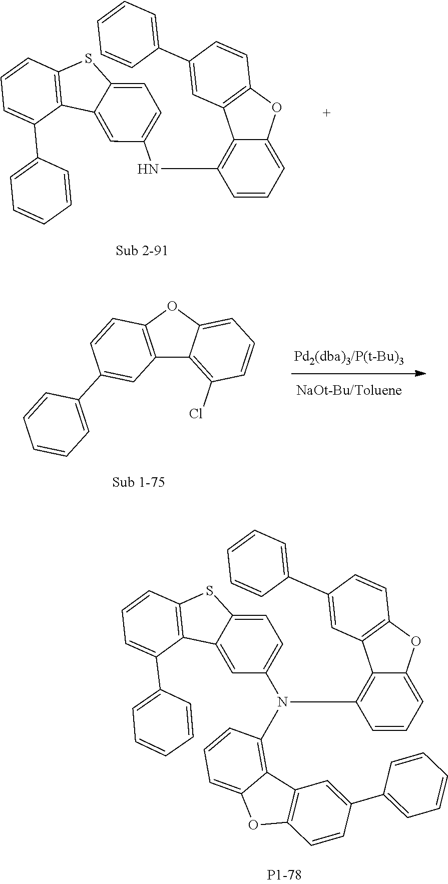 [SMILES: c1ccc(-c2ccc3oc4cccc(Nc5ccc6sc7cccc(-c8ccccc8)c7c6c5)c4c3c2)cc1 ; Clc1cccc2oc3ccc(-c4ccccc4)cc3c12 ; c1ccc(-c2ccc3oc4cccc(N(c5ccc6sc7cccc(-c8ccccc8)c7c6c5)c5cccc6oc7ccc(-c8ccccc8)cc7c56)c4c3c2)cc1]

Sub 2-91 (25 g, 48.3 mmol), Toluene (160 mL), Sub 1-75 (13.5 g, 48.3 mmol), Pd₂(dba)₃ (1.33 g, 1.45 mmol), P(t-Bu)₃ (0.59 g, 2.90 mmol), NaOt-Bu (9.28 g, 96.6 mmol) were added and stirred at 100° C. After the reaction was completed, the organic layer was extracted with toluene and water, dried over MgSO₄, concentrated, and the resulting compound was recrystallized using a silica gel column to obtain the product (26.8 g, 73%).

### 10. Synthesis Example of P1-96

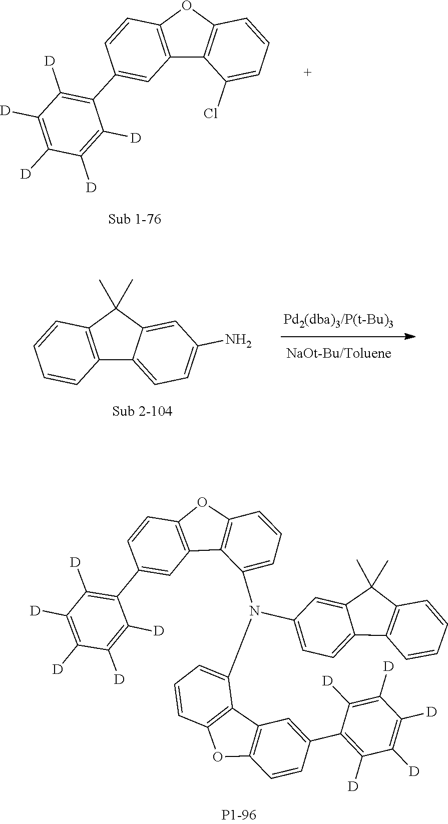 [SMILES: [2H]c1c([2H])c([2H])c(-c2ccc3oc4cccc(Cl)c4c3c2)c([2H])c1[2H] ; CC1(C)c2ccccc2-c2ccc(N)cc21 ; [2H]c1c([2H])c([2H])c(-c2ccc3oc4cccc(N(c5ccc6c(c5)C(C)(C)c5ccccc5-6)c5cccc6oc7ccc(-c8c([2H])c([2H])c([2H])c([2H])c8[2H])cc7c56)c4c3c2)c([2H])c1[2H]]

Sub 1-76 (10 g, 47.8 mmol), Toluene (160 mL), Sub 2-104 (27.1 g, 100.3 mmol), Pd₂(dba)₃ (2.19 g, 2.39 mmol), P(t-Bu)₃ (0.97 g, 4.78 mmol), NaOt-Bu (13.89, 143.3 mmol) were added and stirred at 100-8. After the reaction was completed, the organic layer was extracted with toluene and water, dried over MgSO₄, concentrated, and the resulting compound was recrystallized using a silica gel column to obtain the product (25.2 g, 75%).

The FD-MS values of compounds P1-1 to P1-97 of the present invention manufactured according to the above synthetic examples are as shown in Table 3.

TABLE 3

| compound | FD-MS | compound | FD-MS |
|---|---|---|---|
| P1-1 | m/z = 473.21(C₃₆H₂₇N = 473.62) | P1-2 | m/z = 471.20(C₃₆H₂₅N = 471.60) |
| P1-3 | m/z = 675.29(C₅₂H₃₇N = 675.88) | P1-4 | m/z = 715.29(C₅₄H₃₇NO = 715.90) |
| P1-5 | m/z = 623.26(C₄₈H₃₃N = 623.80) | P1-6 | m/z = 649.28(C₅₀H₃₅N = 649.84) |
| P1-7 | m/z = 667.39(C₅₀H₁₇D₁₈N = 667.95) | P1-8 | m/z = 749.31(C₅₈H₃₉N = 749.96) |
| P1-9 | m/z = 653.24(C₄₈H₃₁NO₂ = 653.78) | P1-10 | m/z = 567.17(C₄₀H₂₅NOS = 567.71) |
| P1-11 | m/z = 531.13(C₃₆H₂₁NO₂S = 531.63) | P1-12 | m/z = 593.18(C₄₂H₂₇NOS = 593.74) |
| P1-13 | m/z = 527.17(C₃₈H₂₅NS = 527.68) | P1-14 | m/z = 561.21(C₄₂H₂₇NO = 561.68) |
| P1-15 | m/z = 527.22(C₃₉H₂₉NO = 527.67) | P1-16 | m/z = 769.30(C₅₇H₃₉NO₂ = 769.94) |
| P1-17 | m/z = 643.29(C₄₈H₃₇NO = 643.83) | P1-18 | m/z = 719.32(C₅₄H₄₁NO = 719.93) |
| P1-19 | m/z = 767.32(C₅₈H₄₁NO = 767.97) | P1-20 | m/z = 651.26(C₄₉H₃₃NO = 651.81) |
| P1-21 | m/z = 731.36(C₅₆H₄₅N = 731.98) | P1-22 | m/z = 717.34(C₅₅H₄₃N = 717.96) |
| P1-23 | m/z = 767.36(C₅₉H₄₅N = 768.02) | P1-24 | m/z = 767.36(C₅₉H₄₅N = 768.02) |
| P1-25 | m/z = 817.33(C₆₂H₄₃NO = 818.03) | P1-26 | m/z = 727.29(C₅₅H₃₇NO = 727.91) |
| P1-27 | m/z = 817.33(C₆₂H₄₃NO = 818.03) | P1-28 | m/z = 703.25(C₅₂H₃₃NO₂ = 703.84) |
| P1-29 | m/z = 869.40(C₆₇H₅₁N = 870.15) | P1-30 | m/z = 767.36(C₅₉H₄₅N = 768.02) |
| P1-31 | m/z = 562.24(C₄₂H₃₀N₂ = 562.72) | P1-32 | m/z = 686.27(C₅₂H₃₄N₂ = 686.86) |
| P1-33 | m/z = 586.24(C₄₄H₃₀N₂ = 586.74) | P1-34 | m/z = 602.27(C₄₅H₃₄N₂ = 602.78) |
| P1-35 | m/z = 602.27(C₄₅H₃₄N₂ = 602.78) | P1-36 | m/z = 649.24(C₄₉H₃₁NO = 649.79) |
| P1-37 | m/z = 673.24(C₅₁H₃₁NO = 673.81) | P1-38 | m/z = 711.29(C₅₅H₃₇N = 711.91) |
| P1-39 | m/z = 725.27(C₅₅H₃₅NO = 725.89) | P1-40 | m/z = 965.38(C₇₃H₄₇N₃ = 966.20) |
| P1-41 | m/z = 815.32(C₆₂H₄₁NO = 816.02) | P1-42 | m/z = 919.42(C₇₁H₅₃N = 920.21) |
| P1-43 | m/z = 753.30(C₅₇H₃₉NO = 753.94) | P1-44 | m/z = 758.24(C₅₄H₃₄N₂OS = 758.94) |
| P1-45 | m/z = 717.25(C₅₃H₃₅NS = 717.93) | P1-46 | m/z = 891.35(C₆₈H₄₅NO = 892.11) |
| P1-47 | m/z = 759.22(C₅₄H₃₃NO₂S = 759.92) | P1-48 | m/z = 705.27(C₅₂H₃₅NO₂ = 705.86) |
| P1-49 | m/z = 691.29(C₅₂H₃₇NO = 691.87) | P1-50 | m/z = 757.24(C₅₅H₃₅NOS = 757.95) |
| P1-51 | m/z = 849.34(C₆₆H₄₃N = 850.08) | P1-52 | m/z = 753.34(C₅₈H₄₃N = 753.99) |
| P1-53 | m/z = 783.35(C₅₉H₄₅NO = 784.01) | P1-54 | m/z = 747.35(C₅₆H₄₅NO = 747.98) |
| P1-55 | m/z = 761.37(C₅₇H₄₇NO = 762.01) | P1-56 | m/z = 781.30(C₅₈H₃₉NO₂ = 781.95) |
| P1-57 | m/z = 766.33(C₅₈H₄₂N₂ = 766.99) | P1-58 | m/z = 845.28(C₆₂H₃₉NOS = 846.06) |
| P1-59 | m/z = 727.32(C₅₆H₄₁N = 727.95) | P1-60 | m/z = 945.40(C₆₉H₅₅NOS = 946.26) |
| P1-61 | m/z = 643.29(C₄₈H₃₇NO = 643.83) | P1-62 | m/z = 682.21(C₄₈H₃₀N₂OS = 682.84) |
| P1-63 | m/z = 707.26(C₅₁H₃₇NOSi = 707.95) | P1-64 | m/z = 707.26(C₅₁H₃₇NOSi = 707.95) |
| P1-65 | m/z = 679.38(C₅₀H₄₉NO = 679.95) | P1-66 | m/z = 801.34(C₆₂H₄₃N = 802.03) |
| P1-67 | m/z = 691.32(C₅₃H₄₁N = 691.92) | P1-68 | m/z = 705.34(C₅₄H₄₃N = 705.94) |
| P1-69 | m/z = 761.26(C₅₄H₃₉NSSi = 762.06) | P1-70 | m/z = 695.36(C₅₃H₄₅N = 695.95) |
| P1-71 | m/z = 589.37(C₄₄H₄₇N = 589.87) | P1-72 | m/z = 603.26(C₄₅H₃₃NO = 603.76) |
| P1-73 | m/z = 753.34(C₅₈H₄₃N = 753.99) | P1-74 | m/z = 767.32(C₅₈H₄₁NO = 767.97) |
| P1-75 | m/z = 753.34(C₅₈H₄₃N = 753.99) | P1-76 | m/z = 759.22(C₅₄H₃₃NO₂S = 759.92) |
| P1-77 | m/z = 759.22(C₅₄H₃₃NO₂S = 759.92) | P1-78 | m/z = 759.22(C₅₄H₃₃NO₂S = 759.92) |
| P1-79 | m/z = 763.32(C₅₉H₄₁N = 763.98) | P1-80 | m/z = 753.34(C₅₈H₄₃N = 753.99) |
| P1-81 | m/z = 639.29(C₄₉H₃₇N = 639.84) | P1-82 | m/z = 685.33(C₅₁H₄₃NO = 685.91) |
| P1-83 | m/z = 665.37(C₄₉H₄₇NO = 665.92) | P1-84 | m/z = 651.39(C₄₉H₄₉N = 651.94) |
| P1-85 | m/z = 750.49(C₅₅H₆₂N₂ = 751.11) | P1-86 | m/z = 577.37(C₄₃H₄₇N = 577.86) |
| P1-87 | m/z = 773.50(C₅₈H₆₃N = 774.15) | P1-88 | m/z = 695.36(C₅₃H₄₅N = 695.95) |
| P1-89 | m/z = 533.27(C₃₉H₃₅NO = 533.71) | P1-90 | m/z = 719.32(C₅₄H₄₁NO = 719.93) |
| P1-91 | m/z = 709.24(C₅₁H₃₅NOS = 709.91) | P1-92 | m/z = 768.31(C₅₇H₄₀N₂O = 768.96) |
| P1-93 | m/z = 767.33(C₅₇H₄₁N₃ = 767.98) | P1-94 | m/z = 767.33(C₅₇H₄₁N₃ = 767.98) |
| P1-95 | m/z = 693.27(C₅₁H₃₅NO₂ = 693.85) | P1-96 | m/z = 703.33(C₅₁H₂₅D₁₀NO₂ = 703.91) |
| P1-97 | m/z = 683.33(C₅₁H₃₃D₅N₂ = 683.91) | | |

### [Synthesis Example 2] Synthesis Example of Formula 2

The compound represented by Formula 2 according to the present invention (final product 2) can be synthesized according to the reaction path of the following reaction scheme 2, but is not limited thereto.

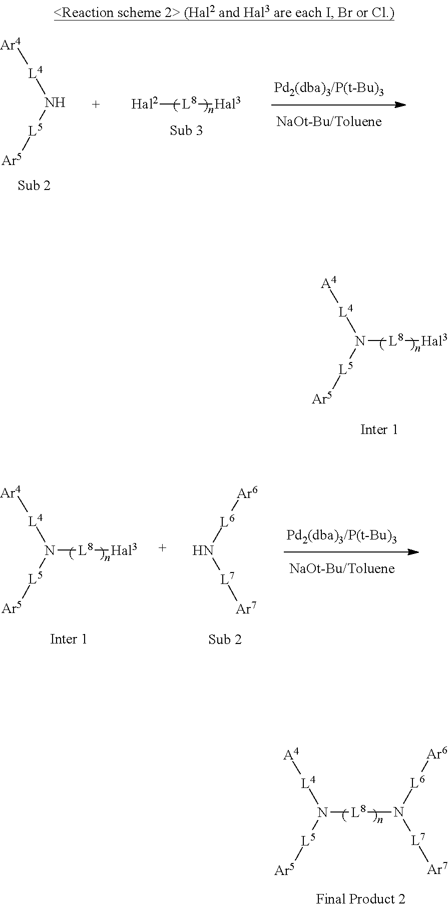

Compounds belonging to Sub 3 of the reaction scheme 2 may be, but are not limited to, the compounds, and Table 4 shows the FD-MS (Field Desorption-Mass Spectrometry) values of the compounds.

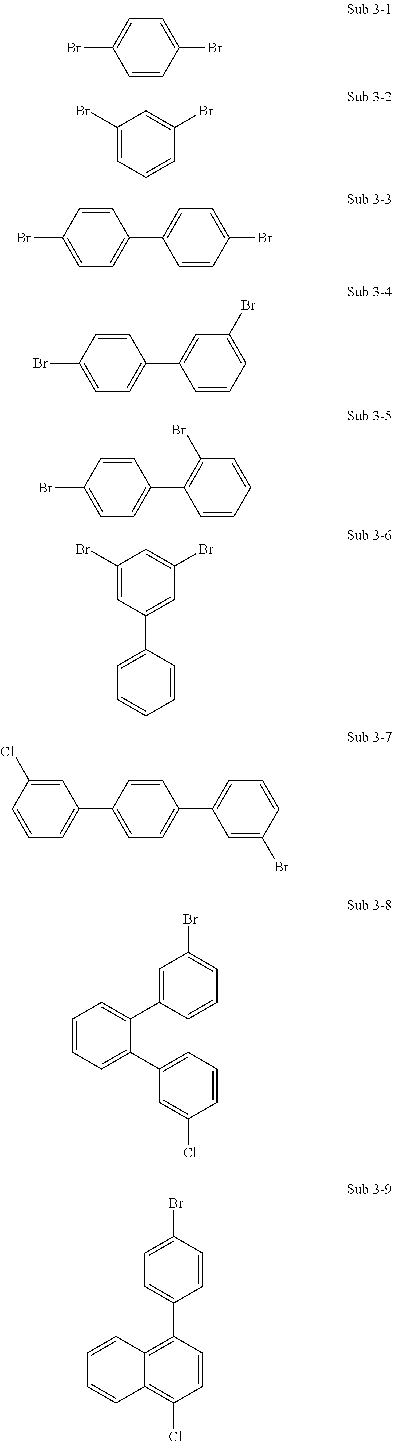

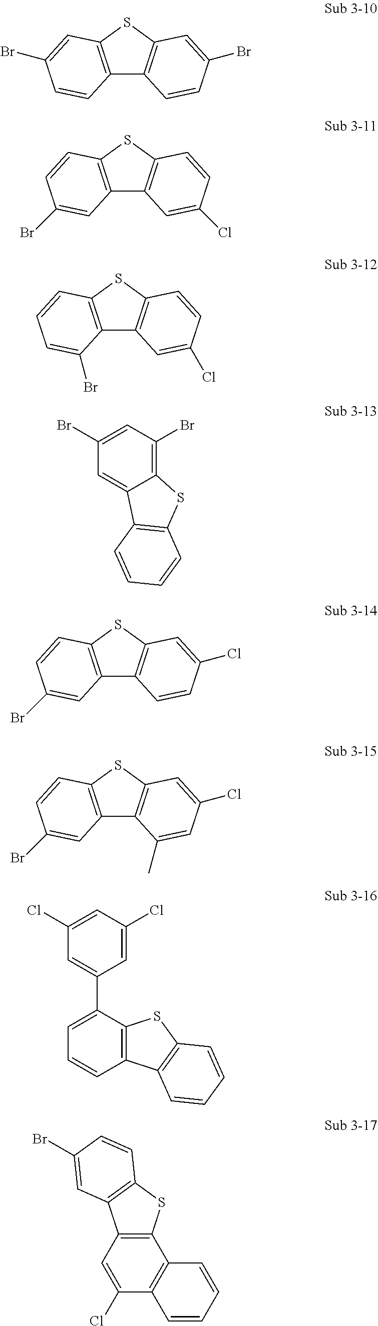

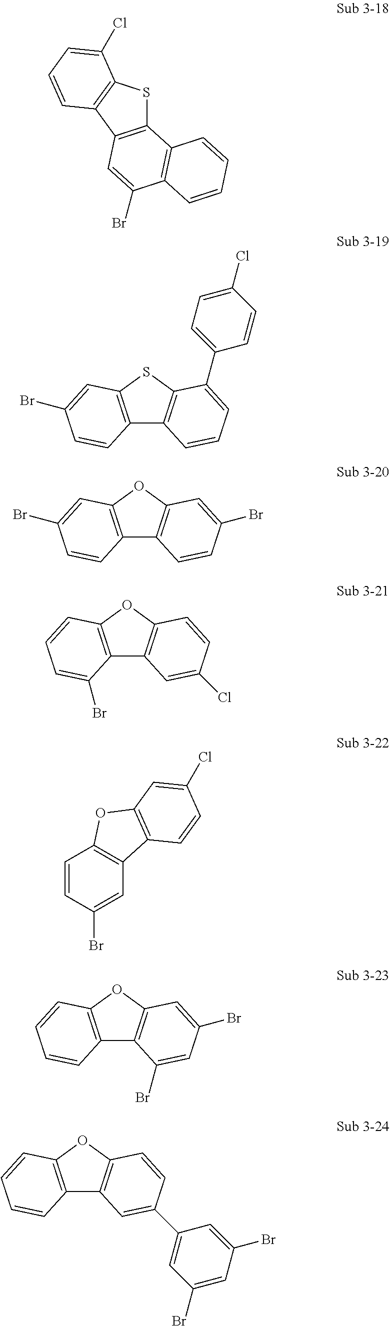

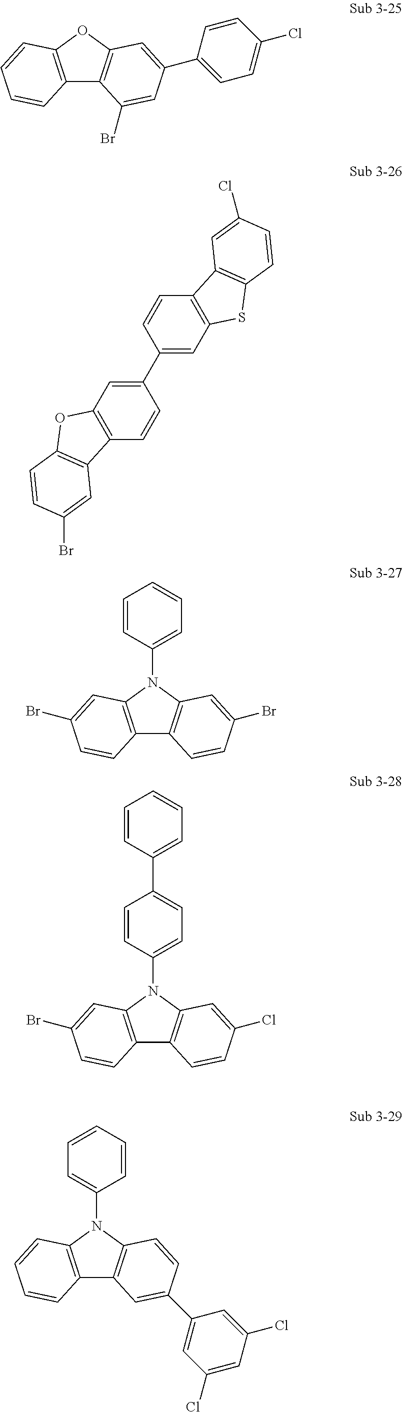 [SMILES: Clc1ccc(-c2cc(Br)c3c(c2)oc2ccccc23)cc1 ; Clc1ccc2sc3cc(-c4ccc5c(c4)oc4ccc(Br)cc45)ccc3c2c1 ; Brc1ccc2c3ccc(Br)cc3n(-c3ccccc3)c2c1 ; Clc1ccc2c3ccc(Br)cc3n(-c3ccc(-c4ccccc4)cc3)c2c1 ; Clc1cc(Cl)cc(-c2ccc3c(c2)c2ccccc2n3-c2ccccc2)c1]

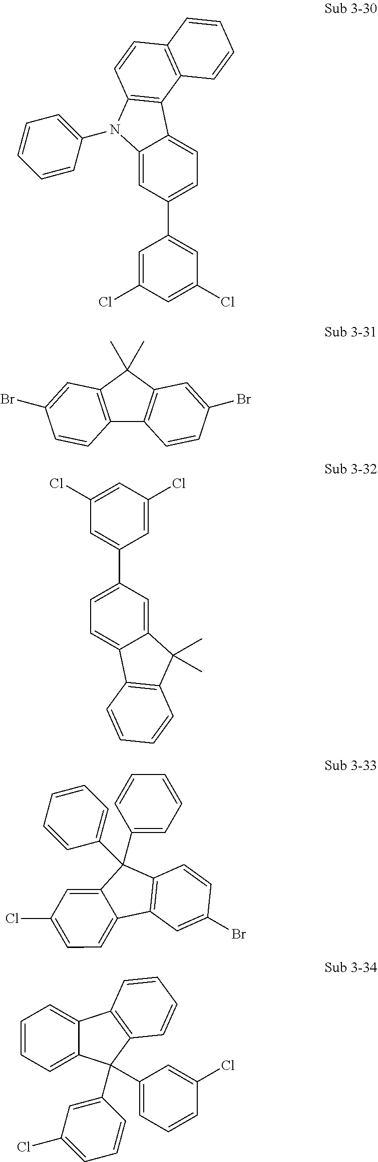

TABLE 4

| compound | FD-MS | compound | FD-MS |
|---|---|---|---|
| Sub 3-1 | m/z = 235.87(C₆H₄Br₂ = 235.91) | Sub 3-2 | m/z = 235.87(C₆H₄Br₂ = 235.91) |
| Sub 3-3 | m/z = 311.90(C₁₂H₈Br₂ = 312.00) | Sub 3-4 | m/z = 311.90(C₁₂H₈Br₂ = 312.00) |
| Sub 3-5 | m/z = 311.90(C₁₂H₈Br₂ = 312.00) | Sub 3-6 | m/z = 311.90(C₁₂H₈Br₂ = 312.00) |
| Sub 3-7 | m/z = 343.98(C₁₈H₁₂BrCl = 343.65) | Sub 3-8 | m/z = 343.98(C₁₈H₁₂BrCl = 343.65) |
| Sub 3-9 | m/z = 317.96(C₁₆H₁₀BrCl = 317.61) | Sub 3-10 | m/z = 341.85(C₁₂H₆Br₂S = 342.05) |
| Sub 3-11 | m/z = 297.90(C₁₂H₆BrClS = 297.59) | Sub 3-12 | m/z = 297.90(C₁₂H₆BrClS = 297.59) |
| Sub 3-13 | m/z = 341.85(C₁₂H₆Br₂S = 342.05) | Sub 3-14 | m/z = 297.90(C₁₂H₆BrClS = 297.59) |
| Sub 3-15 | m/z = 311.92(C₁₃H₈BrClS = 311.62) | Sub 3-16 | m/z = 327.99(C₁₈H₁₀Cl₂S = 329.24) |
| Sub 3-17 | m/z = 347.92(C₁₆H₈BrClS = 347.65) | Sub 3-18 | m/z = 347.92(C₁₆H₈BrClS = 347.65) |
| Sub 3-19 | m/z = 371.94(C₁₈H₁₀BrClS = 373.69) | Sub 3-20 | m/z = 325.88(C₁₂H₆Br₂O = 325.99) |
| Sub 3-21 | m/z = 281.93(C₁₂H₆BrClO = 281.53) | Sub 3-22 | m/z = 281.93(C₁₂H₆BrClO = 281.53) |
| Sub 3-23 | m/z = 325.88(C₁₂H₆Br₂O = 325.99) | Sub 3-24 | m/z = 401.91(C₁₈H₁₀Br₂O = 402.08) |
| Sub 3-25 | m/z = 357.96(C₁₈H₁₀BrClO = 357.63) | Sub 3-26 | m/z = 463.95(C₂₄H₁₂BrClOS = 463.77) |
| Sub 3-27 | m/z = 400.92(C₁₈H₁₁Br₂N = 401.10) | Sub 3-28 | m/z = 433.01(C₂₄H₁₅BrClN = 432.75) |
| Sub 3-29 | m/z = 387.06(C₂₄H₁₅Cl₂N = 388.29) | Sub 3-30 | m/z = 437.07(C₂₈H₁₇Cl₂N = 438.35) |
| Sub 3-31 | m/z = 351.93(C₁₅H₁₂Br₂ = 352.07) | Sub 3-32 | m/z = 338.06(C₂₁H₁₆Cl₂ = 339.26) |
| Sub 3-33 | m/z = 386.06(C₂₅H₁₆Cl₂ = 387.30) | Sub 3-34 | m/z = 386.06(C₂₅H₁₆Cl₂ = 387.30) |

### Synthesis Example of Final Compound

### 1. Synthesis Example of P2-31

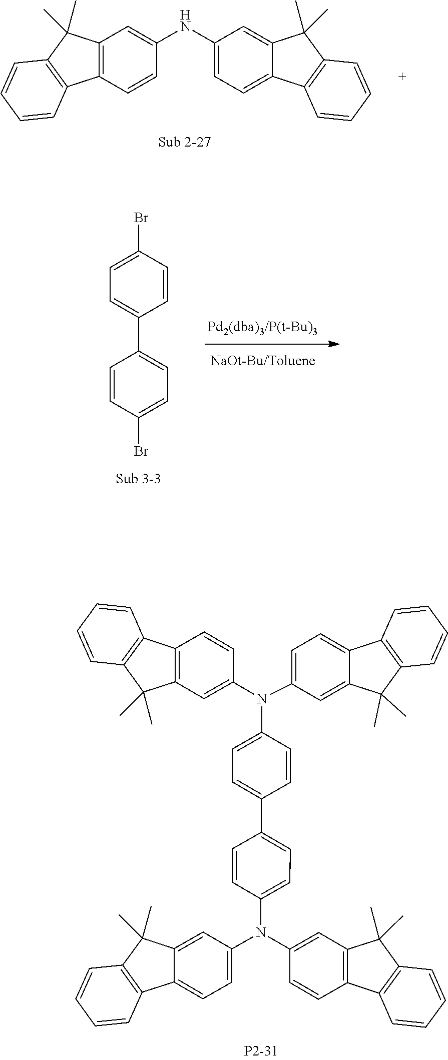 [SMILES: CC1(C)c2ccccc2-c2ccc(Nc3ccc4c(c3)C(C)(C)c3ccccc3-4)cc21 ; Brc1ccc(-c2ccc(Br)cc2)cc1 ; CC1(C)c2ccccc2-c2ccc(N(c3ccc(-c4ccc(N(c5ccc6c(c5)C(C)(C)c5ccccc5-6)c5ccc6c(c5)C(C)(C)c5ccccc5-6)cc4)cc3)c3ccc4c(c3)C(C)(C)c3ccccc3-4)cc21]

Sub 2-27 (25.7 g, 64.1 mmol), Toluene (105 mL), Sub 3-3 (10 g, 32.1 mmol), Pd₂(dba)₃ (1.47 g, 1.60 mmol), P(t-Bu)₃ (0.65 g, 3.21 mmol), NaOt-Bu (9.24 g, 96.2 mmol) were added and stirred at 100° C. After the reaction was completed, the organic layer was extracted with toluene and water, dried over MgSO₄, concentrated, and the resulting compound was recrystallized using a silica gel column to obtain the product (25.7 g, 84%).

### 2. Synthesis Example of P2-37

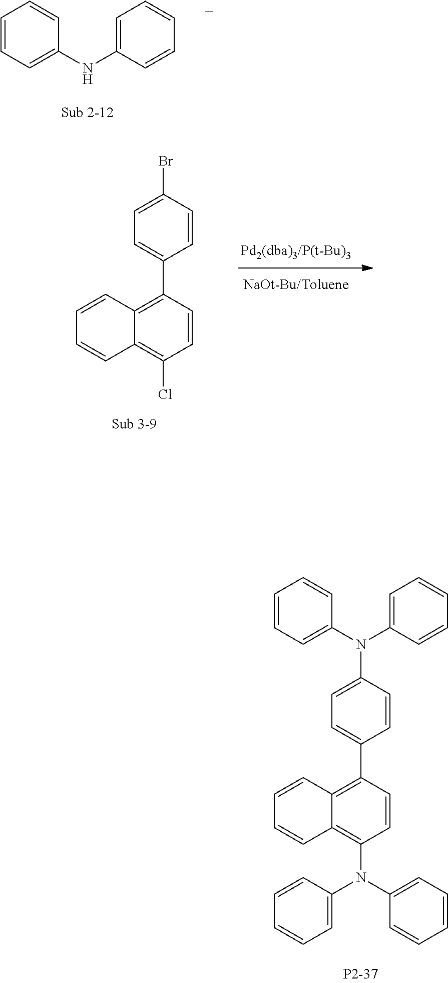 [SMILES: c1ccc(Nc2ccccc2)cc1 ; Clc1ccc(-c2ccc(Br)cc2)c2ccccc12 ; c1ccc(N(c2ccccc2)c2ccc(-c3ccc(N(c4ccccc4)c4ccccc4)c4ccccc34)cc2)cc1]

Sub 2-12 (16 g, 94.5 mmol), Toluene (160 mL), Sub 3-9 (15 g, 47.2 mmol), Pd₂(dba)₃ (2.16 g, 2.36 mmol), P(t-Bu)₃ (0.96 g, 4.72 mmol), NaOt-Bu (13.6 g, 141.7 mmol) were added and stirred at 100° C. After the reaction was completed, the organic layer was extracted with toluene and water, dried over MgSO₄, concentrated, and the resulting compound was recrystallized using a silica gel column to obtain the product (18.1 g, 71%).

### 3. Synthesis Example of P2-52

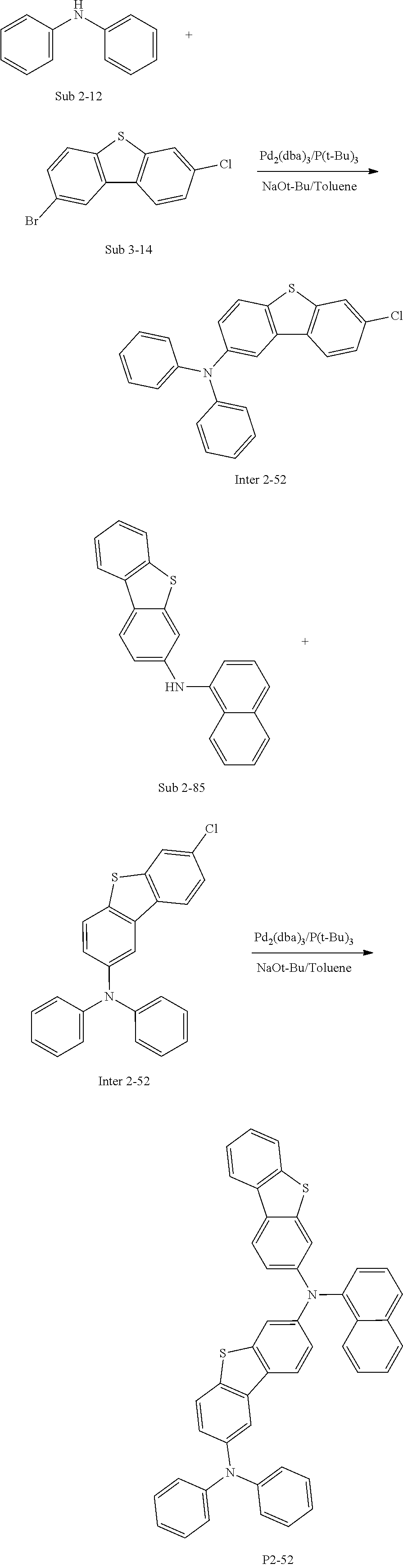 [SMILES: c1ccc(Nc2ccccc2)cc1 ; Clc1ccc2c(c1)sc1ccc(Br)cc12 ; Clc1ccc2c(c1)sc1ccc(N(c3ccccc3)c3ccccc3)cc12 ; c1ccc2c(Nc3ccc4c(c3)sc3ccccc34)cccc2c1 ; Clc1ccc2c(c1)sc1ccc(N(c3ccccc3)c3ccccc3)cc12 ; c1ccc(N(c2ccccc2)c2ccc3sc4cc(N(c5ccc6c(c5)sc5ccccc56)c5cccc6ccccc56)ccc4c3c2)cc1]

### (1) Synthesis of Inter 2-52

Sub 2-12 (15 g, 88.6 mmol), Toluene (300 mL), Sub 3-14 (26.4 g, 88.6 mmol), Pd₂(dba)₃ (2.44 g, 2.66 mmol), P(t-Bu)₃ (1.08 g, 5.32 mmol), NaOt-Bu (17.0 g, 177.3 mmol) were added and stirred at 70° C. After the reaction was completed, the organic layer was extracted with toluene and water, dried over MgSO₄, concentrated, and the resulting compound was recrystallized using a silica gel column to obtain the product (23.6 g, 69%).

### (2) Synthesis of P2-52

Sub 2-85 (18 g, 55.3 mmol), Toluene (180 mL), Inter 2-52 (21.4 g, 55.3 mmol), Pd₂(dba)₃ (1.52 g, 1.66 mmol), P(t-Bu)₃ (0.67 g, 3.32 mmol), NaOt-Bu (10.6 g, 110.6 mmol) were added and stirred at 100° C. After the reaction was completed, the organic layer was extracted with toluene and water, dried over MgSO₄, concentrated, and the resulting compound was recrystallized using a silica gel column to obtain the product (27.6 g, 74%).

### 4. Synthesis of P2-68

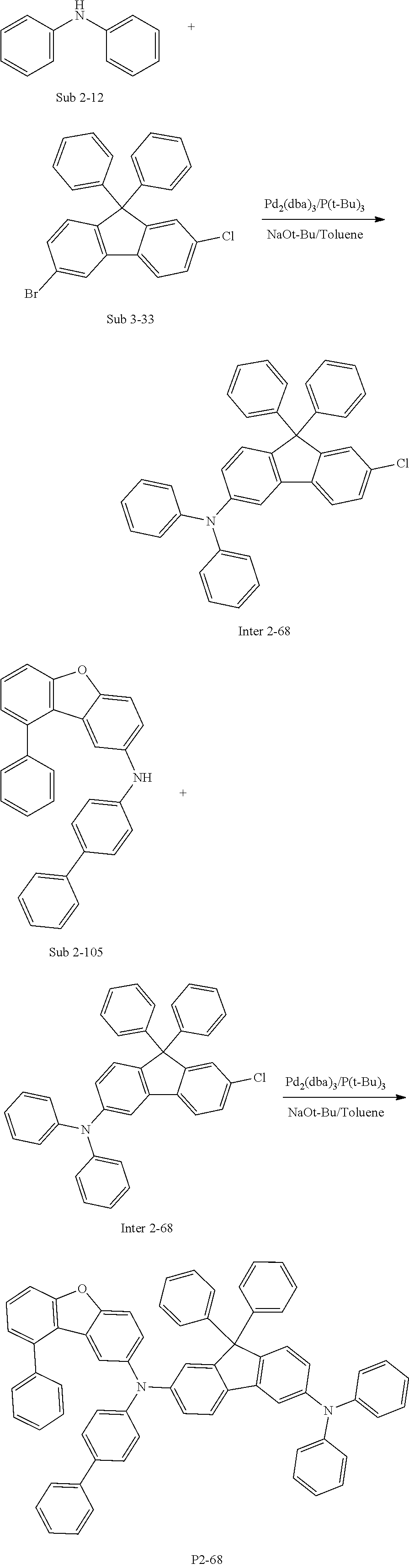 [SMILES: c1ccc(Nc2ccccc2)cc1 ; Clc1ccc2c(c1)C(c1ccccc1)(c1ccccc1)c1ccc(Br)cc1-2 ; Clc1ccc2c(c1)C(c1ccccc1)(c1ccccc1)c1ccc(N(c3ccccc3)c3ccccc3)cc1-2 ; c1ccc(-c2ccc(Nc3ccc4oc5cccc(-c6ccccc6)c5c4c3)cc2)cc1 ; Clc1ccc2c(c1)C(c1ccccc1)(c1ccccc1)c1ccc(N(c3ccccc3)c3ccccc3)cc1-2 ; c1ccc(-c2ccc(N(c3ccc4c(c3)C(c3ccccc3)(c3ccccc3)c3ccc(N(c5ccccc5)c5ccccc5)cc3-4)c3ccc4oc5cccc(-c6ccccc6)c5c4c3)cc2)cc1]

### (1) Synthesis of Inter 2-68

Sub 2-12 (10 g, 59.1 mmol), Toluene (200 mL), Sub 3-33 (25.5 g, 59.1 mmol), Pd₂(dba)₃ (1.62 g, 1.77 mmol), P(t-Bu)₃ (0.72 g, 3.55 mmol), NaOt-Bu (11.4 g, 118.2 mmol) were added and stirred at 70° C. After the reaction was completed, the organic layer was extracted with toluene and water, dried over MgSO₄, concentrated, and the resulting compound was recrystallized using a silica gel column to obtain the product (20.0 g, 65%).

### (2) Synthesis of P2-68

Sub 2-105 (15 g, 36.5 mmol), Toluene (120 mL), Inter 2-68 (19.0 g, 36.5 mmol), Pd₂(dba)₃ (1.0 g, 1.09 mmol), P(t-Bu)₃ (0.44 g, 2.19 mmol), NaOt-Bu (7.01 g, 72.9 mmol) were added and stirred at 100° C. After the reaction was completed, the organic layer was extracted with toluene and water, dried over MgSO₄, concentrated, and the resulting compound was recrystallized using a silica gel column to obtain the product (25.1 g, 77%).

### 5. Synthesis of P2-77

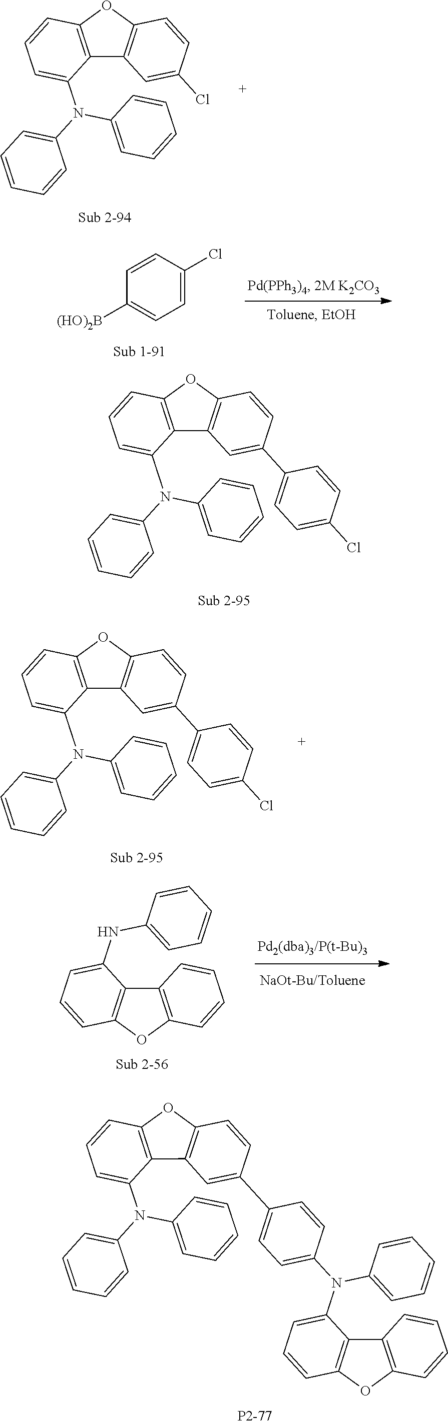 [SMILES: Clc1ccc2oc3cccc(N(c4ccccc4)c4ccccc4)c3c2c1 ; OB(O)c1ccc(Cl)cc1 ; Clc1ccc(-c2ccc3oc4cccc(N(c5ccccc5)c5ccccc5)c4c3c2)cc1 ; Clc1ccc(-c2ccc3oc4cccc(N(c5ccccc5)c5ccccc5)c4c3c2)cc1 ; c1ccc(Nc2cccc3oc4ccccc4c23)cc1 ; c1ccc(N(c2ccc(-c3ccc4oc5cccc(N(c6ccccc6)c6ccccc6)c5c4c3)cc2)c2cccc3oc4ccccc4c23)cc1]

### (1) Synthesis of Sub 2-95

Sub 2-94 (30 g, 81.1 mmol), THE (270 mL), Sub 1-91 (12.7 g, 81.1 mmol), Pd(PPh₃)₄ (2.81 g, 2.43 mmol), 2M K₂CO₃ (81 mL, 162.2 mmol) were added and stirred at 70° C. After the reaction was completed, the organic layer was extracted with toluene and water, dried over MgSO₄, concentrated, and the resulting compound was recrystallized using a silica gel column to obtain the product (23.5 g, 65%).

### (2) Synthesis of P2-77

Sub 2-95 (23.5 g, 52.7 mmol), Toluene (175 mL), Sub 2-56 (13.7 g, 52.7 mmol), Pd₂(dba)₃ (1.45 g, 1.58 mmol), P(t-Bu)₃ (0.64 g, 3.16 mmol), NaOt-Bu (10.1 g, 105.4 mmol) were added and stirred at 100° C. After the reaction was completed, the organic layer was extracted with toluene and water, dried over MgSO₄, concentrated, and the resulting compound was recrystallized using a silica gel column to obtain the product (27.1 g, 77%).

The FD-MS values of compounds P2-1 to P2-81 of the present invention manufactured according to the synthetic examples are as shown in Table 5.

TABLE 5

| compound | FD-MS | compound | FD-MS |
|---|---|---|---|
| P2-1 | m/z = 716.32(C54H40N2 = 716.93) | P2-2 | m/z = 792.35(C60H44N2 = 793.03) |
| P2-3 | m/z = 806.33(C60H42N2O = 807.01) | P2-4 | m/z = 822.31(C60H42N2S = 823.07) |
| P2-5 | m/z = 881.38(C66H47N3 = 882.12) | P2-6 | m/z = 832.38(C63H48N2 = 833.09) |
| P2-7 | m/z = 868.38(C66H48N2 = 869.12) | P2-8 | m/z = 866.37(C66H46N2 = 867.11) |
| P2-9 | m/z = 842.37(C64H46N2 = 843.09) | P2-10 | m/z = 816.35(C62H44N2 = 817.05) |
| P2-11 | m/z = 918.40(C70H50N2 = 919.18) | P2-12 | m/z = 931.39(C70H49N3 = 932.18) |
| P2-13 | m/z = 790.21(C54H34N2OS2 = 791.00) | P2-14 | m/z = 912.32(C66H44N2OS = 913.15) |
| P2-15 | m/z = 664.29(C50H36N2 = 664.85) | P2-16 | m/z = 652.25(C48H32N2O = 652.80) |
| P2-17 | m/z = 550.20(C40H26N2O = 550.66) | P2-18 | m/z = 1037.47(C78H59N3 = 1038.35) |
| P2-19 | m/z = 756.35(C57H44N2 = 756.99) | P2-20 | m/z = 698.20(C48H30N2O2S = 698.84) |
| P2-21 | m/z = 894.37(C66H46N4 = 895.12) | P2-22 | m/z = 885.32(C64H43N3S = 886.13) |
| P2-23 | m/z = 832.32(C60H40N4O = 833.01) | P2-24 | m/z = 682.23(C48H30N2O3 = 682.78) |
| P2-25 | m/z = 819.32(C60H41N3O = 820.01) | P2-26 | m/z = 832.31(C61H40N2O2 = 833.00) |
| P2-27 | m/z = 743.29(C54H37N3O = 743.91) | P2-28 | m/z = 818.33(C61H42N2O = 819.02) |
| P2-29 | m/z = 791.24(C54H37N3S2 = 792.03) | P2-30 | m/z = 879.36(C66H45N3 = 880.11) |
| P2-31 | m/z = 952.48(C72H60N2 = 953.29) | P2-32 | m/z = 800.23(C56H36N2S2 = 801.04) |
| P2-33 | m/z = 780.31(C58H40N2O = 780.97) | P2-34 | m/z = 904.38(C69H48N2 = 905.16) |
| P2-35 | m/z = 664.29(C50H36N2 = 664.85) | P2-36 | m/z = 674.19(C46H30N2S2 = 674.88) |
| P2-37 | m/z = 538.24(C40H30N2 = 538.69) | P2-38 | m/z = 674.19(C46H30N2S = 674.88) |
| P2-39 | m/z = 846.29(C61H38N2O3 = 846.99) | P2-40 | m/z = 888.32(C64H44N2OS = 889.13) |
| P2-41 | m/z = 830.29(C61H38N2O2 = 830.99) | P2-42 | m/z = 832.31(C61H40N2O2 = 833.00) |
| P2-43 | m/z = 792.39(C57H52N2Si = 793.14) | P2-44 | m/z = 896.34(C66H44N2O2 = 897.09) |
| P2-45 | m/z = 694.24(C50H34N2S = 694.90) | P2-46 | m/z = 608.19(C42H28N2OS = 608.76) |
| P2-47 | m/z = 668.25(C48H32N2O2 = 668.80) | P2-48 | m/z = 791.24(C54H37N3S2 = 792.03) |
| P2-49 | m/z = 658.21(C46H30N2OS = 658.82) | P2-50 | m/z = 624.17(C42H28N2S2 = 624.82) |
| P2-51 | m/z = 700.20(C48H32N2S2 = 700.92) | P2-52 | m/z = 674.19(C46H30N2S2 = 674.88) |
| P2-53 | m/z = 791.24(C54H37N3S2 = 792.03) | P2-54 | m/z = 638.19(C43H30N2S2 = 638.85) |
| P2-55 | m/z = 624.17(C42H28N2S2 = 624.82) | P2-56 | m/z = 674.19(C46H30N2S2 = 674.88) |
| P2-57 | m/z = 684.22(C48H32N2OS = 684.86) | P2-58 | m/z = 775.27(C54H37N3OS = 775.97) |
| P2-59 | m/z = 848.29(C61H40N2OS = 849.06) | P2-60 | m/z = 800.29(C57H40N2OS = 801.02) |
| P2-61 | m/z = 668.25(C48H32N2O2 = 668.80) | P2-62 | m/z = 710.28(C51H38N2S = 710.94) |
| P2-63 | m/z = 891.33(C63H45N3OS = 892.13) | P2-64 | m/z = 848.29(C61H40N2OS = 849.06) |
| P2-65 | m/z = 774.27(C55H38N2OS = 774.98) | P2-66 | m/z = 682.23(C48H30N2O3 = 682.78) |
| P2-67 | m/z = 758.26(C54H34N2O3 = 758.88) | P2-68 | m/z = 894.36(C67H46N2O = 895.12) |
| P2-69 | m/z = 1112.43(C83H56N2O2 = 1113.37) | P2-70 | m/z = 849.30(C60H39N3O3 = 849.99) |
| P2-71 | m/z = 834.29(C60H38N2O3 = 834.97) | P2-72 | m/z = 818.33(C61H42N2O = 819.02) |
| P2-73 | m/z = 744.28(C54H36N2O2 = 744.89) | P2-74 | m/z = 916.39(C67H52N2S = 917.23) |
| P2-75 | m/z = 837.34(C61H35D5N2O2 = 838.03) | P2-76 | m/z = 758.26(C54H34N2O3 = 758.88) |
| P2-77 | m/z = 668.25(C48H32N2O2 = 668.80) | P2-78 | m/z = 846.29(C61H38N2O3 = 846.99) |
| P2-79 | m/z = 784.31(C57H40N2O2 = 784.96) | | |

Meanwhile, an exemplary synthesis example of the present invention represented by Formula 1 or Formula 2 has been described above, but these are all based on the Buchwald-Hartwig cross coupling reaction, Miyaura boration reaction, Suzuki cross-coupling reaction, Intramolecular acid-induced cyclization reaction (J. mater. Chem. 1999, 9, 2095.), Pd(II)-catalyzed oxidative cyclization reaction (Org. Lett. 201 1, 13, 5504), and PPh₃-mediated reductive cyclization reaction (J. Org. Chem. 2005, 70, 5014.), and those skilled in the art will easily understand that the above reaction proceeds even if substituents other than those specified in the specific synthesis examples are bonded to.

### Experimental Example of Measuring the Lateral Resistance Change Ratio

### 1. Measurement of Lateral Resistance

The term “lateral resistance” used in this specification is a numerical value representing the resistance to leakage current in an organic layer, and the higher the lateral resistance value, the lower the lateral leakage current. The lateral resistance can be obtained through the measured value using the Maxscience M6100 Source meter.

$$R = \frac{V}{I}$$

(R: resistance, I: current, V: voltage)

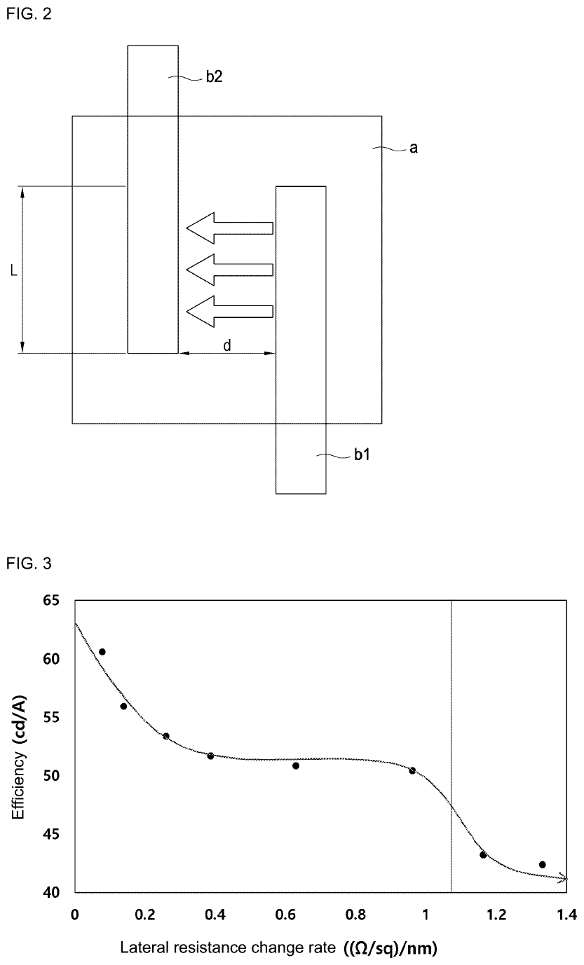

FIG. 2 is a schematic diagram for the experimental setup for measuring lateral resistance using a Maxscience M6100 Source meter.

In FIG. 2, a is an insulator, b1 is a cathode, b2 is an anode, d is the distance between b1 and b2, and L represents the length of the electrode through which current can flow between b1 and b2 (hereinafter, active electrode length). Although only electrodes b1 and b2 are disclosed in FIG. 2, the electrodes may be composed of an even number of electrodes, from 2 to 20. A hole injection layer, a hole transport layer, and an emitting auxiliary layer are sequentially laminated between the anode and the cathode. Wherein, the hole injection layer can be composed of 10 nm, the hole transport layer can be composed of 110 nm, and the emitting auxiliary layer can be composed of 10 nm to 75 nm.

In the element configured as in FIG. 2, d was set to 40 μm, a voltage of 100 V was applied, the current was measured, and the resistance value was calculated using the resistance-current equation.

The resistance value obtained through calculation is multiplied by the number of electrodes in the element. In the experiment, the number of electrodes was set to 20, so the value (A) was obtained by multiplying by 20 (20 Pairs, Anode Cathode 1 Pair) and then multiplying by the length (L) of the active electrode.

Afterwards, the experiment is performed in the same manner as above, but the d value is adjusted to 80 μm, 160 μm, and 320 μm to obtain the value (A).

By adjusting the d value in this way, the values (A) obtained were used to calculate the resistance value ohm/sq. using the LINEST formula in Excel, and the unit of the resistance value is expressed as Gohm (GO) for convenience.

### 2. Calculation of Lateral Resistance Change Ratio

In an element configured as shown in FIG. 2, as shown in Equation 1, the lateral resistance change ratio is calculated by calculating the ratio of the difference in lateral resistance measured according to the thickness of the emitting auxiliary layer on the hole transport layer and the difference in the thickness of the emitting auxiliary layer. It was calculated using the formula shown in Equation 1 of this specification.

The lateral resistance change ratio measured according to the lateral resistance change ratio measurement method described above is as shown in Table 6.

TABLE 6

| | | | | lateral |
|---|---|---|---|---|
| Hole | Emitting | | | resistance |
| transport | auxiliary | Rs (GΩ/sq) | Rs (GΩ/sq) | change ratio |
| layer | layer | @ 20 nm | @ 56 nm | ((Ω/sq)/nm) |
| C-1 | P1-54 | 10.48 | 58.39 | 1.33 |
| | P2-39 | 12.00 | 53.87 | 1.16 |
| | P1-78 | 25.35 | 28.12 | 0.08 |
| | P1-21 | 23.83 | 28.80 | 0.14 |
| | P1-48 | 21.63 | 30.96 | 0.26 |
| | P1-77 | 20.11 | 34.01 | 0.39 |
| | P2-77 | 16.90 | 39.54 | 0.63 |
| | P1-95 | 14.70 | 49.30 | 0.96 |
| C-2 | P1-54 | 9.13 | 49.84 | 1.13 |
| | P2-39 | 5.93 | 43.26 | 1.04 |
| | P1-78 | 13.57 | 17.42 | 0.11 |
| | P1-21 | 12.66 | 17.13 | 0.12 |
| | P1-48 | 11.86 | 20.54 | 0.24 |
| | P1-77 | 11.06 | 21.53 | 0.29 |
| | P2-77 | 10.05 | 22.18 | 0.34 |
| | P1-95 | 7.34 | 32.86 | 0.71 |
| C-3 | P1-54 | 11.83 | 51.11 | 1.09 |
| | P2-39 | 10.41 | 50.59 | 1.12 |
| | P1-78 | 39.75 | 40.50 | 0.02 |
| | P1-21 | 36.20 | 39.51 | 0.09 |
| | P1-48 | 34.54 | 40.81 | 0.17 |
| | P1-77 | 31.47 | 42.70 | 0.31 |
| | P2-77 | 23.66 | 40.18 | 0.46 |
| | P1-95 | 14.67 | 45.70 | 0.86 |

Hereinafter, the manufacture and evaluation of organic electronic elements using the compound of the present invention will be described with examples, but the present invention is not limited to the following examples.

### Manufacturing Evaluation of Organic Electronic Elements

### [Example 1] Green Organic Light Emitting Device

A hole injection layer with a thickness of 60 nm was formed by vacuum-depositing 4,4′4″ (hereinafter, abbreviated as 2-TNATA) on a ITO layer (anode) formed on a glass substrate, and then a hole transport layer was formed by vacuum-depositing the compound C-1 on the hole injection layer to a thickness of 80 nm.

After forming an emitting auxiliary layer by vacuum-depositing the compound P1-78 of the present invention on the hole transport layer to a thickness of 45 nm, and then on the emitting auxiliary layer, 4,4′-N,N′-dicarbazole-biphenyl (hereinafter abbreviated as CBP) was used as a host material, and Tris(2-phenylpyridine)iridium(III) (hereinafter abbreviated as Ir(ppy)₃) was used as a dopant material, and the dopant was doped at a weight ratio of 93:7 to form an emitting layer with a thickness of 35 nm.

Next, (1,1′biphenyl-4-olato)bis(2-methyl-8-quinolinolato)aluminum (hereinafter abbreviated as BAlq) is vacuum-deposited to a thickness of 5 nm on the light-emitting layer to form a hole blocking layer. An electron transport layer was formed by vacuum depositing 2,9-Dimethyl-4,7-diphenyl-1,10-phenanthroline (hereinafter abbreviated as BCP) to a thickness of 30 nm on the hole blocking layer.

Thereafter, LiF was deposited with a thickness of 0.2 nm on the electron transport layer to form an electron injection layer, and Al was deposited with a thickness of 150 nm on the electron injection layer to form a cathode.

### [Comparative Example 1] to [Comparative Example 2], [Example 2] to

### Example 18

An organic light-emitting device was manufactured in the same manner as in Example 1, except that the compound of the present invention described in Table 7 was used.

Electroluminescence (EL) characteristics were measured using PR-650 from Photoresearch by applying a forward bias DC voltage to the organic electroluminescence devices manufactured by Examples 1 to 18 and Comparative Examples 1 and 2 of the present invention, and the T95 lifespan was measured using a lifespan measuring device manufactured by Maxscience at a standard luminance of 5000 cd/m². The measurement results are shown in Table 7.

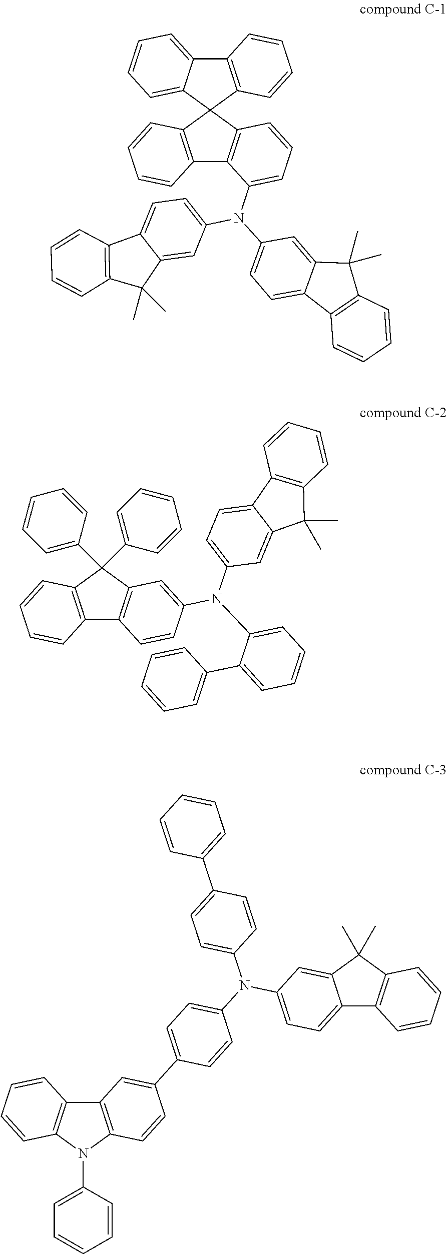 [SMILES: CC1(C)c2ccccc2-c2ccc(N(c3ccc4c(c3)C(C)(C)c3ccccc3-4)c3cccc4c3-c3ccccc3C43c4ccccc4-c4ccccc43)cc21 ; CC1(C)c2ccccc2-c2ccc(N(c3ccc4c(c3)C(c3ccccc3)(c3ccccc3)c3ccccc3-4)c3ccccc3-c3ccccc3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

This measuring device can evaluate the performance of new materials compared to comparative compounds under identical conditions, without being affected by possible daily variations in deposition rate, vacuum quality or other parameters.

Since, during the evaluation, one batch contains 4 identically prepared OLEDs including a comparative compound, and the performance of a total of 12 OLEDs is evaluated in 3 batches, the values of the experimental results obtained in this way exhibit statistical significance.

TABLE 7

| | Hole | Emitting | Volt- | Current | Effi- | |
|---|---|---|---|---|---|---|
| | transport | auxiliary | age | Density | ciency | |
| | layer | layer | (V) | (mA/cm2) | (cd/A) | T(95) |
| comparative | C-1 | P1-54 | 5.1 | 11.8 | 42.4 | 75.6 |
| example (1) | | | | | | |
| comparative | | P2-39 | 4.5 | 11.6 | 43.2 | 90.7 |
| example (2) | | | | | | |
| example(1) | C-1 | P1-78 | 4.8 | 8.2 | 60.6 | 136.8 |
| example(2) | | P1-21 | 4.5 | 8.9 | 56.0 | 167.1 |
| example(3) | | P1-48 | 4.6 | 9.4 | 53.4 | 127.8 |
| example(4) | | P1-77 | 4.7 | 9.7 | 51.7 | 136.8 |
| example(5) | | P2-77 | 4.7 | 9.8 | 50.9 | 147.4 |
| example(6) | | P1-95 | 4.5 | 9.9 | 50.5 | 124.7 |
| example(7) | C-2 | P1-78 | 4.3 | 8.7 | 57.6 | 157.4 |
| example(8) | | P1-21 | 4.4 | 9.4 | 53.2 | 192.1 |
| example(9) | | P1-48 | 4.5 | 9.9 | 50.8 | 146.9 |
| example(10) | | P1-77 | 4.5 | 10.2 | 49.1 | 157.4 |
| example(11) | | P2-77 | 4.3 | 9.9 | 50.8 | 146.9 |
| example(12) | | P1-95 | 4.1 | 10.3 | 48.3 | 169.5 |
| example(13) | C-3 | P1-78 | 5.2 | 7.5 | 66.7 | 130.0 |
| example(14) | | P1-21 | 4.9 | 8.1 | 61.6 | 158.7 |
| example(15) | | P1-48 | 5.0 | 8.5 | 58.8 | 121.4 |
| example(16) | | P1-77 | 5.1 | 8.8 | 56.9 | 130.0 |
| example(17) | | P2-77 | 5.1 | 8.9 | 56.0 | 140.0 |
| example(18) | | P1-95 | 4.9 | 9.0 | 55.5 | 118.5 |

As can be seen from the results in Table 7, when a green organic emitting device was manufactured using a material with improved lateral resistance change ratio as an emitting auxiliary layer, the efficiency and lifespan could be improved compared to the comparative example.

In Comparative Examples 1 and 2, an emitting auxiliary layer having a lateral resistance change ratio of 1.1 or more was formed. In this case, it appears that the element characteristics are reduced due to charge imbalance in which holes are increased in the emitting layer due to excessive hole injection between the hole injection layer and the emitting auxiliary layer.

Whereas, compared to Comparative Examples 1 and 2, Examples 1 to 18 form an emitting auxiliary layer, but the lateral resistance change rate is small and 1.1 or less, so it can be confirmed that the efficiency and lifespan of the element are significantly improved.

This appears to be because the amount of holes injected into the emitting layer is reduced by limiting hole injection between the hole transport layer and the emitting auxiliary layer, thereby increasing the charge balance between holes and electrons within the emitting layer.

Although exemplary embodiments of the present invention have been described for illustrative purposes, those skilled in the art will appreciate that various modifications, additions and substitutions are possible, without departing from the scope and spirit of the invention as disclosed in the accompanying claims. Therefore, the embodiment disclosed in the present invention is intended to illustrate the scope of the technical idea of the present invention, and the scope of the present invention is not limited by the embodiment.

The scope of the present invention shall be construed on the basis of the accompanying claims, and it shall be construed that all of the technical ideas included within the scope equivalent to the claims belong to the present invention.

[Description of the numerals]

| | |
|---|---|
| a: insulator | b1: cathode |
| b2: anode | d: distance between b1 and b2 |

L: length of electrode through which current can flow between b1 and b2

1. An organic electronic element comprising a first electrode; a second electrode; and an organic material layer formed between the first electrode and the second electrode, wherein the organic material layer comprises a hole transport layer, an emitting layer and an electron transport layer, and forms an emitting auxiliary layer between the hole transport layer and the emitting layer, wherein the hole transport layer and the emitting auxiliary layer satisfy the following equation 1:
$$\vert \frac{Δ {Rs}_{p}}{Δ {d}_{p}} \vert \leq 1.1 \qquad [ Equation 1 ]$$
wherein:
1) ΔRsₚ is the difference in lateral resistance according to the thickness of the emitting auxiliary layer,
2) Δdₚ is the difference in thickness of the emitting auxiliary layer.

2. The organic electronic element according to claim 1, wherein the lateral resistance change ratio has a value less than 1.0.

3. The organic electronic element according to claim 1, wherein the lateral resistance change ratio has a value less than 0.9.

4. The organic electronic element according to claim 1, wherein the hole transport layer or the emitting auxiliary layer is represented by Formula 1 or Formula 2: 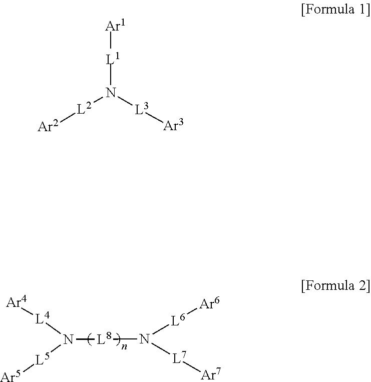
wherein:
L¹, L², L³, L⁴, L⁵, L⁶ and L⁷ are each selected from the group consisting of single bond; a C₆-C₆₀ arylene group; a fluorenylene group; a C₂-C₆₀ heterocyclic group including at least one heteroatom of O, N, S, Si or P; and a fused ring group of a C₃-C₆₀ aliphatic ring and a C₆-C₆₀ aromatic ring;
L⁸ is selected from the group consisting of single bond; a C₆-C₆₀ arylene group; a fluorenylene group; a C₂-C₆₀ heterocyclic group including at least one heteroatom of O, N, S, Si or P; and a fused ring group of a C₃-C₆₀ aliphatic ring and a C₆-C₆₀ aromatic ring;
Ar¹, Ar², Ar³, Ar⁴, Ar⁵, Ar⁶ and Ar⁷ are each selected from the group consisting of a C₆-C₆₀ aryl group; a fluorenyl group; a C₂-C₆₀ heterocyclic group including at least one heteroatom of O, N, S, Si or P; and a fused ring group of a C₃-C₆₀ aliphatic ring and a C₆-C₆₀ aromatic ring; a C₃-C₆₀ aliphatic ring; C₁-C₅₀ alkyl group; C₂-C₂₀ alkenyl group; C₂-C₂₀ alkynyl group; a C₁-C₃₀ alkoxyl group; a C₆-C₃₀ aryloxy group; and -L′-N(R′)(R″); or, the Ar⁴ and Ar⁵ or Ar⁶ and Ar⁷ can be bonded to each other to form a ring,
wherein L′ is selected from the group consisting of single bond; a C₆-C₆₀ arylene group; a fluorenylene group; a C₃-C₆₀ aliphatic ring; and a C₂-C₆₀ heterocyclic group including at least one heteroatom of O, N, S, Si or P;
R′ and R″ are each independently selected from the group consisting of a C₆-C₆₀ aryl group; a fluorenyl group; a C₃-C₆₀ aliphatic ring group; and a C₂-C₆₀ heterocyclic group including at least one hetero atom of O, N, S, Si or P;
n is an integer from 1 to 3,
wherein the aryl group, arylene group, heterocyclic group, fluorenyl group, fluorenylene group, fused ring group, aliphatic ring group, alkyl group, alkenyl group, alkynyl group, alkoxy group and aryloxy group may be substituted with one or more substituents selected from the group consisting of deuterium; halogen; C₁-C₂₀ alkyl group; or a silane group substituted or unsubstituted with an C₆-C₂₀ aryl group; siloxane group; boron group; germanium group; cyano group; nitro group; C₁-C₂₀ alkylthio group; C₁-C₂₀ alkoxyl group; C₁-C₂₀ alkyl group; C₂-C₂₀ alkenyl group; C₂-C₂₀ alkynyl group; C₆-C₂₀ aryl group; C₆-C₂₀ aryl group substituted with deuterium; a fluorenyl group; C₂-C₂₀ heterocyclic group; C₃-C₂₀ cycloalkyl group; C₇-C₂₀ arylalkyl group; C₈-C₂₀ arylalkenyl group; and -L′-N(R′)(R″); additionally, the hydrogens of these substituents may be further substituted with one or more deuteriums, also the substituents may be bonded to each other to form a saturated or unsaturated ring, wherein the term ‘ring’ means a C₃-C₆₀ aliphatic ring or a C₆-C₆₀ aromatic ring or a C₂-C₆₀ heterocyclic group or a fused ring formed by the combination thereof.

5. The organic electronic element according to claim 1, further comprising a light efficiency enhancing layer formed on at least one surface of the first electrode and the second electrode, the surface being opposite to the organic material layer.

6. The organic electronic element of claim 1, wherein the organic material layer comprises 2 or more stacks comprising a hole transport layer, an emitting layer and an electron transport layer sequentially formed on the first electrode.

7. The organic electronic element of claim 6, wherein the organic material layer further comprise a charge generation layer formed between the 2 or more stacks.

8. The organic electronic element of claim 1, further comprising a buffer layer between the emitting auxiliary layer and the hole transport layer.

9. An electronic device comprising a display device comprising the organic electronic element of claim 1; and a control unit for driving the display device.

10. The electronic device according to claim 9, wherein the organic electronic element is at least one of an OLED, an organic solar cell, an organic photo conductor, organic transistor and an element for monochromic or white illumination.
